(19) United States
(12) Patent Application Publication
(10) Pub. No.: US 2002/0035710 A1
(43) Pub. Date: Mar. 21, 2002

(54) SEMICONDUCTOR STORAGE DEVICE

(76) Inventors: HIROMOTO MIURA, TOKYO (JP); KATSUKI HAZAMA, TOKYO (JP)

Correspondence Address: POLLOCK VANDE SANDE AND PRIDDY, P O BOX 19088, WASHINGTON, DC, 200363425

(21) Appl. No.: 09/089,359

(22) Filed: Jun. 3, 1998

(30) Foreign Application Priority Data
Jun. 6, 1997 (JP) 9-165164
Dec. 25, 1997 (JP) 9-367115
Dec. 26, 1997 (JP) 9-367744
Mar. 3, 1998 (JP) 10-67886
Mar. 3, 1998 (JP) 10-67887

(51) Int. Cl. G01R 31/28; G11C 29/00

(52) U.S. Cl. 714/716

(57) ABSTRACT

First data (“00”, “01”, “10”, “11”) corresponding to threshold voltages of four values (1 V, 2 V, 3 V, 4 V) are stored in the individual memory cells of an EEPROM. Upon reading, a decoder circuit assigns bits so that neighboring first data have only one different bit in their two-bit architectures, thus converting the first data into second data (“00”, “01”, “11”, and “10”), and outputting the second data as storage data of the memory cells. Even when multiple-valued storage data are lost from the EEPROM due to data errors arising from deterioration of memory cells which have inevitably occurred after repetitive uses, error detection and error correction can be efficiently and accurately done. Of course, the data to be stored is not limited to 2-bit data, but the present invention can also be applied to multiple-valued data of 3 bits or more.

### BACKGROUND OF THE INVENTION

1. Field of the Invention

The present invention relates to a multiple-valued storage type semiconductor storage device, a method of using the same, and a storage medium that stores the use method and, more particularly, to a semiconductor storage device suitably applied to a semiconductor storage device which can store predetermined data of 2 bits or more as binary data.

2. Description of the Related Art

In currently available semiconductor storage devices, one memory cell is assigned only two different storage states, i.e., “0” and “1”, and hence, the storage capacity of one memory cell is 1 bit (=binary). By contrast, a semiconductor storage device which assigns four different storage data (00, 01, 10, 11) to one memory cell, and holds the stored data by four different threshold voltages (e.g., 1 V, 2 V, 3 V, 4 V) corresponding to these storage data, and in which the storage capacity of one memory cell corresponds to 2 bits (quaternary or four-valued) has been proposed.

Examples of the above-mentioned multiple-valued type semiconductor storage device are disclosed in Japanese Patent Laid-Open Nos. 6-282992 and 8-287698. In the circuit arrangement of a read means in semiconductor storage devices disclosed in these references, a decoder circuit for outputting the determination result of the threshold voltage of each memory cell as binary data is designed to output the individual bits that form binary data via at least one of logic gates such as a NOT gate, AND gate, OR gate, and the like.

Upon reading out storage data stored in the above-mentioned semiconductor storage device, the upper bit of 2 bits of the storage data is detected first. More specifically, a determination voltage having an intermediate value between 2 V and 3 V, e.g., 2.5 V, is applied, and if a current flows, since the storage data is one of “10” and “11”, the upper bit is determined to be “1”. On the other hand, if a current does not flow, since the storage data is one of “00” and “01”, the upper bit is determined to be “0”.

Subsequently, the lower bit of the 2 bits of the storage data is detected to determine the storage data. More specifically, when a current flowed upon determination of the upper bit, a determination voltage having an intermediate value between 1 V and 2 V, e.g., 1.5 V, is applied, and if a current flows, it is determined that the threshold voltage is 1 V and, hence, the storage data is “00”. Otherwise, if a current does not flow, it is determined that the threshold voltage is 2 V and, hence, the storage data is “01”.

On the other hand, when a current did not flow upon determination of the upper bit, a determination voltage having an intermediate value between 3 V and 4 V, e.g., 3.5 V, is applied, and if a current flows, it is determined that the threshold voltage is 3 V and, hence, the storage data is “10”. Otherwise, if a current does not flow, it is determined that the threshold voltage is 4 V and, hence, the storage data is “11”.

As a matter of course, as the number of logic gates through which the signal must pass, and the number of input lines to each logic gate increase especially in a decoder circuit, problems such as signal delays and the like are posed. For example, when the storage data is 2-bit binary data as the minimum multiple-valued storage data like in Japanese Patent Laid-Open No. 8-287698, signal delays are not so serious, since the decoder circuit has a relatively simple arrangement. However, when the storage data is 3-bit binary data as in Japanese Patent Laid-Open No. 6-282992, not only the number of logic gates increases, but also a very large number of input lines are connected to each logic gate. As the number of bits that form multiple-valued data to be stored in the semiconductor storage device increases, signal delays become more serious accordingly, and disturb efficient implementation of multiple-valued data storage.

When the semiconductor storage device is used repetitively, the memory cells deteriorate, and their threshold voltages may drop. If a certain threshold voltage drops below the determination voltage of the neighboring threshold voltage, data errors occur. For example, upon reading, the storage data “01” is erroneously read out as “00”, “10” as “01”, “11” as “10”, and so on. In such case, as for data errors from “01” to “00” or “11” to “10”, an error has occurred in only one bit, e.g., the upper or lower bit alone. However, as for data errors from “10” to “01”, both the upper and lower bits have suffered errors. When data errors for two bits have occurred, error detection using parity error check codes or error correction using Hamming codes as conventional error detection and error correction methods cannot be done.

In recent years, semiconductor storage devices having a larger number of bits that form multiple-valued data have been studied. When storage data is octonary or eight-valued data (3 bits) or more, the probability of data errors simultaneously occurring in 2 bits or more of the storage data becomes very high as compared to four-value data (2 bits), and error detection and error correction that require complicated algorithms and a larger number of check bits become unwantedly indispensable.

For example, Japanese Patent Laid-Open No. 8-249893 discloses the following technique. That is, in addition to a first write verify means, which is normally used in a conventional device, a second write verify means is arranged to confirm write errors, and the threshold value of a memory cell is set for each data to fall within a predetermined range. However, this technique aims at preventing errors in storage data, but is not a technique that can solve the problem of data errors since the above reference does not mention about any data errors described above.

An excellent semiconductor storage device that can attain parity error check is disclosed in Japanese Patent Laid-Open No. 6-282992 above. In this technique, when, for example, the storage data is 3-bit data, binary data to be stored in memory cells in correspondence with the threshold voltages are defined so that the storage data corresponding to neighboring threshold values have only one different bit. According to this technique, even when data errors have occurred due to changes in threshold voltage, they can be corrected by normal parity error check since they have occurred in only one bit.

In the circuit arrangement of a read means in the semiconductor storage device disclosed in this reference, a decoder circuit that outputs the determination result of the threshold voltage of each memory cell as binary data outputs bits that form binary data via at least one of logic gates such as a NOT gate, AND gate, OR gate, and the like. Apparently, as the number of logic gates through which a signal must pass, and the number of input lines to each logic gate increase especially in a decoder circuit, problems pertaining to signal delays and the like are posed. For example, when the storage data is 2-bit binary data as the minimum multiple-valued storage, signal delays are not so serious, since the decoder circuit has a relatively simple arrangement. However, when the storage data is 3-bit binary data as in Japanese Patent Laid-Open No. 6-282992, not only the number of logic gates increases, but also a very large number of input lines are connected to each logic gate. As the number of bits that form multiple-valued data to be stored in the semiconductor storage device increases, signal delays become more serious accordingly, and disturb efficient implementation of multiple-valued data storage. That is, the semiconductor storage device of Japanese Patent Laid-Open No. 6-282992 can attain correction by normal parity error check and can improve reliability, but requires a dedicated device arrangement that sets only one different bit between neighboring threshold voltages. In addition, as the number of bits that form multiple-valued data increases, the device arrangement becomes inevitably considerably complicated.

### SUMMARY OF THE INVENTION

It is an object of the present invention to provide a semiconductor storage device which can suppress signal delays and can attain high-speed reads without complicating the circuit arrangement even when the number of bits that form multiple-valued data to be stored in the semiconductor storage device increases, and to provide a quick read method using that device, and a storage medium which records the read method.

It is another object of the present invention to provide a semiconductor storage device which can efficiently and accurately implement error detection and error correction with a very simple arrangement even when multiple-valued storage data are lost due to data errors arising from deterioration of memory cells that have been inevitably produced after repetitive uses, and which can suppress signal delays and can attain high-speed reads without complicating the circuit arrangement even when the number of bits that form multiple-valued data to be stored in the semiconductor storage device increases, and to provide a method of using that device, and a storage medium which records the use method.

A semiconductor device according to the present invention is a semiconductor storage device which has a matrix of a plurality of memory cells, and obeys a first rule according to which storage data of predetermined values of at least two digits are stored in the respective memory cells in correspondence with an order of reference voltages, comprising write means for generating codes by assigning the input storage data according to a second rule, and storing the codes in the memory cells, and read means for assigning the code read out from the selected memory cell according to a third rule, and outputting the assigned code as output data, wherein the third rule is a rule for generating the output data by assigning the codes complying with the first rule to have only one different digit between neighboring codes when the codes are arranged in turn in correspondence with the reference voltages, and the second rule is an inverse assignment rule to the third rule, and the storage data and output data match each other unless an error has occurred in the output data.

A semiconductor device according to another aspect of the present invention is a semiconductor storage device comprising storage means having a matrix of a plurality of memory cells, each of which stores first data of a predetermined value of at least two digits, read means for selecting a desired memory cell from the storage means, detecting the first data stored in the selected memory cell, generating second data by converting the first data in accordance with an assignment rule for obtaining only one different digit in correspondence with neighboring reference voltages, and outputting the second data as storage data, and write means for converting the storage data into the first data by performing assignment inverse to the assignment rule of the read means, and storing the first data in the memory cells.

A semiconductor device according to still another aspect of the present invention is a multiple-valued type semiconductor storage device, which can store, in memory cells, storage data each defined by at least two digits, each of which assumes one of two values, wherein input storage data are converted in accordance with a rule that makes the storage data correspond to reference voltages, and the converted data are stored in the memory cells upon writing, the storage data stored in the memory cells are converted by an inverse conversion of the rule to have only one different digit between the storage data corresponding to neighboring reference voltages upon reading, and the input storage data and output storage data match each other unless an error has occurred upon writing, upon storing in the memory cells, or upon reading.

A semiconductor device according to still another aspect of the present invention is a semiconductor storage device which comprises a memory cell which can store predetermined storage data of 2ⁿ values (n is a natural number not less than 2), comprising read means for reading out first storage data stored in the memory cell, first data conversion means for converting a first specific value of the first storage data obtained by the read means into binary data of at least one predetermined digit, and second data conversion means for comparing the first specific value with (2ⁿ−1) reference values to obtain a second specific value and converting the second specific value into binary data, wherein neighboring binary data corresponding to the first storage data have only one different digit therebetween.

A semiconductor device according to still another aspect of the present invention is a semiconductor storage device which comprises a memory cell which can store predetermined storage data of 2ⁿ values (n is a natural number not less than 2), comprising read means for reading out first storage data stored in the memory cell, first data conversion means for converting a first specific value of the first storage data obtained by the read means into binary data of at least one predetermined digit, and second data conversion means for comparing the first specific value with (2ⁿ−1) reference values (m is a natural number smaller than n) to obtain a second specific value and converting the second specific value into binary data of m digits, wherein neighboring binary data corresponding to the first storage data have only one different digit therebetween.

A semiconductor device according to still another aspect of the present invention is a semiconductor storage device which comprises a memory cell which can store predetermined storage data of N^{M} values (N and M are natural numbers not less than 2), comprising read means for reading out first storage data stored in the memory cell, first data conversion means for converting a first specific value of the first storage data obtained by the read means into binary data of at least one predetermined digit, and second data conversion means for comparing the first specific value with (N^{M} −1) reference values to obtain a second specific value and converting the second specific value into binary data, wherein neighboring binary data corresponding to the first storage data have only one different digit therebetween.

A semiconductor device according to still another aspect of the present invention is a semiconductor storage device which comprises a memory cell which can store predetermined storage data of N^{M} values (N and M are natural numbers not less than 2), comprising read means for reading out first storage data stored in the memory cell, first data conversion means for converting a first specific value of the first storage data obtained by the read means into binary data of at least one predetermined digit, and second data conversion means for comparing the first specific value with (N^{L}−1) reference values (L is a natural number smaller than M) to obtain a second specific value and converting the second specific value into binary data of L digits, wherein neighboring binary data corresponding to the first storage data have only one different digit therebetween.

A semiconductor device according to still another aspect of the present invention is a multiple-valued type semiconductor storage device which can store storage data of predetermined values of at least three digits in memory cells in correspondence with reference voltages, and read out the storage data by specifying the reference voltages by several determination processes, wherein data of a predetermined one of digits that form the storage data is output first, and the data of the predetermined digit is output by a single determination process.

A semiconductor device according to still another aspect of the present invention is a semiconductor storage device comprising storage means having a matrix of a plurality of memory cells, which store 2-bit storage data in correspondence with reference voltages, and read means having three reference transistors, each of which has a predetermined value between neighboring reference voltages as a threshold voltage thereof, wherein the read means specifies and outputs first an upper bit of the storage data by a single first determination process using a predetermined one of the reference transistors, and performs second and third determination processes using remaining two of the reference transistors, specifies a result of the second or third determination process as a lower bit of the storage data depending on a result of the first determination process, and then outputs the lower bit.

A semiconductor device according to still another aspect of the present invention is a semiconductor storage device comprising storage means having a matrix of a plurality of memory cells, which store storage data of predetermined values of at least three digits in correspondence with reference voltages, and read means for selecting a desired memory cell from the storage means, and specifying and outputting the storage data by determining the reference voltage, the read means outputting data of a predetermined one of digits that form the storage data first, and outputting the data of the predetermined digit by a single determination process.

A semiconductor device according to still another aspect of the present invention is a semiconductor storage device which comprises a memory cell which can store predetermined storage data of 2ⁿ values (n is a natural number not less than 3), comprising read means for reading out first storage data stored in the memory cell, first data conversion means for converting a first specific value of the first storage data obtained by the read means into binary data of at least one predetermined digit, and second data conversion means for comparing the first specific value with (2ⁿ−1) reference values to obtain a second specific value and converting the second specific value into binary data.

A semiconductor device according to still another aspect of the present invention is a semiconductor storage device which comprises a memory cell which can store predetermined storage data of 2ⁿ values (n is a natural number not less than 3), comprising read means for reading out first storage data stored in the memory cell, first data conversion means for converting a first specific value of the first storage data obtained by the read means into binary data of at least one predetermined digit, and second data conversion means for comparing the first specific value with (2^{m}−1) reference values (m is a natural number smaller than n) to obtain a second specific value and converting the second specific value into binary data of m digits.

A semiconductor device according to still another aspect of the present invention is a semiconductor storage device which comprises a memory cell which can store predetermined storage data of N^{M} values (N is a natural number not less than 2, and M is a natural number not less than 3), comprising read means for reading out first storage data stored in the memory cell, first data conversion means for converting a first specific value of the first storage data obtained by the read means into binary data of at least one predetermined digit, and second data conversion means for comparing the first specific value with (N^{M}−1) reference values to obtain a second specific value and converting the second specific value into binary data.

A semiconductor device according to still another aspect of the present invention is a semiconductor storage device which comprises a memory cell which can store predetermined storage data of N^{M} values (N is a natural number not less than 2, and M is a natural number not less than 3), comprising read means for reading out first storage data stored in the memory cell, first data conversion means for converting a first specific value of the first storage data obtained by the read means into binary data of at least one predetermined digit, and second data conversion means for comparing the first specific value with (N^{L}−1) reference values (L is a natural number smaller than M) to obtain a second specific value and converting the second specific value into binary data of L digits.

In the semiconductor device of the present invention, since multiple-valued data is used as storage data, and the respective digits that form the storage data are assigned an output order to output especially the data of a predetermined digit (e.g., uppermost digit) first, the data of the predetermined digit is specified and output by a single determination process. More specifically, the semiconductor storage device of the present invention comprises reference transistors each of which has a predetermined value between neighboring threshold voltages as its threshold value, and the threshold voltages of the reference transistors are compared with the threshold voltage of the memory cell to specify the threshold voltage of that memory cell. For example, when the storage data is binary data, and values that the binary data can assume are arranged in turn, two groups having identical uppermost digits (most significant bits), the number of which is equal to the number of digits (the number of bits) of the storage data are formed. Using this fact, one of the two groups, i.e., the most significant bit, is specified by only single determination using one predetermined reference transistor, and the most significant bit is output first. In general, the arrangement of a decoder circuit in a read means is relatively simple when the storage data is 2-bit data. However, when the number of bits of the storage data is three or more, the arrangement of the decoder circuit tends to be complicated since the number of logic gates that make up the decoder circuit and the number of input lines of each logic gate increase tremendously, thus posing various problems such as signal delays. The semiconductor storage device of the present invention has an arrangement that can output the most significant bit first, and then outputs lower bits in turn, even when the number of bits that form the storage data becomes equal to or larger than 3, thus suppressing signal delays and the like.

In the semiconductor storage device of the present invention, as for the respective memory cells, multiple-valued storage data are defined in correspondence with threshold voltages, and each storage data is converted and output when it is read out, so that the difference between the storage data corresponding to neighboring threshold voltage is only one digit. In this case, in order to attain matching in correspondence with conversion upon reading, storage data input upon writing undergoes inversion conversion of that upon reading. More specifically, when storage data is binary data (e.g., 2-bit data), memory cells store (00, 01, 10, 11) in correspondence with threshold voltages. Upon reading, these storage data are converted into, e.g., (00, 01, 11, 10) so that the difference between neighboring storage data is 1 bit. At this time, if no errors have occurred in the storage data, the input and output storage data must naturally coincide with each other. For this purpose, inverse conversion of the conversion is done upon writing to obtain storage data (00, 01, 10, 11), and the converted data can be stored in the memory cells. As described above, the semiconductor storage device of the present invention can use normal memory cells that store data in correspondence with threshold voltages. Even when data errors have occurred due to threshold voltage drop arising from deterioration of memory cells after repetitive uses, storage data errors in the output can be restricted to only single-bit errors. Hence, error detection and error correction can be effectively attained by a conventional error detection method using parity error check codes and error correction method using Hamming codes.

Furthermore, in the semiconductor storage device of the present invention, since multiple-valued data is used as storage data, and the respective digits that form the storage data are assigned an output order to output especially the data of the uppermost digit first, the data of the predetermined digit is specified and output by a single determination process. More specifically, the semiconductor storage device of the present invention comprises reference transistors each of which has a predetermined value between neighboring threshold voltages as its threshold value, and the threshold voltages of the reference transistors are compared with the threshold voltage of the memory cell to specify the threshold voltage of that memory cell. For example, when the storage data is binary data, and values that the binary data can take on are arranged in turn, two groups having identical uppermost digits (most significant bits), the number of which is equal to the number of digits (the number of bits) of the storage data are formed. Exploiting this fact, one of the two groups, i.e., the most significant bit, is specified by only single determination using one predetermined reference transistor, and the most significant bit is output first. In general, the arrangement of a decoder circuit in a read means is relatively simple when the storage data is 2-bit data. However, when the number of bits of the storage data is three or more, the arrangement of the decoder circuit tends to be complicated since the number of logic gates that construct the decoder circuit and the number of input lines of each logic gate increase greatly, thus posing various problems such as signal delays. The semiconductor storage device of the present invention has an arrangement that can output the most significant bit first, and then outputs lower bits in turn, even when the number of bits that form the storage data becomes equal to or larger than 3, thus suppressing signal delays and the like.

In the semiconductor device of the present invention, since multiple-valued data is used as storage data, and the respective digits that form the storage data are assigned an output order to output especially the data of a predetermined digit (e.g., uppermost digit) first, the data of the predetermined digit is specified and output by a single determination process. More specifically, the semiconductor storage device of the present invention comprises reference transistors each of which has a predetermined value between neighboring threshold voltages as its threshold value, and the threshold voltages of the reference transistors are compared with the threshold voltage of the memory cell to specify the threshold voltage of that memory cell. For example, when the storage data is binary data, and values that the binary data can assume are arranged in turn, two groups having identical uppermost digits (most significant bits), the number of which is equal to the number of digits (the number of bits) of the storage data are formed. Using this fact, one of the two groups, i.e., the most significant bit, is specified by only single determination using one predetermined reference transistor, and the most significant bit is output first. In general, the arrangement of a decoder circuit in a read means is relatively simple when the storage data is 2-bit data. However, when the number of bits of the storage data is three or more, the arrangement of the decoder circuit tends to be complicated since the number of logic gates that build the decoder circuit and the number of input lines of each logic gate increase immensely, thus posing various problems such as signal delays. The semiconductor storage device of the present invention has an arrangement that can output the most significant bit first, and then outputs lower bits in turn, even when the number of bits that form the storage data becomes equal to or larger than 3, thus suppressing signal delays and the like.

Therefore, according to the present invention, even when multiple-valued storage data are lost from the EEPROM due to data errors arising from deterioration of memory cells which have inevitably occurred after repetitive uses, error detection and error correction can be efficiently and accurately done with a very simple arrangement. Also, even when the number of bits that form multi-value data to be stored in the semiconductor storage device increases, signal delays can be suppressed and high-speed reads can be attained without complicating the circuit arrangement.

Furthermore, according to the present invention, even when the number of bits that form multi-value data to be stored in the semiconductor storage device increases, signal delays can be suppressed and high-speed reads can be attained without complicating the circuit arrangement. Moreover, storage data can be quickly read out from the semiconductor storage device.

Another aspect of the present invention is a method of using and reading a semiconductor device, and a storage medium storing a method of using and reading the same.

A method of using a semiconductor device according to the present invention is a method of using a multiple-valued type semiconductor storage device which stores storage data of predetermined values each defined by at least two digits in memory cells, first data corresponding to reference voltages being defined in the memory cells with a value of the first data sequentially becoming larger as the reference voltage becomes higher, the method comprising the first step of converting input data into the first data, and storing the first data in a selected memory cell, the second step of detecting the first data from the memory cell, and the third step of converting the first data into the second data by assigning individual digits to have only one different digit between neighboring data, and outputting the second data as output data, wherein the storage data and output data match each other unless an error has occurred in the output data.

Preferably, the first step includes the step of forming a data sequence by adding redundant data for error detection or error correction to the storage data, converting the data sequence into the first data, and storing the first data in a series of a predetermined number of memory cells, and the third step includes the step of outputting the second data after it is checked if an error has occurred in the second data.

Preferably, the first step includes the step of forming a data sequence by adding redundant data for error detection or error correction to the storage data, converting the data sequence into the first data, and storing the first data in a series of a predetermined number of memory cells, and the third step includes the step of correcting an error when the error has occurred in the second data, and outputting the corrected second data.

Preferably, the third step includes the step of outputting data of an uppermost digit of the digits that form the storage data first, outputting the data of the uppermost digit by a single determination process, and sequentially outputting lower digits following the uppermost digit.

Preferably, the third step includes the steps of specifying and outputting first the data of the uppermost digit of the storage data by a single determination process using a predetermined one of reference transistors, each of which has a predetermined value between neighboring reference voltages as a threshold voltage thereof, and compares the threshold value with the reference voltage of the memory cell, specifying and outputting data of a lower digit following the uppermost digit by the determination process using a predetermined one of the remaining reference transistors on the basis of the data of the uppermost digit, and repeating operation for specifying and outputting data of a lower digit following the lower digit until a lowermost digit is reached.

Preferably, the third step further includes the steps of using selection means for selecting and enabling the predetermined one of the reference transistors in accordance with the storage data from the memory cell; and making the comparison by the reference transistor selected by said selection means.

Preferably, the third step includes the steps of specifying and outputting first the data of the uppermost digit of the data sequence by a single determination process using a predetermined one of reference transistors, each of which has a predetermined value between neighboring reference voltages as a threshold voltage thereof, and compares the threshold value with the reference voltage of the memory cell, specifying and outputting data of a lower digit following the uppermost digit by the determination process using a predetermined one of the remaining reference transistors on the basis of the data of the uppermost digit, and repeating operation for specifying and outputting data of a lower digit following the lower digit until a lowermost digit is reached.

Preferably, the third step further includes the steps of using selection means for selecting and enabling the predetermined one of the reference transistors in accordance with the data sequence from the memory cell and making the comparison by the reference transistor selected by said selection means.

Preferably, the third step includes the steps of specifying and outputting first the data of the uppermost digit of the data sequence by a single determination process using a predetermined one of reference transistors, each of which has a predetermined value between neighboring reference voltages as a threshold voltage thereof, and compares the threshold value with the reference voltage of the memory cell, specifying and outputting data of a lower digit following the uppermost digit by the determination process using a predetermined one of the remaining reference transistors on the basis of the data of the uppermost digit, and repeating operation for specifying and outputting data of a lower digit following the lower digit until a lowermost digit is reached.

Preferably, the third step further includes the steps of using selection means for selecting and enabling the predetermined one of the reference transistors in accordance with the data sequence from the memory cell, and making the comparison by the reference transistor selected by said selection means.

Preferably, the storage data is binary data.

Preferably, each memory cell is of serial access type.

Preferably, each memory cell has a gate, source, and drain, and also has an island-shaped floating gate formed via a dielectric film on a portion between said gate and a tunnel insulating film formed on a channel region between said source and drain.

A storage medium according to the present invention computer-readably stores the first to third steps that form a method of using a semiconductor storage device.

Preferably, a read method of a semiconductor storage device according to the present invention is a method of reading out data from a multiple-valued type semiconductor storage device, which can store storage data of predetermined values of at least three digits in memory cells in correspondence with reference voltages, and reads out the storage data by sequentially comparing a threshold voltage with the reference voltages of the memory cells using reference transistors, each of which has a predetermined value between neighboring reference voltages as a threshold voltage thereof to specify the reference voltage, comprising the first step of specifying and outputting the data of the uppermost digit of the storage data first by a single determination process using a predetermined one of the reference transistors, and the second step of specifying and outputting data of a lower digit following the uppermost digit by the determination process using a predetermined one of the remaining reference transistors on the basis of the data of the uppermost digit, wherein the second step of specifying and outputting data of a lower digit following the lower digit is sequentially repeated until a lowermost digit is reached.

Preferably, the storage data is binary data.

A read method of a semiconductor storage device according to another aspect of the present invention is a method of reading out data from a multiple-valued type semiconductor storage device, which can store 2-bit storage data in memory cells in correspondence with reference voltages, and reads out the storage data by sequentially comparing a threshold voltage with the reference voltages of the memory cells using three reference transistors, each of which has a predetermined value between neighboring reference voltages as a threshold voltage thereof, to specify the reference voltage, comprising, the first step of specifying and outputting first an upper bit of the storage data by a single first determination process using a predetermined one of the reference transistors, and the second step of performing second and third determination processes using remaining two of the reference transistors, specifying a result of the second or third determination process as a lower bit of the storage data depending on a result of the first determination process, and then outputting the lower bit.

Preferably, the first and second steps include the steps of using selection means for selecting and enabling the predetermined one of the reference transistors in accordance with the storage data from the memory cell, and making the comparison by the reference transistor selected by said selection means.

Preferably, each memory cell has a gate, source, and drain, and also has an island-shaped floating gate formed via a dielectric film on a portion between said gate and a tunnel insulating film formed on a channel region between said source and drain, and the memory cell stores the storage data corresponding to the reference voltage by setting the reference voltage as a threshold voltage upon applying predetermined voltages to said gate, source, and drain, respectively.

Preferably, each memory cell has a memory capacitor for accumulating a signal charge, and an access transistor for selecting the memory capacitor, and the memory cell stores the storage data corresponding to the reference voltage by setting a charge accumulation state upon applying a predetermined reference voltage to the memory capacitor.

Preferably, each memory cell is of serial access type.

A storage medium according to the present invention computer-readably stores steps that form a method of reading out data from a semiconductor storage device.

### BRIEF DESCRIPTION OF THE DRAWINGS

FIG. 1 is a block diagram showing the arrangement of principal part of an EEPROM according to the first embodiment of the present invention;

FIG. 2 is a schematic sectional view showing the arrangement of principal part of a memory cell of the EEPROM according to the first embodiment of the present invention;

FIG. 3 is a circuit diagram showing only the specific portion of an encoder circuit unit of the EEPROM according to the first embodiment of the present invention;

FIG. 4 is a circuit diagram showing only the specific portion of a decoder circuit unit of the EEPROM according to the first embodiment of the present invention;

FIG. 5 is a graph showing the distribution of threshold voltages in the EEPROM according to the first embodiment of the present invention;

FIGS. 6A and 6B are circuit diagrams showing other examples of a circuit near the output terminal of the decoder circuit unit of the EEPROM according to the first embodiment of the present invention;

FIG. 7 is a flow chart showing the respective steps executed upon reading out four-valued storage data from the EEPROM according to the first embodiment of the present invention;

FIG. 8 is a graph showing an example of the EEPROM according to the first embodiment of the present invention, which has suffered threshold voltage drops arising from deterioration of memory cells;

FIG. 9 is a graph showing an example of a conventional quaternary EEPROM that has suffered threshold voltage drops arising from deterioration of memory cells;

FIG. 10 is a block diagram showing the arrangement of principal part of a first modification of the EEPROM according to the first embodiment of the present invention;

FIG. 11 is a table showing the state wherein first data added with a parity bit are stored in the respective memory cells in the first modification of the EEPROM according to the first embodiment of the present invention;

FIG. 12 is a block diagram showing the arrangement of principal part of a second modification of the EEPROM according to the first embodiment of the present invention;

FIG. 13 is a table showing the state wherein first data added with redundant bits for error correction are stored in the respective memory cells in the first modification of the EEPROM according to the first embodiment of the present invention;

FIG. 14 is a block diagram showing the arrangement of principal part of a third modification of the EEPROM according to the first embodiment of the present invention;

FIG. 15 is a circuit diagram showing only the specific portion of a decoder circuit unit in the third modification of the EEPROM according to the first embodiment of the present invention;

FIG. 16 is a circuit diagram showing only the specific portion of the improved decoder circuit unit in the third modification of the EEPROM according to the first embodiment of the present invention;

FIG. 17 is a is a block diagram showing the arrangement of principal part of a fourth modification of the EEPROM according to the first embodiment of the present invention;

FIG. 18 is a circuit diagram showing only the specific portion of a decoder circuit unit in the fourth modification of the EEPROM according to the first embodiment of the present invention;

FIG. 19 is a circuit diagram showing only the specific portion of the improved decoder circuit unit in the fourth modification of the EEPROM according to the first embodiment of the present invention;

FIG. 20 is a block diagram showing the arrangement of principal part of an EEPROM according to the second embodiment of the present invention;

FIG. 21 is a circuit diagram showing only the specific portion of an encoder circuit unit of the EEPROM according to the second embodiment of the present invention;

FIG. 22 is a circuit diagram showing only the specific portion of a decoder circuit unit of the EEPROM according to the second embodiment of the present invention;

FIG. 23 is a circuit diagram illustrating the characteristic feature of the EEPROM according to the second embodiment of the present invention;

FIG. 24 is a graph showing the distribution of threshold voltages in the EEPROM according to the second embodiment of the present invention;

FIG. 25 is a flow chart showing the respective steps executed upon reading out eight-valued storage data from the EEPROM according to the second embodiment of the present invention;

FIG. 26 is a flow chart showing the respective steps after FIG. 25, that are executed upon reading out eight-valued storage data from the EEPROM according to the second embodiment of the present invention;

FIG. 27 is a graph showing an example of the EEPROM according to the second embodiment of the present invention, which has suffered threshold voltage drops due to deterioration of memory cells;

FIG. 28 is a graph showing an example of a conventional octonary EEPROM that has suffered threshold voltage drops arising from deterioration of memory cells;

FIG. 29 is a block diagram showing the arrangement of principal part of a first modification of the EEPROM according to the second embodiment of the present invention;

FIG. 30 is a table showing the state wherein first data added with a parity bit are stored in the respective memory cells in the first modification of the EEPROM according to the second embodiment of the present invention;

FIG. 31 is a block diagram showing the arrangement of principal part of a second modification of the EEPROM according to the second embodiment of the present invention;

FIG. 32 is a table showing the state wherein first data added with redundant bits for error correction are stored in the respective memory cells in the first modification of the EEPROM according to the second embodiment of the present invention;

FIG. 33 is a block diagram showing the arrangement of principal part of a third modification of the EEPROM according to the second embodiment of the present invention;

FIG. 34 is a circuit diagram showing only the specific portion of a decoder circuit unit in the third modification of the EEPROM according to the second embodiment of the present invention;

FIG. 35 is a circuit diagram showing only the specific portion of the improved decoder circuit unit in the third modification of the EEPROM according to the second embodiment of the present invention;

FIG. 36 is a circuit diagram showing the arrangement of principal part (vicinities of a read means) of an EEPROM according to the third embodiment of the present invention;

FIG. 37 is a circuit diagram showing the arrangement of principal part (vicinities of a read means) of the improved EEPROM according to the third embodiment of the present invention;

FIG. 38 is a schematic sectional view showing the arrangement of principal part of a memory cell of the EEPROM according to the third embodiment of the present invention;

FIG. 39 is a graph showing the distribution of threshold voltages in the EEPROM according to the third embodiment of the present invention;

FIG. 40 is a flow chart showing the respective steps executed upon reading out four-valued storage data from the EEPROM according to the third embodiment of the present invention;

FIG. 41 is a circuit diagram showing the arrangement of principal part of an EEPROM according to the fourth embodiment of the present invention;

FIG. 42 is a circuit diagram showing the arrangement of principal part of the improved EEPROM according to the fourth embodiment of the present invention;

FIG. 43 is a graph showing the distribution of threshold voltages in the EEPROM according to the fourth embodiment of the present invention;

FIG. 44 is a flow chart showing the respective steps executed upon reading out eight-valued storage data from the EEPROM according to the fourth embodiment of the present invention;

FIG. 45 is a flow chart showing the respective steps after FIG. 44, that are executed upon reading out eight-valued storage data from the EEPROM according to the fourth embodiment of the present invention; and

FIG. 46 is a block diagram showing a storage medium and storage/reproduction apparatus.

### DETAILED DESCRIPTION OF THE PREFERRED EMBODIMENTS

Some preferred embodiments of the present invention will be described in detail hereinafter with reference to the accompanying drawings.

First Embodiment

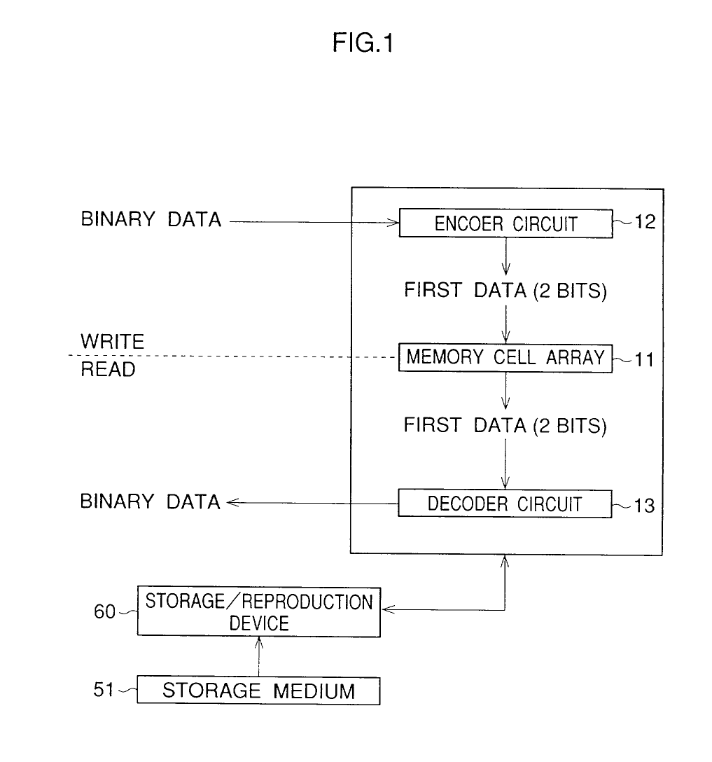

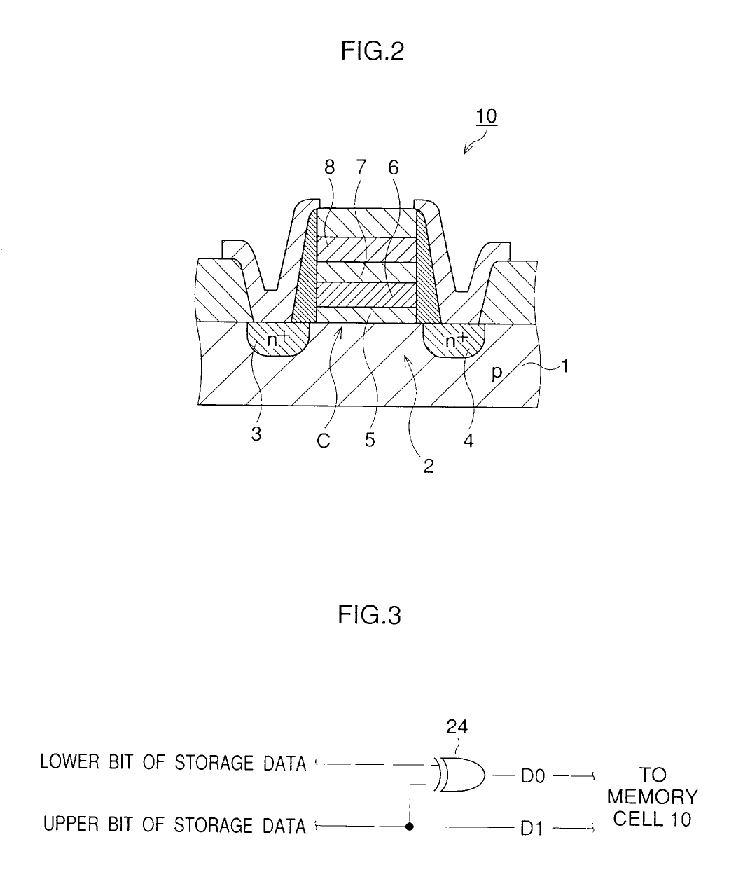

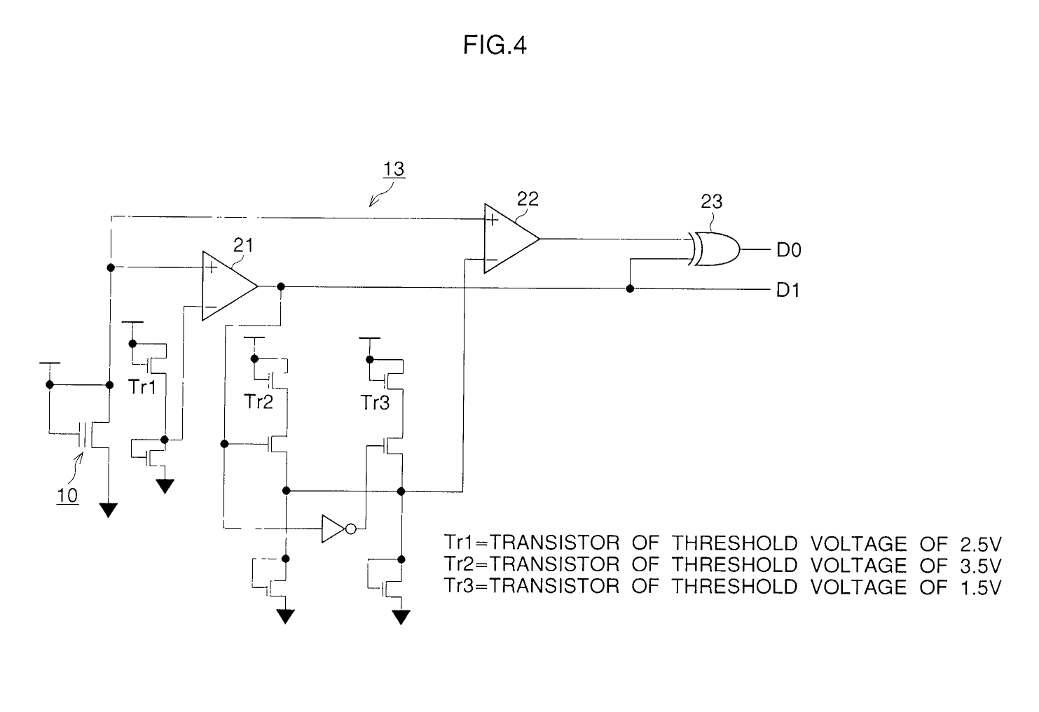

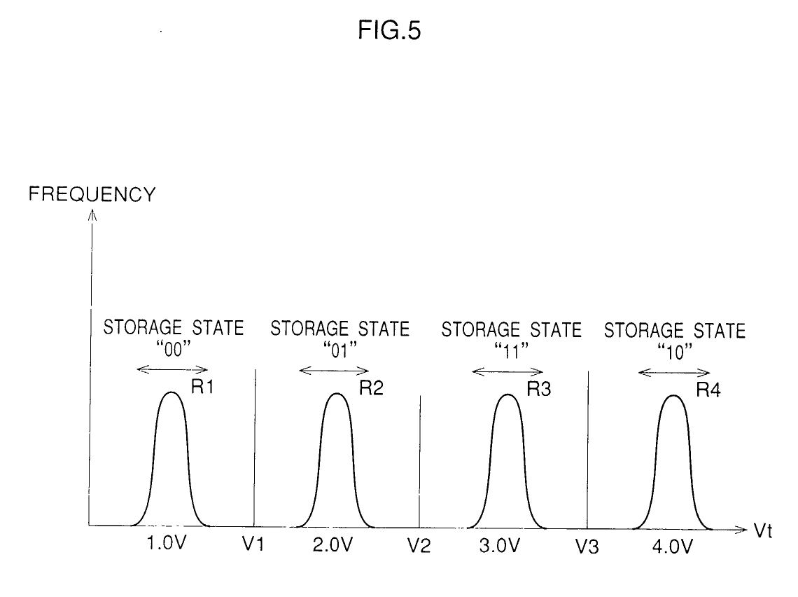

The first embodiment will be described below. In the first embodiment, an EEPROM as a nonvolatile semiconductor storage device that can store quaternary or four-valued (=2 bits) data will be exemplified. FIG. 1 is a block diagram showing the arrangement of principal part of the EEPROM of the first embodiment, FIG. 2 is a schematic sectional view showing the arrangement of principal part of a memory cell of the EEPROM, FIG. 3 is a circuit diagram showing only the specific portion of an encoder circuit unit, FIG. 4 is a circuit diagram showing only the specific portion of a decoder circuit unit, and FIG. 5 is a graph showing the distribution of threshold values of the memory cells.

As shown in FIG. 1, the EEPROM of the first embodiment comprises a memory cell array 11 as a matrix of a plurality of memory cells, an encoder circuit unit 12 for storing input storage data in the memory cells, and a decoder circuit unit 13 for detecting storage data in the selected memory cell, and outputting the detected storage data.

As shown in FIG. 2, each memory cell 10 has a source 3 and drain 4 as a pair of impurity diffusion layers, which are formed by doping an n-type impurity such as phosphorus (P), arsenic (As), or the like into the surface region of an element active region 2 defined by an element isolation structure such as a field oxide film or the like on a p-type silicon semiconductor substrate 1, an isolated, island-like floating gate 6 which is patterned via a tunnel oxide film 5 on a channel region C between the source 3 and drain 4, and a control gate 8 which is patterned on the floating gate 6 via a dielectric film 7 consisting of, e.g., an ONO film, and is capacitively coupled to the floating gate 6.

The encoder circuit unit 12 comprises an EX-OR gate 24, as shown in FIG. 3, and forms storage data by segmenting input binary data in units of 2 bits. In this encoder circuit unit 12, storage data is converted into first data by the EX-OR gate 24, the upper bit of the first data is output from an output terminal D1, and the lower bit of the first data is output from an output terminal D0, so that the first information is stored in the memory cell 10 in correspondence with a predetermined threshold voltage.

As shown in FIG. 4, the decoder circuit unit 13 comprises reference transistors Tr1, Tr2, and Tr3 which are connected to each memory cell 10 and respectively have threshold voltages of 2.5 V, 3.5 V, and 1.5 V, sense amplifiers 21 and 22, and an EX-OR gate 23. The bit line of each memory cell 10 is connected to the + terminal of the sense amplifier 21, and the transistor Tr1 is connected to the − terminal of the sense amplifier 22. Also, the bit line of each memory cell 10 is connected to the + terminal of the sense amplifier 22, and the transistors Tr2 and Tr3 are connected to the − terminal of the sense amplifier 22. Then, the EX-OR gate 23 is connected to receive signals output from the sense amplifiers 21 and 22. In the circuit arrangement of this decoder circuit unit 13, the upper bit of storage data is output from an output terminal D1, and the lower bit of the storage data is then output from an output terminal D0.

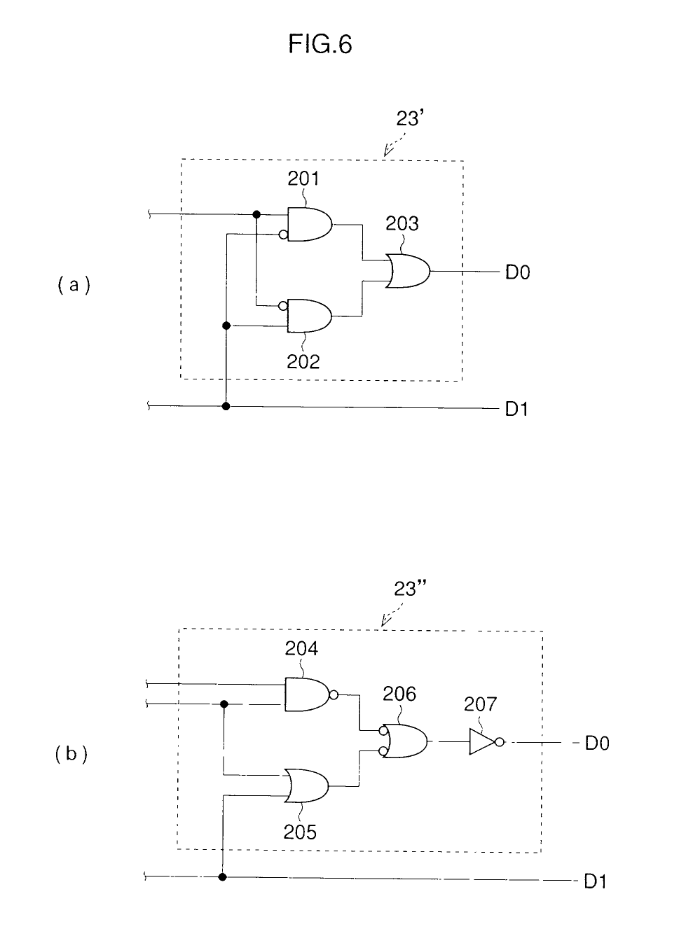

Note that gate groups 23′ and 23″ (portions in the broken lines) shown in FIGS. 6A and 6B may be used in place of the EX-OR gate 23. The gate group 23′ shown in FIG. 6A includes a pair of AND gates 201 and 202 (both having NOT gate portions at their input terminals) in the first stage, and an OR gate 203 in the second stage. On the other hand, the gate group 23″ shown in FIG. 6B includes a NAND gate 204 and OR gate 205 in the first stage, an OR gate 206 (with both input terminals having NOT gate portions) in the second stage, and a NOT gate 207 in the third stage.

The EEPROM can store first data corresponding to threshold voltages of four values (1 V, 2 V, 3 V, 4 V) in the respective memory cells 10 upon operation of the encoder circuit unit 12, and can store four-valued first data (“00”, “01”, “10”, “11”) so that the value of the first data becomes larger as the threshold voltage becomes higher. Upon reading, the decoder circuit unit 13 assigns bits so that neighboring first data have only one different bit in their 2-bit architecture to convert the first data into four-valued second data (“00”, “01”, “1”, and “10”) and the second data are output as storage data of the memory cells 10. More specifically, the operation of the encoder circuit unit 12 corresponds to inverse conversion (inverse assignment) of the operation of the decoder circuit unit 13, and 2-bit storage data formed by the encoder circuit unit 12 always matches 2-bit storage data output from the decoder circuit unit 13 unless the memory cells 10 have suffered data errors due to some causes.

In the first embodiment, the second data are assigned like (“00”, “01”, “11”, “10”). Alternatively, the second data need only be obtained by assigning bits so that neighboring data have only one different bit (one digit). For example, second data may be assigned like (“01”, “00”, “10”, “11”). Bit assignment in this case can also be realized using an EX-OR gate.

The method of writing storage data in the EEPROM will be explained below.

When first data “10” converted from storage data “11” by the EX-OR gate 24 is to be written, the drain 4 of the memory cell is set at the ground potential, the source 3 is opened, and a voltage of about 22 V is applied to the control gate 8. At this time, electrons are injected from the drain 4 into the floating gate 6 via the tunnel oxide film 5, and the threshold voltage (V_{T}) shifts in the positive direction. The threshold voltage of the memory cell then rises to about 4 V. This storage state is defined as “10”.

When first data “11” converted from storage data “10” by the EX-OR gate 24 is to be written, the drain 4 of the memory cell is set at the ground potential, the source 3 is opened, and a voltage of about 20 V is applied to the control gate 8. At this time, electrons are injected from the drain 4 into the floating gate 6 via the tunnel oxide film 5, and the threshold voltage of the memory cell then become about 3 V. This storage state is defined as “11”.

When first data “01” which remains the same as storage data “01” even via the EX-OR gate 24 is to be written, the drain 4 of the memory cell is set at the ground potential, the source 3 is opened, and a voltage of about 18 V is applied to the control gate 8. At this time, electrons are injected from the drain 4 into the floating gate 6 via the tunnel oxide film 5, and the threshold voltage of the memory cell then becomes about 2 V. This storage state is defined as “11”.

Finally, when first data “00” which remains the same as storage data “00” even via the EX-OR gate 24 is to be written, a voltage around 10 V is applied to the drain 4 of the memory cell to open the source 3 and to set the control gate 8 at the ground potential. At this time, electrons injected into the floating gate 6 are cleared from the drain 4, and the threshold voltage of the memory cell becomes about 1 V. This storage state is defined as “00”. Table 1 below shows the above-mentioned conversion states from storage data into first data by the EX-OR gate 24.

TABLE 1

| | | | | |
|---|---|---|---|---|
| Storage | “00” | “01” | “11” | “10” |
| Device | | | | |
| First Data | “00” | “01” | “10” | “11” |

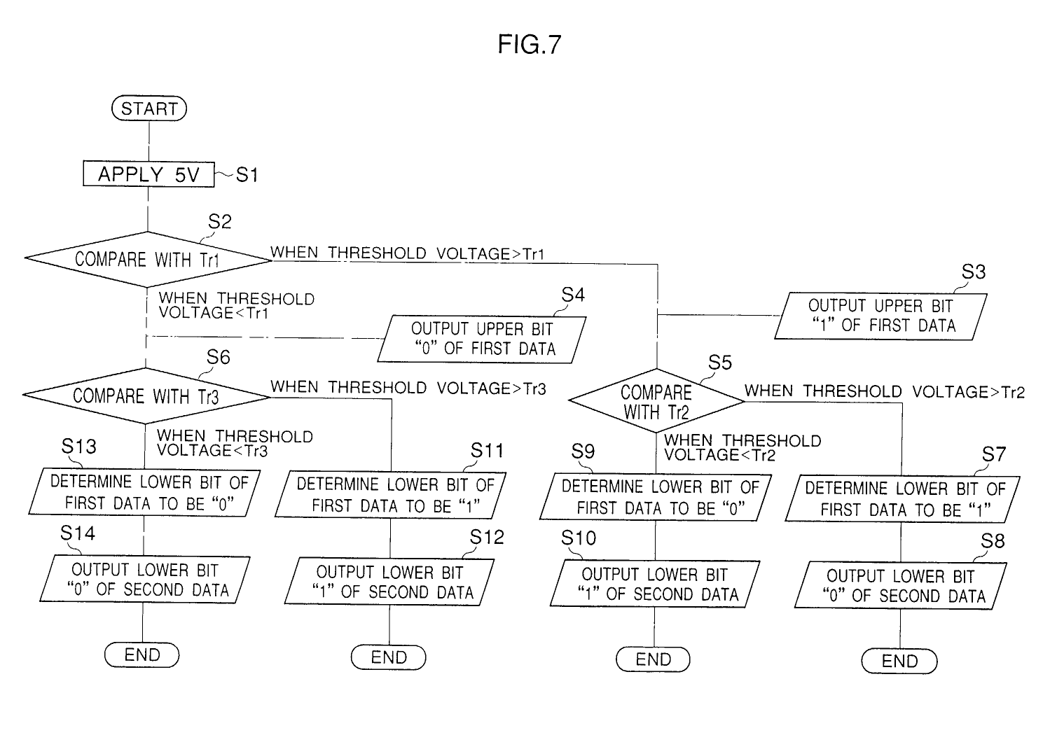

Furthermore, data is read out from the respective memory cells 10 of the EEPROM as follows. FIG. 7 is a flow chart showing the respective steps upon reading.

As for storage data, i.e., second data, read out from the selected memory cell 10 via the decoder circuit unit 13, as shown in FIG. 5, the threshold voltage (V_{T}) exhibits a distribution having four peaks (four values) of about 1 V, 2 V, 3 V, and 4 V. In FIG. 5, when the threshold voltage V_{T} is detected within the range R1, the storage state (second data) is “00”; and when the threshold voltage V_{T} is detected within the range R2, the storage state is “01”. Also, when the threshold voltage V_{T} is detected within the range R3, the storage state is “11”; and when the threshold voltage V_{T} is detected within the range R4, the storage state is “10”.

Hence, whether the storage state is “R1 or R2”, or “R3 or R4”, i.e., whether the upper bit of the first data stored in the memory cell 10 is “0” or “1” is determined using the transistor Tr1. In this case, as shown in FIG. 7, a voltage of about 5 V is applied to the source 3 and drain 4, and the gate electrode 6 (step S1). The drain current is detected by the sense amplifier 21, and the threshold voltage V_{T} and the threshold voltage of the transistor Tr1 are compared with each other (step S2). At this time, if the threshold voltage V_{T} is larger than the threshold voltage of the transistor Tr1, i.e., if the current of the transistor Tr1 is larger than that which flows in the channel region C of the memory cell, it is determined that the upper bit is “1”; if the threshold voltage V_{T} is smaller than the threshold voltage of the transistor Tr1, i.e., if the current which flows in the memory cell is larger than that which flows in the transistor Tr1, it is determined that the upper bit is “0”. The upper bit of the first data is equal to that of the second data, and is output from the output terminal D1 as the upper bit of the storage data prior to the lower bit (steps S3 and S4).

Subsequently, if the threshold voltage V_{T} is larger than the threshold voltage of the transistor Tr1, a similar read is done using the transistor Tr2, and the current which flows in the memory cell is compared with that which flows in the transistor Tr2 (step S5); if the threshold voltage V_{T} is smaller than the threshold voltage of the transistor Tr1, a similar read is done using the transistor Tr3 (step S6).

If it is determined in step S5 that the threshold voltage V_{T} is larger than the threshold voltage of the transistor Tr1 and is also larger than the threshold voltage of the transistor Tr2 in the read, it is determined that the lower bit of the first data stored in the memory cell 10 is “1”, i.e., the first data is “11” (step S7). The determined lower bit “1” is input to the EX-OR gate 23 together with the upper bit “1” of the first data. The EX-OR gate 23 converts the first data “11” into a lower bit “0” of the second information, and the converted bit is output from the output terminal D0 as the lower bit of the storage data (step S8). In this case, the storage data read out from the memory cell 10 is “10”.

On the other hand, if it is determined in step S5 that the threshold voltage V_{T} is smaller than the threshold voltage of the transistor Tr2, it is determined that the first data stored in the memory cell 10 is “10” (step S9), and its lower bit “0” is input to the EX-OR gate 23 together with the upper bit “1” of the first data. The EX-OR gate 23 converts the first data “10” into a lower bit “1” of the second data, and the converted lower bit is output from the output terminal D0 as the lower bit of the storage data (step S10). In this case, the storage data read out from the memory cell 10 is “11”.

If the threshold voltage V_{T} is smaller than the threshold voltage of the transistor Tr1, i.e., the current of the memory cell is larger than that of the transistor Tr1, the threshold voltage V_{T} is then compared with the threshold voltage of the transistor Tr3 (step S6). If the threshold voltage V_{T} is larger than the threshold voltage of the memory cell, it is determined that the lower bit is “1” (step S11), and the bit is input to the EX-OR gate 23 together with the upper bit “0” of the first data. The EX-OR gate 23 converts the first data “01” into a lower bit “1” of the second data, and the converted bit is output from the output terminal D0 as the lower bit of the storage data (step S12). Hence, in this case, the storage data read out from the memory cell 10 is “01” equal to the first data.

Similarly, if the threshold voltage V_{T} is smaller than the threshold voltage of the transistor Tr1, i.e., the current of the memory cell is larger than that of the transistor Tr1, the threshold voltage V_{T} is compared with the threshold voltage of the transistor Tr3. If the threshold voltage V_{T} is smaller than the threshold voltage of the memory cell contrary to the above case, it is determined that the lower bit is “0” (step S13), and that bit is input to the EX-OR gate 23 together with the upper bit “0”. The EX-OR gate 23 converts the first data “00” into a lower bit “0” of the second data, and the converted bit is output from the output terminal D0 as the lower bit of the storage data (step S14). Hence, in this case, the storage data read out from the memory cell 10 is “00” equal to the first data. Table 2 summarizes the above-mentioned conversion state from the first data to the second data by the EX-OR gate 23.

TABLE 2

| | | | | |
|---|---|---|---|---|
| First Data | “00” | “01” | “10” | “11” |
| Second Data | “00” | “01” | “11” | “10” |

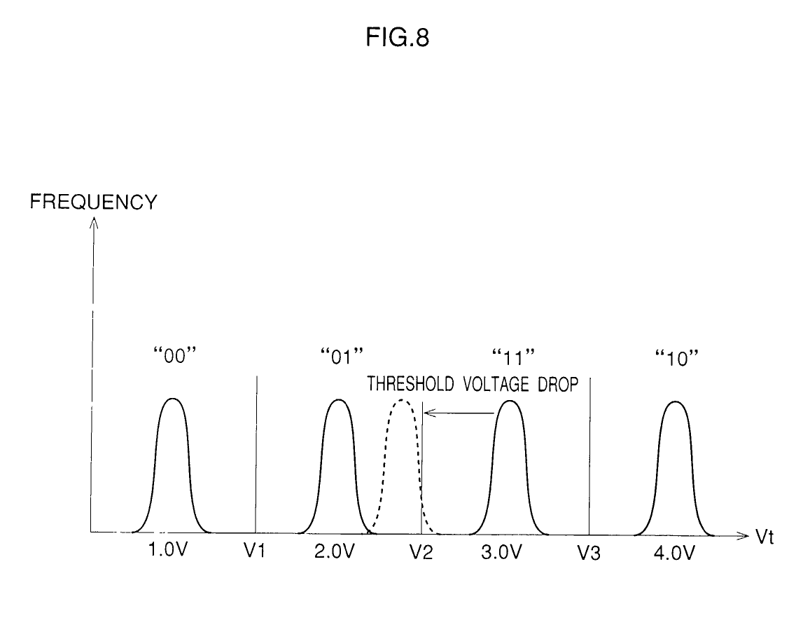

When the semiconductor storage device is used repetitively, the memory cells deteriorate, and their threshold voltages may drop. If a certain threshold voltage drops below the determination voltage of the neighboring threshold voltage, data errors occur. For example, upon reading, the storage data “01” is erroneously read out as “00”, “11” as “01”, “10” as “11”, and so on. In such case, errors have occurred in only one bit, e.g., the upper or lower bit alone. FIG. 8 shows as an example the case wherein the threshold voltage V_{T} corresponding to the storage data “11” has dropped below the threshold voltage (=2.5 V) of the transistor Tr1, i.e., the storage data “11” becomes “01” as a result of data errors.

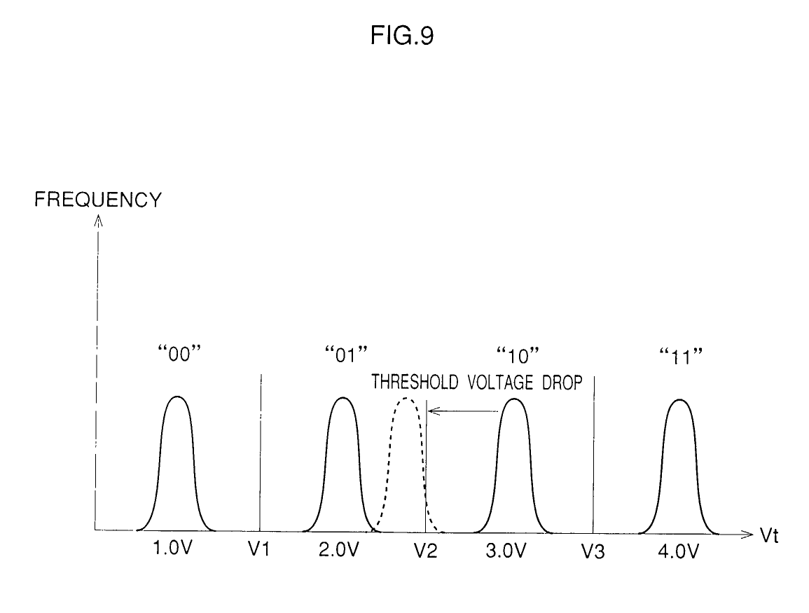

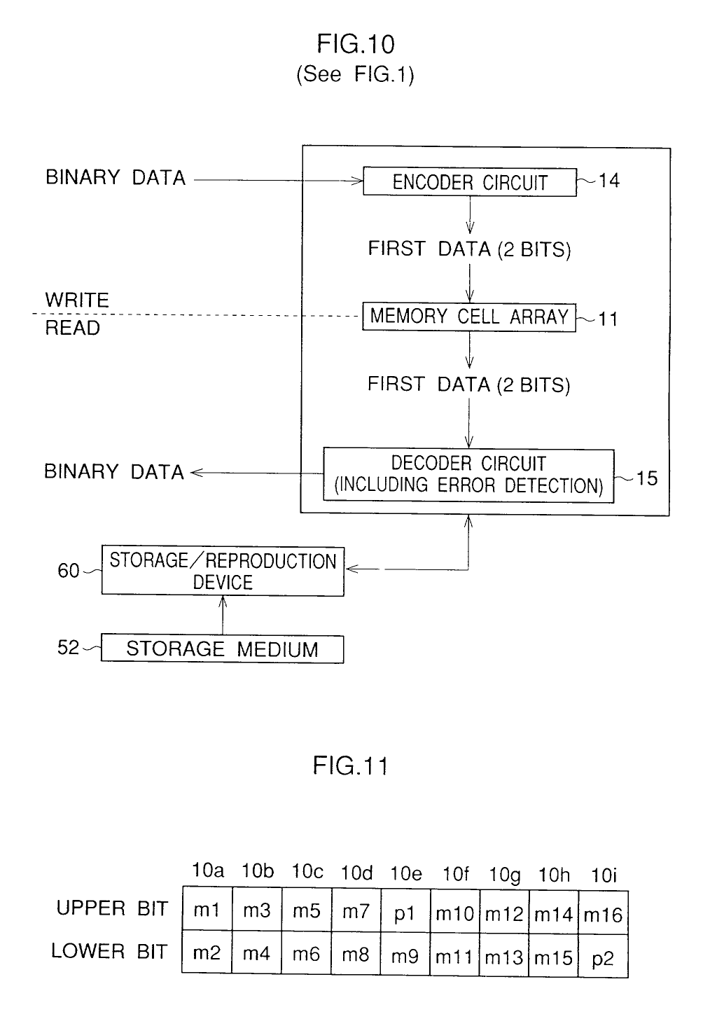

When first data (00, 01, 10, 11) directly stored in the memory cells 10 are used as storage data as in the conventional device, if the threshold voltage V_{T} becomes lower than the threshold voltage (=2.5 V) of the transistor Tr1, as shown in, e.g., FIG. 9, the storage data “10” becomes “01” as a result of data errors. At that time, data errors have occurred in both the upper and lower bits. By contrast, in the EEPROM of the first embodiment, data errors occur in only the lower bit, as described above. Therefore, when the EEPROM of the first embodiment is used, even when data errors occur due to deterioration of the memory cells 10, they can be confined to only single-bit errors, and error detection and error correction can be effectively performed using conventional error detection using parity error check codes and error correction using Hamming codes.

In the EEPROM of the first embodiment, since 2-bit binary data are used as storage data, and the respective bits that form each storage data are assigned an output order to output especially the data of the upper bit first, the data of the upper bit is specified and output by a single determination process by the transistor Tr1. More specifically, when values that the storage data can assume are aligned in turn, two groups having identical upper bits, the number of which is equal to the number of bits of the storage data are formed. Exploiting this fact, one of the two groups, i.e., the upper bit, is specified by only a single determination process of the transistor Tr1, and the upper bit is output first.

Furthermore, according to the EEPROM of the first embodiment, the first data, i.e., the data to be directly stored in the memory cells 10 are obtained by inserting only the EX-OR gate 24 in the input stage of the conventional device, and data errors can be restricted to only single-bit errors by a simple arrangement, i.e., by inserting the EX-OR gate 23 in the output stage of the conventional device. Hence, even when multiple-valued storage data are lost due to data errors resulting from deterioration of the memory cells 10, which have inevitably occurred after repetitive uses, error detection and error correction can be efficiently and accurately done.

Consequently, according to the EEPROM of the present invention, even when multiple-valued storage data are lost due to data errors ascribed to deterioration of the memory cells 10, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

First Modification

An EEPROM of the first modification will be explained below. This EEPROM has substantially the same arrangement as that of the first embodiment. In this modification, a case will be exemplified wherein a parity bit for error detection is added to storage data. Note that the same reference numerals denote parts corresponding to those of the EEPROM of the first embodiment, and a detailed description thereof will be omitted.

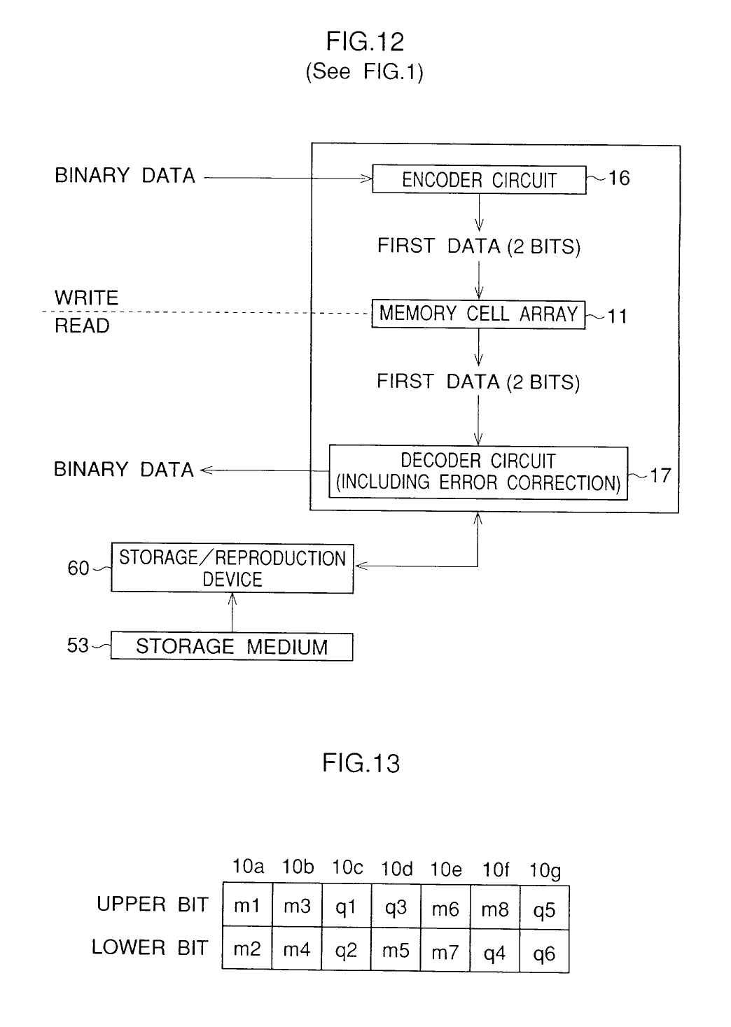

The EEPROM mainly comprises a memory cell array 11, encoder circuit unit 14, and decoder circuit unit 15, as shown in FIG. 10, like in the first embodiment. In this modification, a parity bit generation function is added to the encoder circuit unit 14, and an error detection function is added to the decoder circuit unit 15, unlike in the first embodiment.

More specifically, the encoder circuit unit 14 comprises an EX-OR gate 24, and adds one parity bit to every 8 bits of input binary data. In this case, a data sequence is formed by 9 bits, i.e., the sum of a total of 8 information bits (four data) and a parity bit, so that the number of “1” s always becomes an odd number (an example of odd parity). After the encoder circuit unit 14 forms a data sequence by adding one parity bit to every 8 bits of input binary data, it converts the data sequence into first data via the EX-OR gate 24 as in the first embodiment, and the first data are stored in memory cells 10. More specifically, as shown in FIG. 11, memory cells 10a to 10i sequentially store first data (m1, m2, . . . , m8, p1) and first data (m9, m10, . . . , m16, p2). Note that m1 to m16 are information bits, and p1 and p2 are parity bits.

By adding the parity bit, upon reading out second data from the memory cells 10 via the decoder circuit unit 15, if the reconstructed 9-bit second data includes an odd number of “1” s, the second data has no errors; if the second data includes an even number of “1”, the second data has errors.

Normally, in a parity check based on odd parity, if data errors have occurred in two or more bits in 8-bit binary data, it becomes impossible to accurately detect the errors. By contrast, in the EEPROM of the first modification, even when errors have occurred in the first data stored in one memory cell, e.g., data “10” becomes “01” as a result of data errors, data “11” merely becomes “01” as a result of data errors in the readout second data, and errors have occurred in only one bit. As for continuous storage data (for 8 bits in this case), since data errors are unlikely to occur in the storage data in two or more memory cells 10, such case can be ignored. Hence, error detection of the storage data can be done with sufficiently high accuracy by this parity check method.

In the EEPROM of the first modification, since 2-bit binary data are used as storage data, and the respective bits that form the storage data are assigned an output order to output especially the data of the upper bit first, as in the first embodiment, the data of the upper bit is specified and output by a single determination process of the transistor Tr1. More specifically, when values that the storage data can take on are aligned in turn, two groups having identical upper bits, the number of which is equal to the number of bits of the storage data are formed. Utilizing this fact, one of the two groups, i.e., the upper bit, is specified by only a single determination process of the transistor Tr1, and the upper bit is output first.

Furthermore, according to the EEPROM of the first modification, the first data, i.e., the data to be directly stored in the memory cells 10 are obtained by inserting only the EX-OR gate 24 in the input stage of the conventional device, and data errors can be limited to only single-bit errors by a simple arrangement, i.e., by inserting the EX-OR gate 23 in the output stage of the conventional device. Hence, even when multiple-valued storage data are lost due to data errors arising from deterioration of the memory cells 10, which have inevitably occurred after repetitive uses, error detection and error correction can be efficiently and accurately done.

Therefore, according to the EEPROM of this modification, even when multiple-valued storage data are lost due to data errors arising from deterioration of the memory cells 10, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Second Modification

An EEPROM of the second modification will be explained below. This EEPROM has substantially the same arrangement as that of the first embodiment. In this modification, a case will be exemplified wherein redundant bits for error correction are added to storage data. Note that the same reference numerals denote parts corresponding to those of the EEPROM of the first embodiment, and a detailed description thereof will be omitted.

The EEPROM mainly comprises a memory cell array 11, encoder circuit unit 16, and decoder circuit unit 17, as shown in FIG. 12, like in the first embodiment. However, unlike in the first embodiment, a function of adding redundant bits based on Hamming coding is added to the encoder circuit unit 16, and an error correction function is added to the decoder circuit unit 17.

More specifically, the encoder circuit unit 16 comprises an EX-OR gate 24, segments input binary data in units of 4 bits, forms three redundant bits from such 4-bit data by Hamming coding, and adds the redundant bits to the information bits to form a 7-bit data sequence. In this case, after the data sequence is converted into first data via the EX-OR gate 24 as in the first embodiment, first data (m1, m2, m3, m4, q1, q2, q3) and (m5, m6, m7, m8, q4, q5, q6) are respectively stored in seven bits, i.e., memory cells 10a to 10c and the upper bit of a memory cell 10d, and the lower bit of the memory cell 10d and memory cells 10e to 10g, in units of seven memory cells, as shown in FIG. 13. Note that m1 to m8 are information bits, and q1 to q6 are redundant bits.

Using such first data, upon reading out second data from the memory cells 10 via the decoder circuit unit 17, error correction is done as shown in, e.g., Table 3 below, using the reconstructed 7-bit second data. Of course, if no errors have occurred, the decoder circuit unit 17 outputs correct storage data.

TABLE 3

| Digit | | | 1 | 2 | 3 | 4 | 5 | 6 | 7 |
|---|---|---|---|---|---|---|---|---|---|
| Bit Weight | | | C | C | 8 | C | 4 | 2 | 1 |
| | 0 | = | 0 | 0 | 0 | 0 | 0 | 0 | 0 |
| | 1 | = | 1 | 1 | 0 | 1 | 0 | 0 | 1 |
| | 2 | = | 0 | 1 | 0 | 1 | 0 | 1 | 0 |
| | 3 | = | 1 | 0 | 0 | 0 | 0 | 1 | 1 |
| | 4 | = | 1 | 0 | 0 | 1 | 1 | 0 | 0 |
| | 5 | = | 0 | 1 | 0 | 0 | 1 | 0 | 1 |
| | 6 | = | 1 | 1 | 0 | 0 | 1 | 1 | 0 |
| | 7 | = | 0 | 0 | 0 | 1 | 1 | 1 | 1 |
| | 8 | = | 1 | 1 | 1 | 0 | 0 | 0 | 0 |
| | 9 | = | 0 | 0 | 1 | 1 | 0 | 0 | 1 |
| | 10 | = | 1 | 0 | 1 | 1 | 0 | 1 | 0 |
| | 11 | = | 0 | 1 | 1 | 0 | 0 | 1 | 1 |
| | 12 | = | 0 | 1 | 1 | 1 | 1 | 0 | 0 |
| | 13 | = | 1 | 0 | 1 | 0 | 1 | 0 | 1 |
| | 14 | = | 0 | 0 | 1 | 0 | 1 | 1 | 0 |
| | 15 | = | 1 | 1 | 1 | 1 | 1 | 1 | 1 |

| Digit | 1 | 2 | 3 | 4 | 5 | 6 | 7 | | | | | | |
|---|---|---|---|---|---|---|---|---|---|---|---|---|---|
| Readout code | 0 | 1 | 0 | 1 | 1 | 0 | 0 | | | | | | |
| (4,5,6,7)-th digit parity | | | | ∘ | ∘ | ∘ | ∘ | → | 0 | | | | |
| (2,3,6,7)-th digit parity | | ∘ | ∘ | | | ∘ | ∘ | → | | 1 | | | |
| (1,3,5,7)-th digit parity | ∘ | | ∘ | | ∘ | | ∘ | → | | | 1 | | |
| Digits with errors | | | | | | | | | 0 | 1 | 1 | = | 3 |

Of the second data, the first, second, and fourth bits are redundant bits, which are determined to obtain even parity in digit combinations (1, 3, 5, 7), (2, 3, 6, 7), and (4, 5, 6, 7). For example, assume that a data sequence “0111100” corresponding to a decimal number “12” is written, an error has occurred in one bit, and a data sequence “0101100” is read out. In such case, as shown in Table 1 above, since digits with errors can be obtained as a binary value (“011” in this case), even when a single-bit error has been produced in the second data, it can be easily and accurately corrected.

Normally, in Hamming coding using a data sequence obtained by adding three redundant bits to four storage bits, if data errors have occurred in two bits or more of 7-bit binary data, it becomes impossible to accurately detect such errors. In contrast, in the EEPROM of the second modification, even when errors have occurred in the first data stored in one memory cell, e.g., data “10” becomes “01” as a result of data errors, data “11” merely becomes “01” as a result of data errors in the readout second data, and errors have occurred in only one bit. As for continuous storage data (for 7 bits in this case), since data errors are unlikely to occur in the storage data in two or more memory cells 10, such case can be ignored. Hence, error correction of the storage data can be done with sufficiently high accuracy by this Hamming coding.

In the EEPROM of the second modification, since 2-bit binary data are used as storage data, and the respective bits that form the storage data are assigned an output order to output especially the data of the upper bit first, as in the first embodiment, the data of the upper bit is specified and output by a single determination process of the transistor Tr1. More specifically, when values that the storage data can assume are aligned in turn, two groups having identical upper bits, the number of which is equal to the number of bits of the storage data are formed. Using this fact, one of the two groups, i.e., the upper bit, is specified by only a single determination process of the transistor Tr1, and the upper bit is output first.

Furthermore, according to the EEPROM of the second modification, the first data, i.e., the data to be directly stored in the memory cells 10 are obtained by inserting only the EX-OR gate 24 in the input stage of the conventional device, and data errors can be restricted to only single-bit errors by a simple arrangement, i.e., by inserting the EX-OR gate 23 in the output stage of the conventional device. Hence, even when multiple-valued storage data are lost due to data errors resulting from deterioration of the memory cells 10, which have inevitably occurred after repetitive uses, error detection and error correction can be efficiently and accurately done.

Thus, according to the EEPROM of this modification, even when multiple-valued storage data are lost due to data errors arising from deterioration of the memory cells 10, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Third Modification

An EEPROM of the third modification will be explained below. This EEPROM has substantially the same arrangement as that of the first embodiment, except that the arrangement of the decoder circuit is slightly different from that of the first embodiment. Note that the same reference numerals denote parts corresponding to those of the EEPROM of the first embodiment, and a detailed description thereof will be omitted.

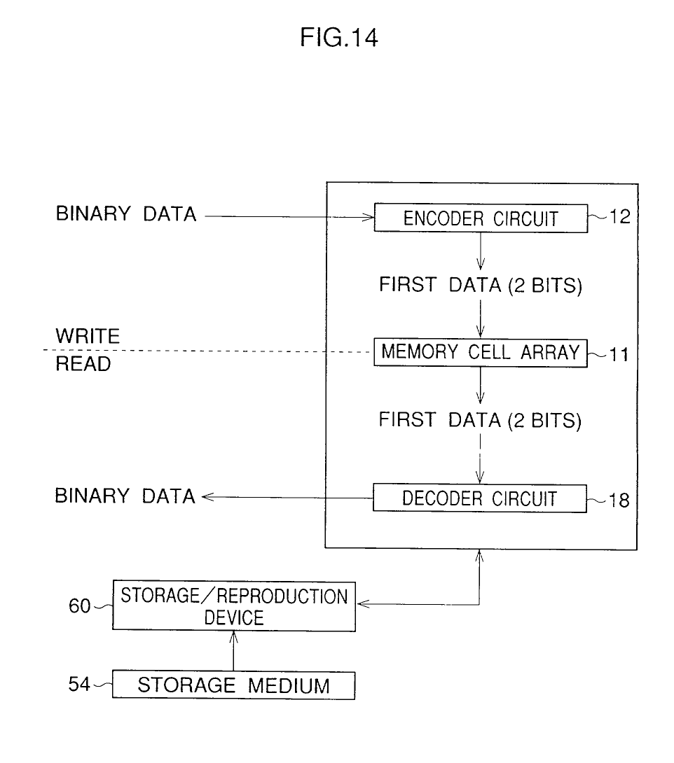

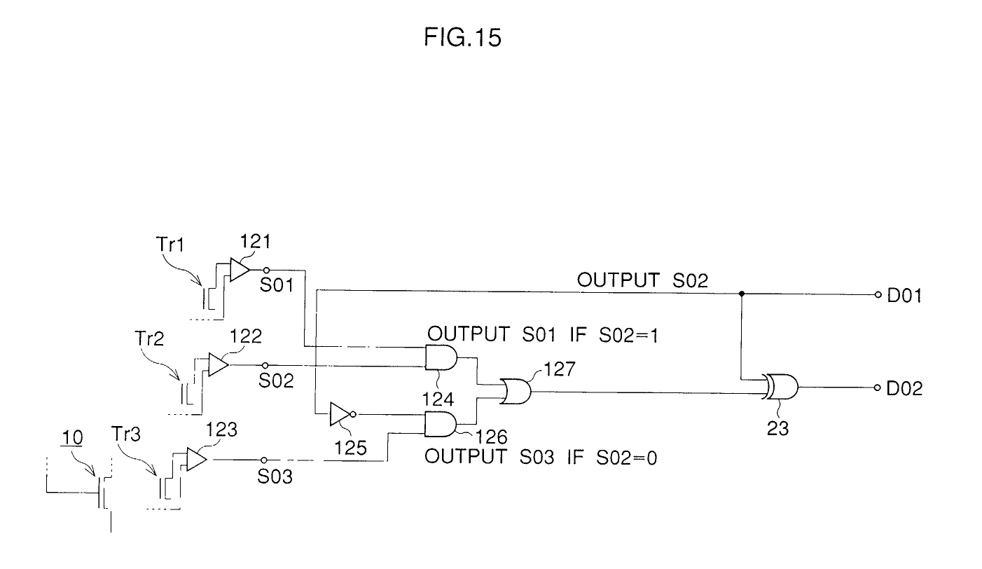

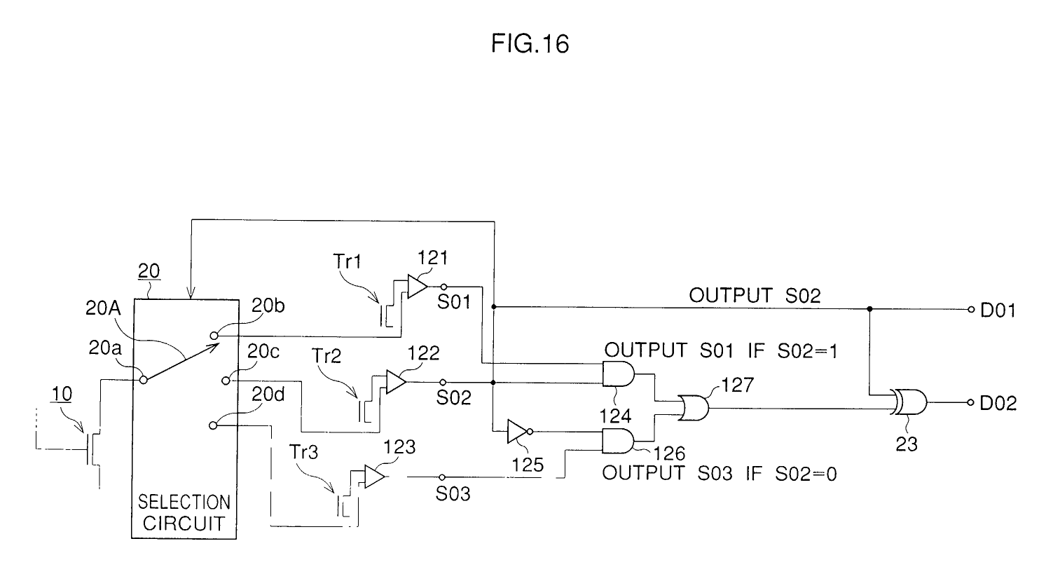

The EEPROM mainly comprises a memory cell array 11, encoder circuit unit 16, decoder circuit unit 18, and the like, as shown in FIG. 14, like in the first embodiment. The arrangement of the decoder circuit unit 18 is slightly different from the decoder circuit unit 13. That is, as shown in FIG. 15, the decoder circuit unit 18 comprises transistors Tr1, Tr2, and Tr3 which are connected to each memory cell 10, and have threshold voltages respectively set at 3.5 V, 2.5 V, and 1.5 V, sense amplifiers 121, 122, and 123 respectively connected to these transistors Tr1 to Tr3, terminals S01, S02, and S03 respectively connected to the sense amplifiers 121 to 123, an AND gate 124 connected to the terminals S01 and S02, an AND gate 126 connected to the terminals S02 and S03 via a NOT gate 125, an OR gate 127 connected to the AND gates 124 and 126, and an EX-OR gate 23 connected to receive signals from the terminal S02 and OR gate 127. The terminal S02 is directly connected to an output terminal D01, and the EX-OR gate 23 to an output terminal D02. In this case, as shown in FIG. 16, a selection circuit 20 is preferably added. The EEPROM 20 with the selection circuit 20 will be explained below with reference to FIG. 15. In this decoder circuit unit 18, the output terminal D01 outputs the upper bit of storage data, and the output terminal D02 the lower bit of the storage data.

The selection circuit 20 is connected to each memory cell 10 and the reference transistors Tr1, Tr2, and Tr3 via connection terminals 20a, 20b, 20c, and 20d, and a selection switch 20A is arranged at the connection terminal 20a. The selection switch 20A can be selectively connected to the connection terminals 20b, 20c, and 20d, and connects the connection terminal 20a and one of the connection terminals 20b to 20d in correspondence with storage data from the memory cell 10 and in accordance with the read flow of storage data (to be described later).

The methods of writing and reading storage data using the EEPROM are the same as those in the first embodiment. An example of the read method will be described below using FIG. 7 again.

As in the first embodiment, whether the storage state is “R1 or R2”, or “R3 or R4”, i.e., whether the upper bit of the first data stored in the memory cell 10 is “0” or “1” is determined using the transistor Tr1. In this case, the memory cell 10 is connected to the reference transistor Tr1 by controlling the selection switch 20A in the selection circuit 20. A voltage of about 5 V is applied to the source 3 and drain 4, and the gate electrode 6 (step S1). The drain current is detected by the sense amplifier 121, and the threshold voltage V_{T} and the threshold voltage of the transistor Tr1 are compared with each other (step S2). At this time, if the threshold voltage V_{T} is larger than the threshold voltage of the transistor Tr1, i.e., if the current of the transistor Tr1 is larger than that which flows in the channel region C of the memory cell, it is determined that the upper bit is “1”; if the threshold voltage V_{T} is smaller than the threshold voltage of the transistor Tr1, i.e., if the current which flows in the memory cell is larger than that which flows in the transistor Tr1, it is determined that the upper bit is “0”. The upper bit of the first data is equal to that of the second data, and is output from the output terminal D01 as the upper bit of the storage data prior to the lower bit (steps S3 and S4).

Subsequently, if the threshold voltage V_{T} is larger than the threshold voltage of the transistor Tr1, a similar read is done using the transistor Tr2. More specifically, the memory cell 10 is connected to the reference transistor Tr2 by controlling the selection switch 20A in the selection circuit 20. Then, the current which flows in the memory cell is compared with that which flows in the transistor Tr2 (step S5). On the other hand, if the threshold voltage V_{T} is smaller than the threshold voltage of the transistor Tr1, a similar read is done using the transistor Tr3. That is, the memory cell 10 is connected to the reference transistor Tr3 by controlling the selection switch 20A in the selection circuit 20. Then, the current which flows in the memory cell 10 is compared with that which flows in the transistor Tr3 (step S6).

If it is determined in step S5 that the threshold voltage V_{T} is larger than the threshold voltage of the transistor Tr1 and is also larger than the threshold voltage of the transistor Tr2 in the read, it is determined that the lower bit of the first data stored in the memory cell 10 is “1”, i.e., the first data is “11” (step S7). The determined lower bit “1” is input to the EX-OR gate 23 together with the upper bit “1” of the first data. The EX-OR gate 23 converts the first data “11” into a lower bit “0” of the second information, and the converted bit is output from the output terminal D02 as the lower bit of the storage data (step S8). In this case, the storage data read out from the memory cell 10 is “10”.

On the other hand, if it is determined in step S5 that the threshold voltage V_{T} is smaller than the threshold voltage of the transistor Tr2, it is determined that the first data stored in the memory cell 10 is “10” (step S9), and its lower bit “0” is input to the EX-OR gate 23 together with the upper bit “1” of the first data. The EX-OR gate 23 converts the first data “10” into a lower bit “1” of the second data, and the converted lower bit is output from the output terminal D02 as the lower bit of the storage data (step S10). In this case, the storage data read out from the memory cell 10 is “11”.

If the threshold voltage V_{T} is smaller than the threshold voltage of the transistor Tr1, i.e., the current of the memory cell is larger than that of the transistor Tr1, the threshold voltage V_{T} is then compared with the threshold voltage of the transistor Tr3 (step S6). If the threshold voltage V_{T} is larger than the threshold voltage of the memory cell, it is determined that the lower bit is “1” (step S11), and the bit is input to the EX-OR gate 23 together with the upper bit “0” of the first data. The EX-OR gate 23 converts the first data “01” into a lower bit “1” of the second data, and the converted bit is output from the output terminal D02 as the lower bit of the storage data (step S12). Hence, in this case, the storage data read out from the memory cell 10 is “01” equal to the first data.

In like manner, if the threshold voltage V_{T} is smaller than the threshold voltage of the transistor Tr1, i.e., the current of the memory cell is larger than that of the transistor Tr1, the threshold voltage V_{T} is compared with the threshold voltage of the transistor Tr3. If the threshold voltage V_{T} is smaller than the threshold voltage of the memory cell contrary to the above case, it is determined that the lower bit is “0” (step S13), and that bit is input to the EX-OR gate 23 together with the upper bit “0”. The EX-OR gate 23 converts the first data “00” into a lower bit “0” of the second data, and the converted bit is output from the output terminal D02 as the lower bit of the storage data (step S14). Hence, in this case, the storage data read out from the memory cell 10 is “00” equal to the first data.

In this case, in the relationship between the outputs from the terminals S01 to S03 and those from the output terminals D01 and D02, since the terminal S02 is directly connected to the output terminal D01, the output from the terminal S02 perfectly matches that (upper bit) from the output terminal D01. Owing to the arrangement of the logic gates (124 to 127), if the signal from the terminal S02, i.e., the upper bit as the output from the output terminal D01, is “1”, the signal from the terminal S01 is output from the OR gate 127. On the other hand, if the signal from the terminal S02, i.e., the upper bit as the output from the output terminal D01, is “0”, the signal from the terminal S03 is output from the OR gate 127. The signals from the terminals S02 and OR gate 127 are input to the EX-OR gate 23, and the signal from the EX-OR gate 23 is output from the output terminal D02 as the lower bit.

When the semiconductor storage device is used repetitively, the memory cells deteriorate, and their threshold voltages may drop. If a certain threshold voltage drops below the determination voltage of the neighboring threshold voltage, data errors occur. For example, upon reading, the storage data “01” is erroneously read out as “00”, “11” as “01”, “10” as “11”, and so on. In such case, errors have occurred in only one of the upper and lower bits.

When first data (00, 01, 10, 11) directly stored in the memory cells 10 are used as storage data as in the conventional device, if the threshold voltage V_{T} becomes lower than the threshold voltage (=2.5 V) of, e.g., the transistor Tr1, the storage data “10” becomes “01” as a result of data errors. At that time, data errors have occurred in both the upper and lower bits. By contrast, in the EEPROM of the third modification, data errors occur in only the lower bit, as described above. Therefore, when the EEPROM of the third modification is used, even when data errors have occurred due to deterioration of the memory cells 10, they can be confined to only single-bit errors, and error detection and error correction can be effectively performed using conventional error detection using parity error check codes and error correction using Hamming codes.

In the EEPROM of the third modification, since 2-bit binary data are used as storage data, and the respective bits that form each storage data are assigned an output order to output especially the data of the upper bit first, the data of the upper bit is specified and output by a single determination process by the transistor Tr1. More specifically, when values that the storage data can assume are aligned in turn, two groups having identical upper bits, the number of which is equal to the number of bits of the storage data are formed. Using this fact, one of the two groups, i.e., the upper bit, is specified by only a single determination process of the transistor Tr1, and the upper bit is output first.

Furthermore, according to the EEPROM of the third modification, the first data, i.e., the data to be directly stored in the memory cells 10 are obtained by inserting only the EX-OR gate 24 in the input stage of the conventional device, and data errors can be restricted to only single-bit errors by a simple arrangement, i.e., by inserting the EX-OR gate 23 in the output stage of the conventional device. Hence, even when multiple-valued storage data are lost due to data errors arising from deterioration of the memory cells 10, which have inevitably occurred after repetitive uses, error detection and error correction can be efficiently and accurately done.

In sum, according to the EEPROM of the present invention, even when multiple-valued storage data are lost due to data errors resulting from deterioration of the memory cells 10, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Fourth Modification

An EEPROM of the fourth modification will be explained below. This EEPROM has substantially the same arrangement as that of the first embodiment, except that the arrangement of the decoder circuit is slightly different from that of the first embodiment. Note that the same reference numerals denote parts corresponding to those of the EEPROM of the first embodiment, and a detailed description thereof will be omitted.

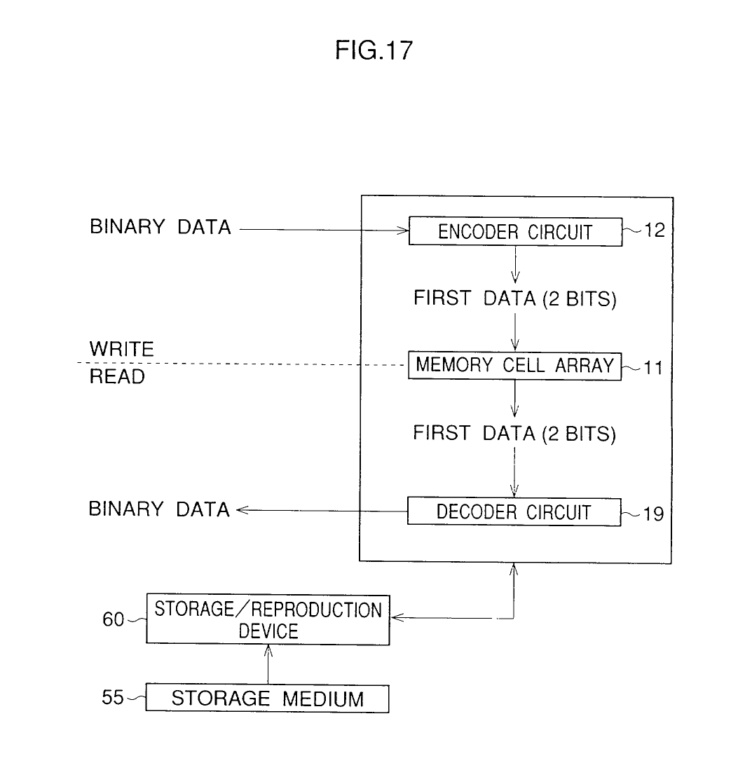

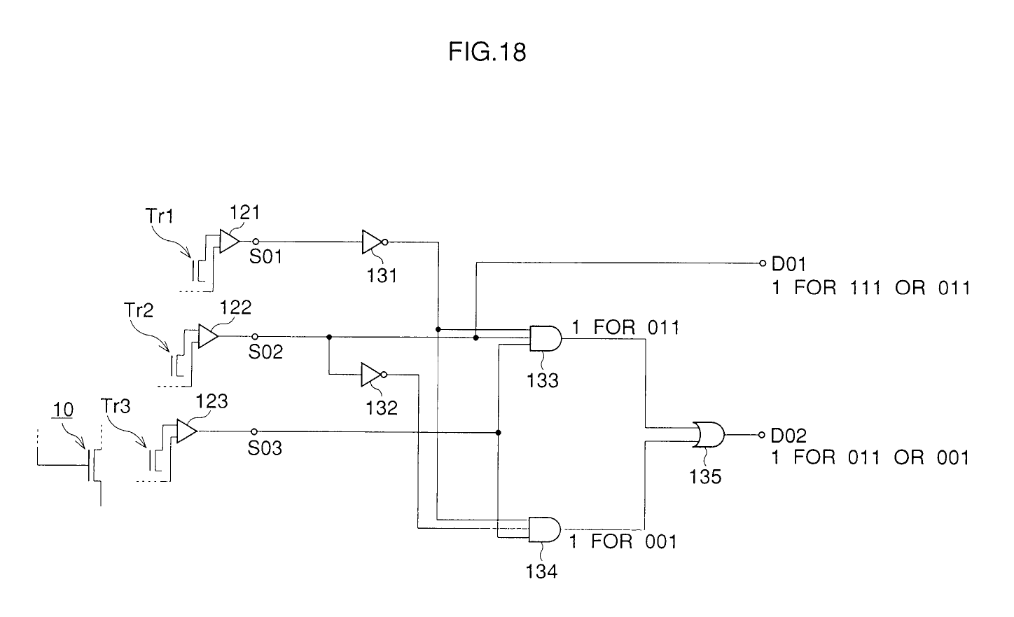

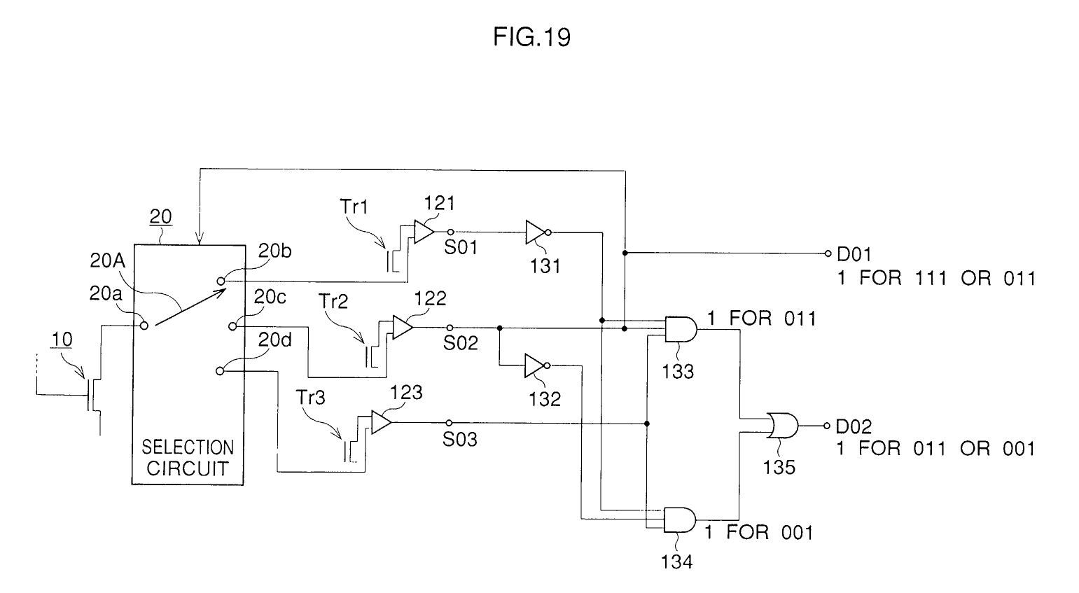

The EEPROM mainly comprises a memory cell array 11, encoder circuit unit 12, decoder circuit unit 19, and the like, as shown in FIG. 17, like in the first embodiment. The arrangement of the decoder circuit unit 19 is slightly different from the decoder circuit unit 13. That is, as shown in FIG. 18, the decoder circuit unit 19 comprises reference transistors Tr1, Tr2, and Tr3 which are connected to each memory cell 10, and have threshold voltages respectively set at 3.5 V, 2.5 V, and 1.5 V, sense amplifiers 121, 122, and 123 respectively connected to these transistors Tr1 to Tr3, terminals S01, S02, and S03 respectively connected to the sense amplifiers 121 to 123, a NOT gate 131 connected to the terminal S02, a NOT gate 132 connected to the terminal S03, an AND gate 133 directly connected to the terminals S01, S02, and S3, an AND gate 134 connected to the terminals S01 and S02 via the NOT gates 131 and 132 and directly to the terminal S03, and an OR gate 135 connected to the AND gates 133 and 134. The terminal S02 is directly connected to an output terminal D01, and the terminals S01 to S03 are connected to the OR gate. In this case, as shown in FIG. 19, a selection circuit 20 is preferably added as in the third modification. In this decoder circuit unit 19, the output terminal D01 outputs the upper bit of storage data, and an output terminal D02 the lower bit of the storage data.

The methods of writing and reading storage data using the EEPROM are the same as those in the third modification. In this case, in the relationship between the outputs from the terminals S01 to S03 and those from the output terminals D01 and D02, since the terminal S02 is directly connected to the output terminal D01, the output from the terminal S02 perfectly matches that (upper bit) from the output terminal D01. Owing to the arrangement of the logic gates (131 to 135), when the output from the terminal S02, i.e., the upper bit as the output from the output terminal D01, is “1”, if the outputs from the terminals S01 and S03 are respectively “0” and “1”, the output (lower bit) from the output terminal D02 becomes “1”; and if the outputs from the terminals S01 and S03 are respectively “1” and “1”, the output (lower bit) from the output terminal D02 becomes “0”. On the other hand, when the output from the terminal S02, i.e., the upper bit as the output from the output terminal D01, is “0”, if the outputs from the terminals S01 and S03 are respectively “0” and “1”, the output (lower bit) from the output terminal D02 becomes “1”; and if the outputs from the terminals S01 and S03 are respectively “0” and “0”, the output (lower bit) from the output terminal D02 becomes “0”.

When first data (00, 01, 10, 11) directly stored in the memory cells 10 are used as storage data as in the conventional device, if the threshold voltage V_{T} becomes lower than the threshold voltage (=2.5 V) of, e.g., the transistor Tr1, the storage data “10” becomes “01” as a result of data errors. At that time, data errors have occurred in both the upper and lower bits. By contrast, in the EEPROM of the fourth modification, data errors occur in only the lower bit, as described above. Therefore, when the EEPROM of the fourth modification is used, even when data errors have occurred due to deterioration of the memory cells 10, they can be confined to only single-bit errors, and error detection and error correction can be effectively performed using conventional error detection using parity error check codes and error correction using Hamming codes.

In the EEPROM of the fourth modification, since 2-bit binary data are used as storage data, and the respective bits that form each storage data are assigned an output order to output especially the data of the upper bit first, the data of the upper bit is specified and output by a single determination process by the transistor Tr2. More specifically, when values that the storage data can take on are aligned in turn, two groups having identical upper bits, the number of which is equal to the number of bits of the storage data are formed. Making use of this fact, one of the two groups, i.e., the upper bit, is specified by only a single determination process of the transistor Tr2, and the upper bit is output first.

Furthermore, according to this EEPROM, data errors can be restricted to only single-bit errors. Hence, even when multiple-valued storage data are lost due to data errors arising from deterioration of the memory cells 10, which have inevitably occurred after the repetitive uses, error detection and error correction can be efficiently and accurately done.

To recapitulate, according to the EEPROM of the present invention, even when multiple-valued storage data are lost due to data errors resulting from deterioration of the memory cells 10, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which obtains storage locations to be accessed in the input/output order.

In the first embodiment and its modifications, a quaternary EEPROM as a nonvolatile memory has been exemplified as a semiconductor storage device. The present invention can also be applied to a quaternary DRAM as a volatile memory, which has memory capacitors each for storing a signal charge, and an access transistor for selecting the memory capacitors, sets the memory capacitor in a charge accumulation state by applying a predetermined reference voltage to the capacitor, and stores storage data corresponding to the reference voltage.

Second Embodiment

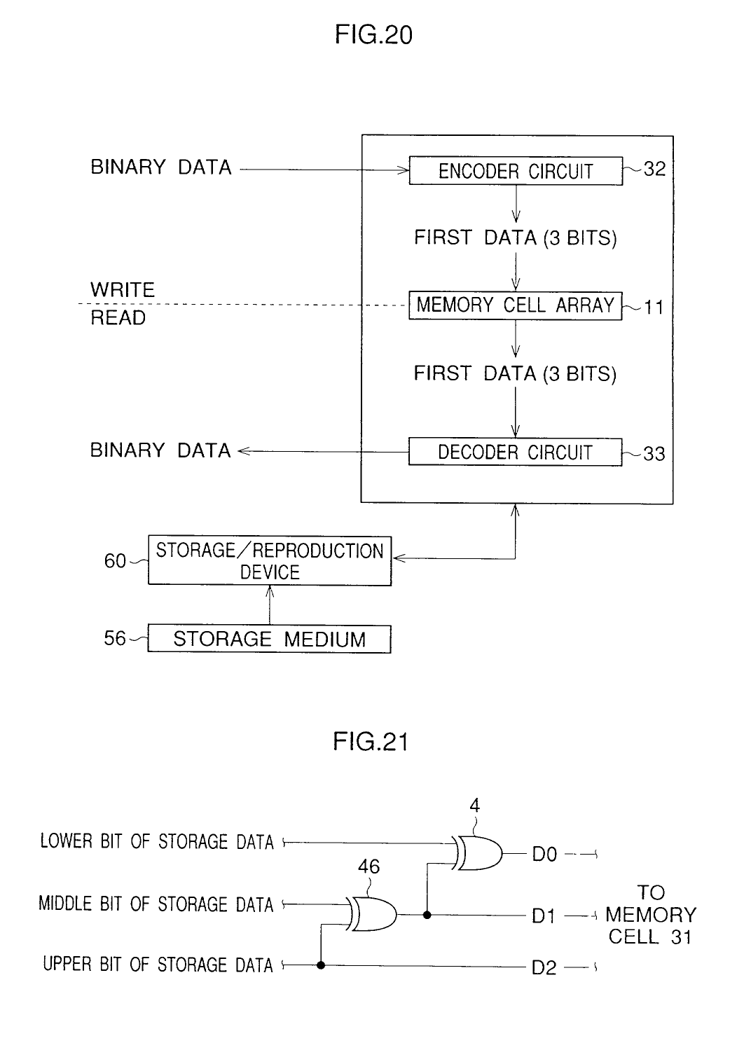

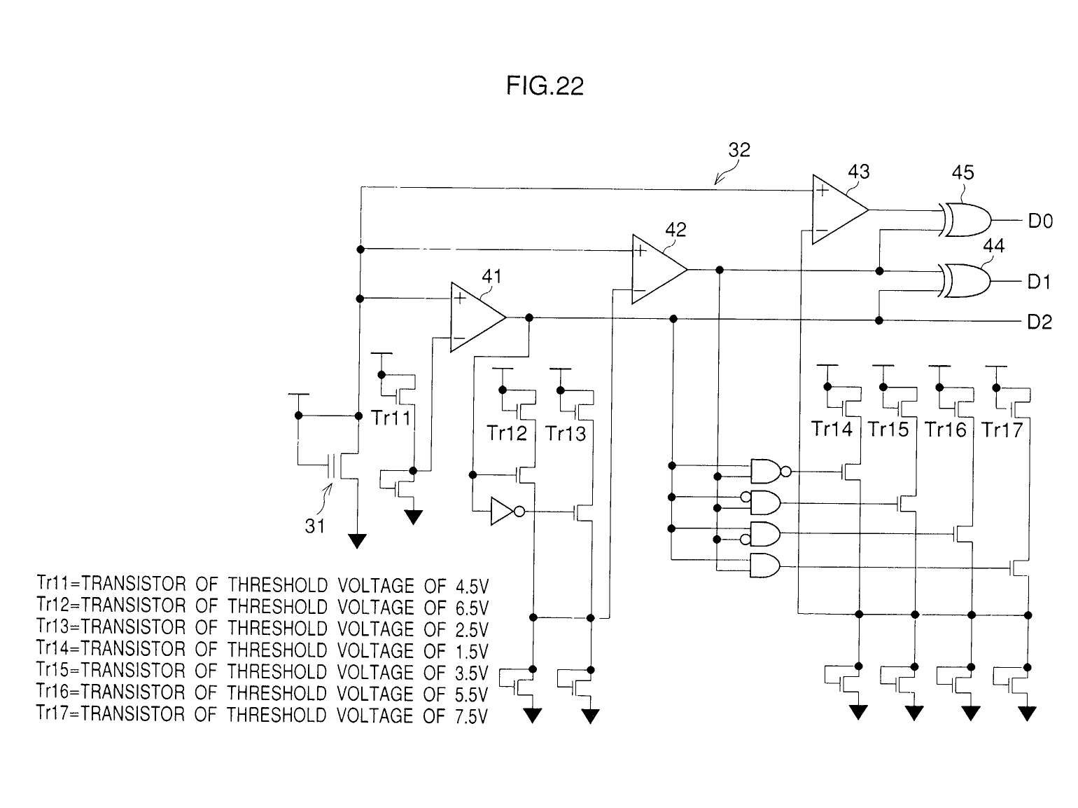

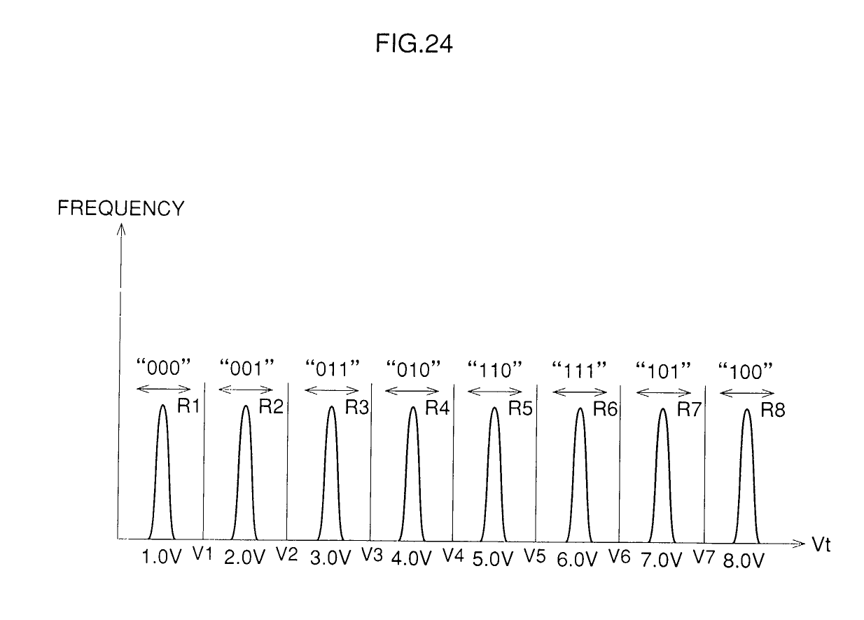

The second embodiment of the present invention will now be described. In the second embodiment, an EEPROM as a nonvolatile semiconductor storage device that can store eight-valued (=3 bits) data will be exemplified. FIG. 20 is a block diagram showing the arrangement of principal part of the EEPROM of the second embodiment, FIG. 21 is a circuit diagram showing only the specific portion of an encoder circuit unit, FIG. 22 is a circuit diagram showing only the specific portion of a decoder circuit unit, and FIG. 24 is a graph showing the distribution of threshold values of the memory cells. Note that the same reference numerals denote the same parts as those in the EEPROM of the first embodiment.

As shown in FIG. 20, the EEPROM of the second embodiment comprises a memory cell array 11 as a matrix of a plurality of memory cells 31, an encoder circuit unit 32 for storing input storage data in the memory cells 31, and a decoder circuit unit 33 for detecting storage data in the selected memory cell 31, and outputting the detected storage data.

As in each memory cell 10 of the first embodiment, each memory cell 31 has a source 3 and drain 4 as a pair of impurity diffusion layers, which are formed by doping an n-type impurity such as phosphorus (P), arsenic (As), or the like into the surface region of an element active region 2 defined by an element isolation structure such as a field oxide film or the like on a p-type silicon semiconductor substrate 1, an isolated, island-like floating gate 6 which is patterned via a tunnel oxide film 5 on a channel region C between the source 3 and drain 4, and a control gate 8 which is patterned on the floating gate 6 via a dielectric film 7 consisting of, e.g., an ONO film, and is capacitively coupled to the floating gate 6.

The encoder circuit unit 32 comprises EX-OR gates 46 and 47, as shown in FIG. 21, and forms storage data by breaking up input binary data in units of 3 bits. In this encoder circuit unit 32, storage data are converted into first data by the EX-OR gates 46 and 47, an output terminal D2 outputs the upper bit of each first data, an output terminal D1 outputs the middle bit of the first data, and an output terminal D0 outputs the lower bit of the first data. In this way, the first data is stored in each memory cell 31 in correspondence with a predetermined threshold voltage.

As shown in FIG. 22, the decoder circuit unit 33 comprises reference transistors Tr11, Tr12, Tr13, Tr14, Tr15, Tr16, and Tr17 respectively having threshold voltages of 4.5 V, 6.5 V, 2.5 V, 1.5 V, 3.5 V, 5.5 V, and 7.5 V, sense amplifiers 41, 42, and 43, and EX-OR gates 44 and 45. The bit line of each memory cell 31 is connected to the + terminals of the sense amplifiers 41, 42, and 43, the transistor Tr11 is connected to the − terminal of the sense amplifier 41, the transistors Tr12 and Tr13 are connected to the − terminal of the sense amplifier 42, and the transistors Tr14, Tr15, Tr16, and Tr17 are connected to the − terminal of the sense amplifier 43. The EX-OR gate 44 is connected to receive signals from the sense amplifiers 41 and 42, and the EX-OR gate 45 is connected to receive signals from the sense amplifiers 42 and 43. In this decoder circuit unit 33, an output terminal D2 outputs the upper bit of storage data (second data), an output terminal D1 outputs the middle bit of the storage data, and an output terminal D0 outputs the lower bit of the storage data.

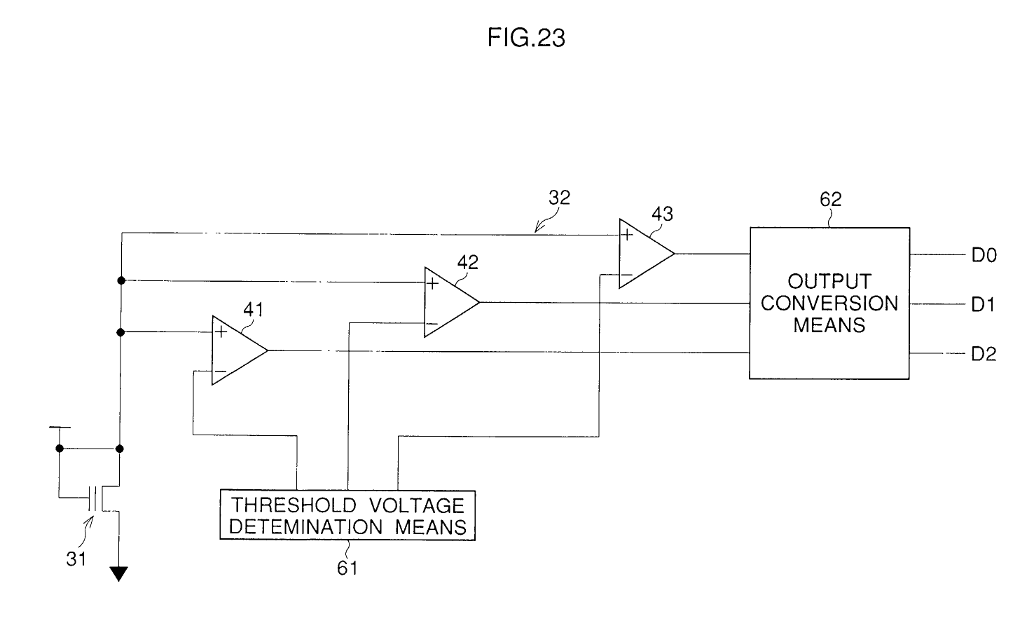

Note that the reference transistors Tr11 to Tr17 form a memory cell array used for determining the threshold voltage of each memory cell 31, and can be considered as a threshold voltage determination means 61, as shown in, e.g., FIG. 23. As will be described later, the EX-OR gates 44 and 45 can be considered as an output conversion means 62 for restricting errors to only single-bit errors even when they have occurred in 3-bit binary data output from each memory cell 31. These threshold voltage determination means 61 and output conversion means 62 may have arrangements different from those mentioned above as long as they have the same functions and can provide the same effects.

The EEPROM can store first data corresponding to threshold voltages of eight values (1 V, 2 V, 3 V, 4 V, 5 V, 6 V, 7 V, 8 V) in the respective memory cells 31 upon operation of the encoder circuit unit 32, and can store eight-valued first data (“000”, “001”, “010”, “011”, “100”, “101”, “110”, “111”) so that the value of the first data becomes larger as the threshold voltage becomes higher. Upon reading, the decoder circuit unit 33 assigns bits so that neighboring first data have only one different bit in their 3-bit architecture to convert the first data into eight-valued second data (“000”, “001”, “011”, “010”, “110”, “111”, “101”, “100”),and the second data are output as storage data of the memory cells 31. More specifically, the operation of the encoder circuit unit 32 corresponds to inverse conversion (inverse assignment) of the operation of the decoder circuit unit 33, and 3-bit storage data formed by the encoder circuit unit 32 always matches 3-bit storage data output from the decoder circuit unit 33 unless the memory cells 31 have suffered data errors due to some causes.

In the second embodiment, the second data are assigned like (“000”, “001”, “011”, “010”, “110”, “111”, “101”, “100”). Alternatively, the second data need only be obtained by assigning bits so that neighboring data have only one different bit (one digit). For example, second data may be assigned like (“000”, “001”, “011”, “010”, “110”, “100”, “101”, “111”). Bit assignment in this case can also be realized using EX-OR gates.

The method of writing storage data in the EEPROM will be explained below.

When first data “100” converted from storage data “110” by the EX-OR gates 46 and 47 is to be written, the drain 4 of the memory cell is set at the ground potential, the source 3 is opened, and a voltage of approximately 30 V is applied to the control gate 8. At this time, electrons are injected from the drain 4 into the floating gate 6 via the tunnel oxide film 5, and the threshold voltage (V_{T}) shifts in the positive direction. The threshold voltage of the memory cell then rises to about 8 V. This storage state is defined as “100”.

When first data “101” converted from storage data “111” by the EX-OR gates 46 and 47 is to be written, the drain 4 of the memory cell is set at the ground potential, the source 3 is opened, and a voltage of about 28 V is applied to the control gate 8. At this time, electrons are injected from the drain 4 into the floating gate 6 via the tunnel oxide film 5, and the threshold voltage of the memory cell then becomes about 7 V. This storage state is defined as “101”.

When first data “111” converted from storage data “100” by the EX-OR gates 46 and 47 is to be written, the drain 4 of the memory cell is set at the ground potential, the source 3 is opened, and a voltage around 26 V is applied to the control gate 8. At this time, electrons are injected from the drain 4 into the floating gate 6 via the tunnel oxide film 5, and the threshold voltage of the memory cell then becomes about 6 V. This storage state is defined as “111”.

When first data “110” converted from storage data “101” by the EX-OR gates 46 and 47 is to be written, the drain 4 of the memory cell is set at the ground potential, the source 3 is opened, and a voltage in the neighborhood of 24 V is applied to the control gate 8. At this time, electrons are injected from the drain 4 into the floating gate 6 via the tunnel oxide film 5, and the threshold voltage of the memory cell then becomes about 5 V. This storage state is defined as “110”.

When first data “010” converted from storage data “011” by the EX-OR gates 46 and 47 is to be written, the drain 4 of the memory cell is set at the ground potential, the source 3 is opened, and a voltage of about 22 V is applied to the control gate 8. At this time, electrons are injected from the drain 4 into the floating gate 6 via the tunnel oxide film 5, and the threshold voltage of the memory cell then becomes about 4 V. This storage state is defined as “010”.

When first data “011” converted from storage data “010” by the EX-OR gates 46 and 47 is to be written, the drain 4 of the memory cell is set at the ground potential, the source 3 is opened, and a voltage near 20 V is applied to the control gate 8. At this time, electrons are injected from the drain 4 into the floating gate 6 via the tunnel oxide film 5, and the threshold voltage of the memory cell then becomes about 3 V. This storage state is defined as “011”.

When first data “001” equal to storage data “001” even via the EX-OR gates 46 and 47 is to be written, the drain 4 of the memory cell is set at the ground potential, the source 3 is opened, and a voltage of about 18 V is applied to the control gate 8. At this time, electrons are injected from the drain 4 into the floating gate 6 via the tunnel oxide film 5, and the threshold voltage of the memory cell then becomes about 2 V. This storage state is defined as “001”.

When first data “000” equal to storage data “000” even via the EX-OR gates 46 and 47 is to be written, a voltage of about 10 V is applied to the drain 4 of the memory cell to open the source 3 and to set the control gate 8 at the ground potential. At this time, electrons injected into the floating gate 6 are cleared from the drain 4, and the threshold voltage of the memory cell becomes about 1 V. This storage state is defined as “000”. Table 4 below shows the above-mentioned conversion states from storage data into first data by the EX-OR gates 46 and 47.

TABLE 4

| | | | | | | | | |
|---|---|---|---|---|---|---|---|---|
| Storage Device | “000” | “001” | “011” | “010” | “110” | “111” | “101” | “100” |
| First Data | “000” | “001” | “010” | “011” | “100” | “101” | “110” | “111” |

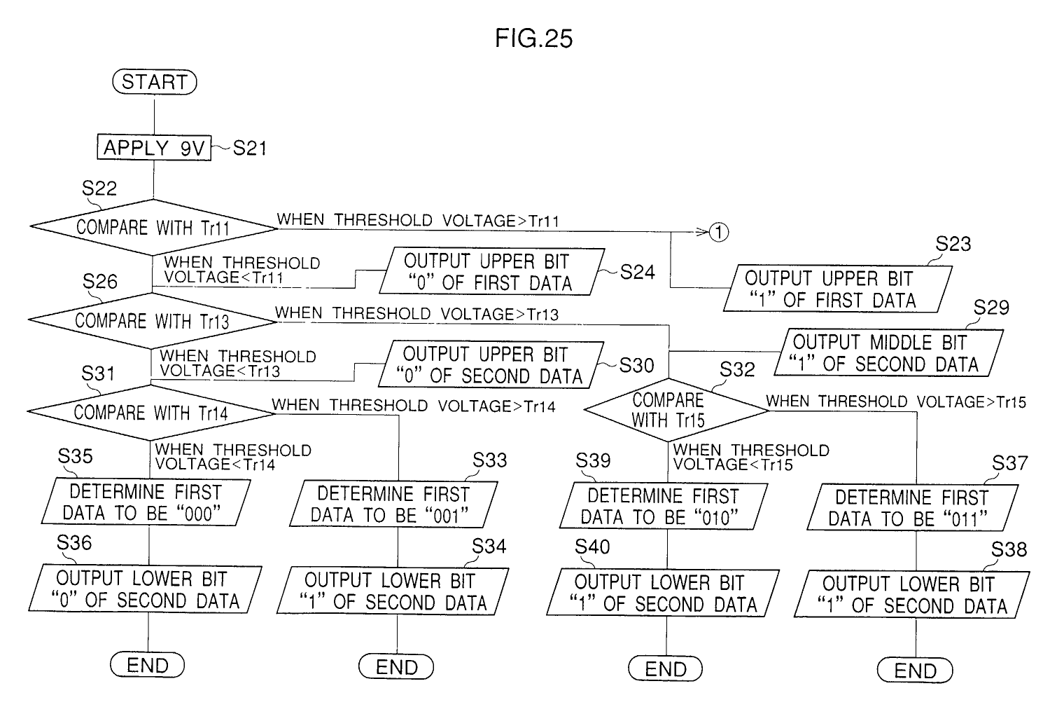

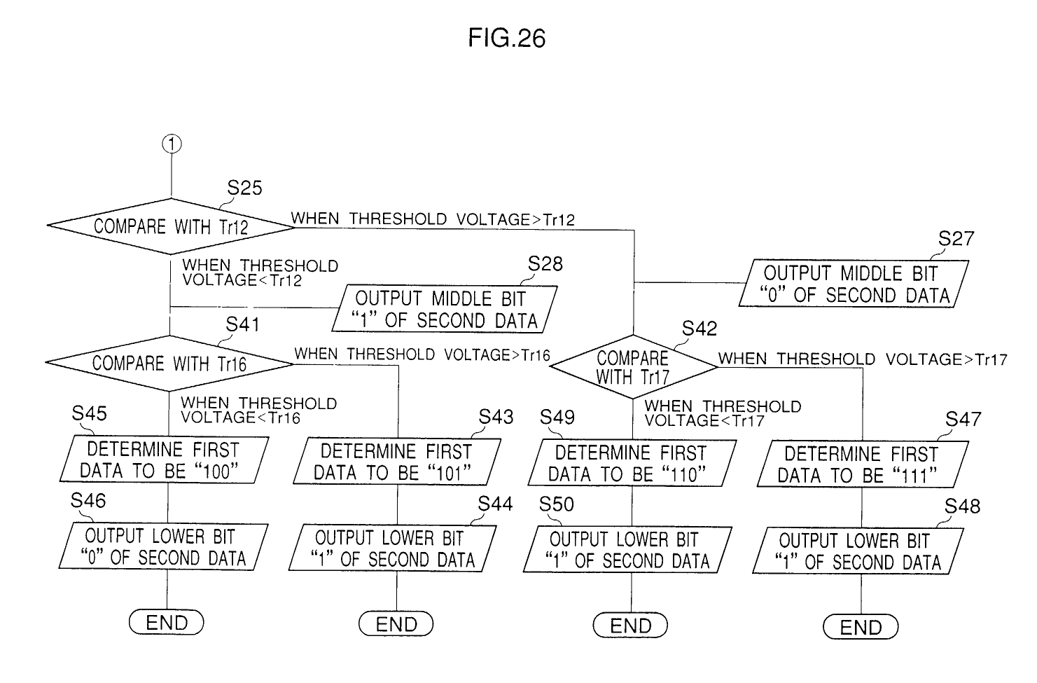

Furthermore, data is read out from the respective memory cells 32 of the EEPROM as follows. FIGS. 25 and 26 are flow charts showing the respective steps upon reading.

As for storage data read out from the selected memory cell 31, the threshold voltages (V_{T}) have a distribution with eight peaks (eight values) at about 1 V, 2 V, 3 V, 4 V, 5 V, 6 V, 7 V, and 8 V, as shown in FIG. 24. In FIG. 24, when the threshold voltage V_{T} is detected within the range R1, the storage state is “000”; when the threshold voltage V_{T} is detected within the range R2, the storage state is “001”; when the threshold voltage V_{T} is detected within the range R3, the storage state is “011”; and when the threshold voltage V_{T} is detected within the range R4, the storage state is “010”. Likewise, when the threshold voltage V_{T} is detected within the range R5, the storage state is “110”; when the threshold voltage V_{T} is detected within the range R6, the storage state is “111”; when the threshold voltage V_{T} is detected within the range R7, the storage state is “101”; and when the threshold voltage V_{T} is detected within the range R8, the storage state is “100”.

Hence, whether the storage state is “R1, R2, R3, or R4”, or “R5, R6, R7, or R8”, i.e., whether the upper bit of the first data stored in the memory cell 31 is “0” or “1” is determined first using the transistor Tr11. In this case, a voltage around 9 V is applied to the source 3 and drain 4, and the gate electrode 6 (step S21). The drain current is then detected by the sense amplifier 41, and the threshold voltage V_{T} is compared with the threshold voltage of the transistor Tr11 (step S22). At this time, if the threshold voltage V_{T} is larger than the threshold voltage of the transistor Tr11, i.e., if the current of the memory cell is smaller than that of the transistor Tr11, it is determined that the upper bit is “1”; if the threshold voltage V_{T} is smaller than the threshold voltage of the transistor Tr11, i.e., if the current of the memory cell is larger than that of the transistor Tr11, it is determined that the upper bit is “0”. The determined upper bit is then output from the sense amplifier 41. The upper bit of the first data is equal to that of the second data, and this signal is output from the output terminal D2 as the upper bit of the storage data prior to the middle and lower bits (steps S23 and S24).

Subsequently, it is checked if the middle bit of the first data stored in the memory cell 31 is “0” or “1”. That is, if the threshold voltage V_{T} is larger than the threshold voltage of the transistor Tr11, a similar read is done using the transistor Tr12, and the current which flows in the memory cell is compared with that which flows in the transistor Tr12 (step S25). On the other hand, if the threshold voltage V_{T} is smaller than the threshold voltage of the transistor Tr11, a similar read is done using the transistor Tr13, and the current which flows in the memory cell is compared with that which flows in the transistor Tr13 (step S26).

If it is determined in step S25 that the threshold voltage V_{T} is larger than the threshold voltage of the transistor Tr12, i.e., the current which flows in the memory cell is smaller than that which flows in the transistor Tr12, it is determined that the middle bit of the first data is “1”, and the determined bit is output from the sense amplifier 42. The middle bit “1” is input to the EX-OR gate 44 together with the upper bit “1” of the first data. The EX-OR gate 44 converts data “11” into a middle bit “0” of the second data, and outputs the converted bit as the middle bit of the storage data from the output terminal D1 (step S27).

On the other hand, if it is determined in step S25 that the threshold voltage V_{T} is smaller than the threshold voltage of the transistor Tr12, i.e., the current which flows in the memory cell is larger than that which flows in the transistor Tr12, it is determined that the middle bit of the first data is “0”, and is output from the sense amplifier 42. The middle bit “0” is input to the EX-OR gate 44 together with the upper bit “1” of the first data. The EX-OR gate 44 converts data “10” into a middle bit “1” of the second data, and outputs the converted bit as the middle bit of the storage data from the output terminal D1 (step S28).

If it is determined in step S26 that the threshold voltage V_{T} is larger than the threshold voltage of the transistor Tr13, i.e., the current which flows in the memory cell is smaller than that which flows in the transistor Tr13, it is determined that the middle bit of the first data is “1”, and the determined bit is output from the sense amplifier 42. The middle bit “1” is input to the EX-OR gate 44 together with the upper bit “0” of the first data. The EX-OR gate 44 converts data “01” into a middle bit “1” of the second data, and outputs the converted bit as the middle bit of the storage data from the output terminal D1 (step S29).

On the other hand, if it is determined in step S26 that the threshold voltage V_{T} is smaller than the threshold voltage of the transistor Tr13, i.e., the current which flows in the memory cell is larger than that which flows in the transistor Tr13, it is determined that the middle bit of the first data is “0”, and the determined bit is output from the sense amplifier 42. The middle bit “0” is input to the EX-OR gate 44 together with the upper bit “0” of the first data. The EX-OR gate 44 converts data “00” into a middle bit “0” of the second data, and outputs the converted bit as the middle bit of the storage data from the output terminal D1 (step S30).

Subsequently, if the threshold voltage V_{T} is smaller than the threshold voltage of the transistor Tr13, a similar read is done using the transistor Tr14, and the currents of the memory cell and transistor Tr14 are compared with each other (step S31). On the other hand, if the threshold voltage V_{T} is larger than the threshold voltage of the transistor Tr13, a similar read is done using the transistor Tr15, and the currents of the memory cell and transistor Tr15 are compared with each other (step S32).

If it is determined in step S31 that the threshold voltage V_{T} is larger than the threshold voltage of the transistor Tr14, i.e., the current which flows in the memory cell is smaller than that which flows in the transistor Tr14, it is determined that the lower bit is “1”, i.e., the first data stored in the memory cell 31 is “001” (step S33), and that bit is output from the sense amplifier 43. The lower bit “1” is input to the EX-OR gate 45 together with the middle bit “0” of the first data. The EX-OR gate 45 converts the data “01” into a lower bit “1” of the second data, and outputs the converted bit as the lower bit of the storage data from the output terminal D0 (step S34). Therefore, in this case, the storage data (second data) read out from the memory cell 31 is “001” equal to the first data.

On the other hand, if it is determined in step S31 that the threshold voltage V_{T} is smaller than the threshold voltage of the transistor Tr14, i.e., the current which flows in the memory cell is larger than that which flows in the transistor Tr14, it is determined that the lower bit is “0”, i.e., the first data stored in the memory cell 31 is “000” (step S35), and that bit is output from the sense amplifier 43. The lower bit “0” is input to the EX-OR gate 45 together with the middle bit “0” of the first data. The EX-OR gate 45 converts the data “00” into a lower bit “0” of the second data, and outputs the converted bit as the lower bit of the storage data from the output terminal D0 (step S36). Therefore, in this case, the storage data (second data) read out from the memory cell 31 is “000” equal to the first data.

If it is determined in step S32 that the threshold voltage V_{T} is larger than the threshold voltage of the transistor Tr15, i.e., the current which flows in the memory cell is smaller than that which flows in the transistor Tr15, it is determined that the lower bit is “1”, i.e., the first data stored in the memory cell 31 is “011” (step S37), and that bit is output from the sense amplifier 43. The lower bit “1” is input to the EX-OR gate 45 together with the middle bit “1” of the first data. The EX-OR gate 45 converts the data “11” into a lower bit “0” of the second data, and outputs the converted bit as the lower bit of the storage data from the output terminal D0 (step S38). Therefore, in this case, the storage data (second data) read out from the memory cell 31 is “010”.

On the other hand, if it is determined in step S32 that the threshold voltage V_{T} is smaller than the threshold voltage of the transistor Tr15, i.e., the current which flows in the memory cell is larger than that which flows in the transistor Tr15, it is determined that the lower bit is “0”, i.e., the first data stored in the memory cell 31 is “010” (step S39), and that bit is output from the sense amplifier 43. The lower bit “0” is input to the EX-OR gate 45 together with the middle bit “1” of the first data. The EX-OR gate 45 converts the data “10” into a lower bit “1” of the second data, and outputs the converted bit as the lower bit of the storage data from the output terminal D0 (step S40). Therefore, in this case, the storage data (second data) read out from the memory cell 31 is “011”.

If the threshold voltage V_{T} is smaller than the threshold voltage of the transistor Tr12, a similar read is done using the transistor Tr16 to compare the currents of the memory cell and transistor Tr16 with each other (step S41); if the threshold voltage V_{T} is larger than the threshold voltage of the transistor Tr12, a similar read is done using the transistor Tr17 to compare the currents of the memory cell and transistor Tr17 with each other (step S42).

If it is determined in step S41 that the threshold voltage V_{T} is larger than the threshold voltage of the transistor Tr16, i.e., the current which flows in the memory cell is smaller than that which flows in the transistor Tr16, it is determined that the lower bit is “1”, i.e., the first data stored in the memory cell 31 is “101” (step S43), and that bit is output from the sense amplifier 43. The lower bit “1” is input to the EX-OR gate 45 together with the middle bit “0” of the first data. The EX-OR gate 45 converts the data “01” into a lower bit “1” of the second data, and outputs the converted bit as the lower bit of the storage data from the output terminal D0 (step S44). Therefore, in this case, as the middle bit of the converted storage data is “1”, the storage data (second data) read out from the memory cell 31 is “111”.

On the other hand, if it is determined in step S41 that the threshold voltage V_{T} is smaller than the threshold voltage of the transistor Tr16, i.e., the current which flows in the memory cell is larger than that which flows in the transistor Tr16, it is determined that the lower bit is “0”, i.e., the first data stored in the memory cell 31 is “100” (step S45), and that bit is output from the sense amplifier 43. The lower bit “0” is input to the EX-OR gate 45 together with the middle bit “0” of the first data. The EX-OR gate 45 converts the data “00” into a lower bit “0” of the second data, and outputs the converted bit as the lower bit of the storage data from the output terminal D0 (step S46). Therefore, in this case, as the middle bit of the converted storage data is “1”, the storage data (second data) read out from the memory cell 31 is “110”.

If it is determined in step S42 that the threshold voltage V_{T} is larger than the threshold voltage of the transistor Tr17, i.e., the current which flows in the memory cell is smaller than that which flows in the transistor Tr17, it is determined that the lower bit is “1”, i.e., the first data stored in the memory cell 31 is “111” (step S47), and that bit is output from the sense amplifier 43. The lower bit “1” is input to the EX-OR gate 45 together with the middle bit “1” of the first data. The EX-OR gate 45 converts the data “11” into a lower bit “0” of the second data, and outputs the converted bit as the lower bit of the storage data from the output terminal D0 (step S48). Therefore, in this case, as the middle bit of the converted storage data is “0”, the storage data (second data) read out from the memory cell 31 is “100”.

On the other hand, if the threshold voltage V_{T} is smaller than the threshold voltage of the transistor Tr17, i.e., the current which flows in the memory cell is larger than that which flows in the transistor Tr17, it is determined that the lower bit is “0”, i.e., the first data stored in the memory cell 31 is “110” (step S49), and that bit is output from the sense amplifier 43. The lower bit “0” is input to the EX-OR gate 45 together with the middle bit “1” of the first data. The EX-OR gate 45 converts the data “10” into a lower bit “1” of the second data, and outputs the converted bit as the lower bit of the storage data from the output terminal D0 (step S50). Therefore, in this case, as the middle bit of the converted storage data is “0”, the storage data (second data) read out from the memory cell 31 is “101”. Table 5 below summarizes the above-mentioned conversion from the first data to the second data by the EX-OR gate 44 and 45.

TABLE 5

| | | | | | | | | |
|---|---|---|---|---|---|---|---|---|
| First Data | “000” | “001” | “010” | “011” | “100” | “101” | “110” | “111” |
| First Data | “000” | “001” | “011” | “010” | “110” | “111” | “101” | “100” |

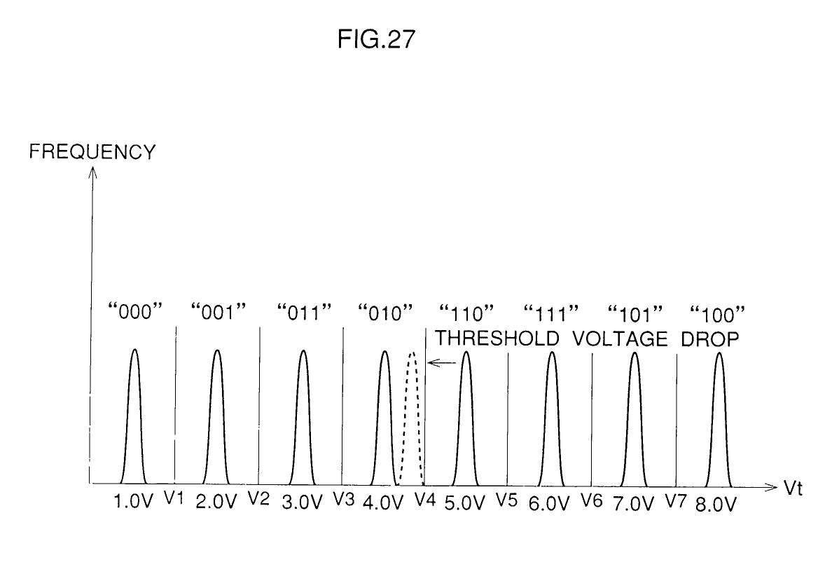

When the EEPROM is used repetitively, the memory cells deteriorate, and their threshold voltages may drop. If a certain threshold voltage drops below the determination voltage of the neighboring threshold voltage, data errors occur. For example, upon reading, the storage data “001” is erroneously read out as “000”, “011” as “001”, “010” as “011”, “110” as “010”, “111” as “110”, “101” as “111”, “100” as “101”, and so on. In such case, data errors have occurred in only one of the upper and lower bits. For example, FIG. 27 shows the case wherein the threshold voltage V_{T} corresponding to the storage data “111” becomes lower than the threshold voltage (=4.5 V) of the transistor Tr11, i.e., when the storage data “110” is read out as “010” as a result of data errors.

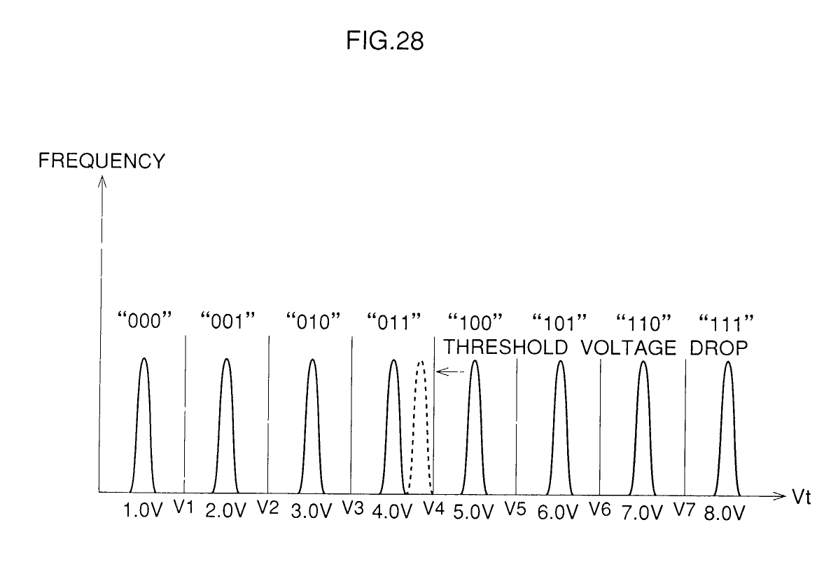

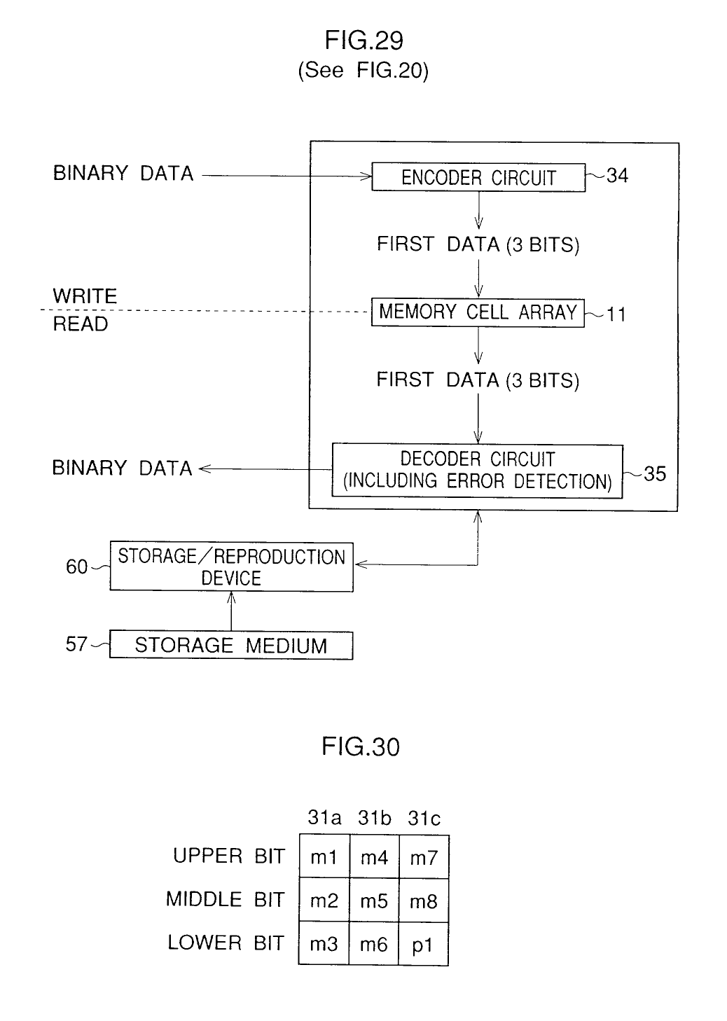

When first data (000, 001, 010, 011, 100, 101, 110, 111) directly stored in the memory cells 31 are used as storage data as in the conventional device, if the threshold voltage V_{T} becomes lower than the threshold voltage (=4.5 V) of the transistor Tr11, as shown in, e.g., FIG. 28, the storage data “100” is read out as “011” as a result of data errors. At that time, data errors have occurred in all the upper, middle, and, lower bits. By contrast, in the EEPROM of the second embodiment, data errors occur in only one bit, as described above. Therefore, when the EEPROM of the second embodiment is used, even when data errors occur due to deterioration of the memory cells 31, they can be restricted to only single-bit errors, and error detection and error correction can be effectively performed using conventional error detection using parity error check codes and error correction using Hamming codes.

Hence, according to the EEPROM of the second embodiment, even when multiple-valued storage data are lost due to data errors arising from deterioration of the memory cells 31, which have inevitably occurred after repetitive uses, error detection and error correction can be efficiently and accurately done.

In the EEPROM of the second embodiment, since 3-bit binary data are used as storage data, and the respective bits that form each storage data are assigned an output order to output especially the data of the upper bit first, the data of the upper bit is specified and output by a single determination process by the transistor Tr11. More specifically, when values that the storage data can assume are aligned in turn, two groups having identical upper bits, the number of which is equal to the number of bits of the storage data are formed. Using this fact, one of the two groups, i.e., the upper bit, is specified by only a single determination process of the transistor Tr11, and the upper bit is output first.

Furthermore, according to the EEPROM of the second embodiment, the first data, i.e., the data to be directly stored in the memory cells 31 are obtained by inserting only the EX-OR gates 46 and 47 in the input stage of the conventional device, and data errors can be limited to only single-bit errors by a simple arrangement, i.e., by inserting the EX-OR gates 44 and 45 in the output stage of the conventional device. Hence, even when multiple-valued storage data are lost due to data errors resulting from deterioration of the memory cells 31, which have inevitably occurred after repetitive uses, error detection and error correction can be efficiently and accurately done.

In this way, according to the EEPROM of the second embodiment, even when multiple-valued storage data are lost due to data errors arising from deterioration of the memory cells 31, which have inevitably occurred after repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Some modifications of the EEPROM of the second embodiment will be explained below.

First Modification

An EEPROM of the first modification will be explained below. This EEPROM has substantially the same arrangement as that of the second embodiment. In this modification, a case will be exemplified wherein a parity bit for error detection is added to storage data. Note that the same reference numerals denote parts corresponding to those of the EEPROM of the second embodiment, and a detailed description thereof will be omitted.

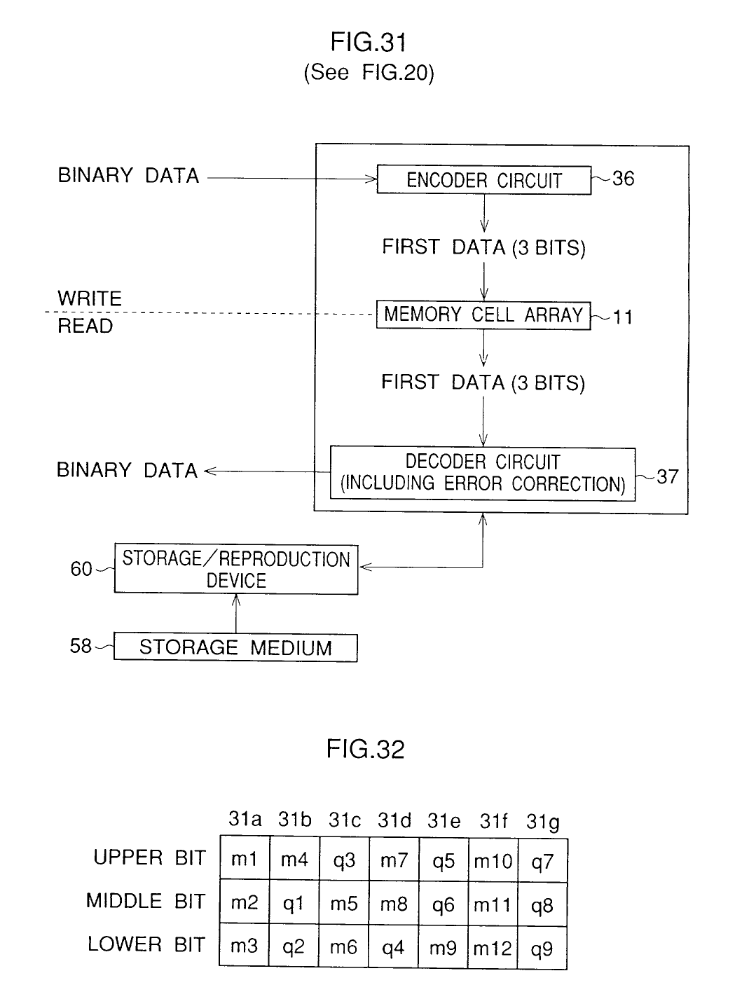

The EEPROM mainly comprises a memory cell array 11, encoder circuit unit 34, and decoder circuit unit 35, as shown in FIG. 29, like in the second embodiment. In this modification, a parity bit generation function is added to the encoder circuit unit 34, and an error detection function is added to the decoder circuit unit 35, unlike in the second embodiment.

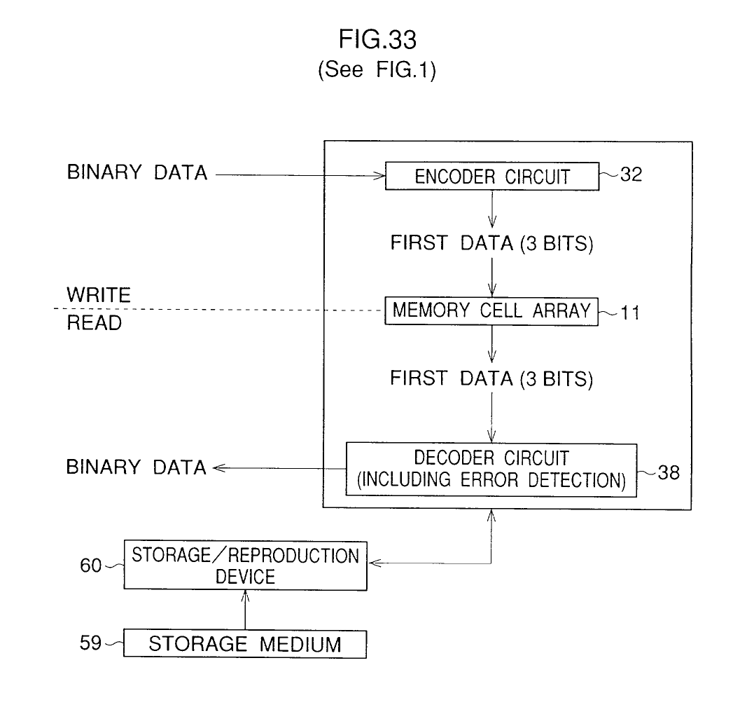

More specifically, the encoder circuit unit 34 comprises EX-OR gates 46 and 47, and adds one parity bit to, e.g., every 8 bits of input binary data. In this case, a data sequence is formed by 9 bits, i.e., the sum of a total of 8 information bits and a parity bit, so that the number of “1” s always becomes an odd number (an example of odd parity). After the encoder circuit unit 34 forms a data sequence by adding one parity bit to every 8 bits of input binary data, it converts the data sequence into first data via the EX-OR gates 46 and 47 as in the second embodiment, and the first data are stored in three memory cells 31. More specifically, as shown in FIG. 30, memory cells 31a, 31b, and 31c sequentially store first data (m1, m2 . . . , m8, p1). Note that m1 to m8 are information bits, and p1 is a parity bit.

By adding the parity bit, upon reading out second data from the memory cells 31 via the decoder circuit unit 35, if the reconstructed 9-bit second data includes an odd number of “1” s, it is determined that the second data has no errors; if the second data includes an even number of “1” s, it is determined that the second data has errors.

Normally, in a parity check based on odd parity, if data errors have occurred in two or more bits in 8-bit binary data, it becomes impossible to perform accurate determination. By contrast, in the EEPROM of the first modification, even when errors have occurred in the first data stored in one memory cell, e.g., data “100” becomes “011” as a result of data errors, data “110” merely becomes “010” as a result of data errors in the readout second data, and errors have occurred in only one bit. As for continuous storage data (for 8 bits in this case), since data errors are unlikely to occur in the storage data in two or more memory cells 31, such case can be ignored. Hence, error detection of the storage data can be done with sufficiently high accuracy by this parity check.

In the EEPROM of the first modification, since 3-bit binary data are used as storage data, and the respective bits that form each storage data are assigned an output order to output especially the data of the upper bit first, the data of the upper bit is specified and output by a single determination process by the transistor Tr11. More specifically, when values that the storage data can take on are aligned in turn, two groups having identical upper bits, the number of which is equal to the number of bits of the storage data are formed. Making use of this fact, one of the two groups, i.e., the upper bit, is specified by only a single determination process of the transistor Tr11, and the upper bit is output first.

Furthermore, according to the EEPROM of the first modification, the first data, i.e., the data to be directly stored in the memory cells 31 are obtained by inserting only the EX-OR gates 46 and 47 in the input stage of the conventional device, and data errors can be restricted to only single-bit errors by a simple arrangement, i.e., by inserting the EX-OR gates 44 and 45 in the output stage of the conventional device. Hence, even when multiple-valued storage data are lost due to data errors caused by deterioration of the memory cells 31, which have inevitably occurred after repetitive uses, error detection and error correction can be efficiently and accurately done.

In sum, according to the EEPROM of the first modification, even when multiple-valued storage data are lost due to data errors arising from deterioration of the memory cells 31, which have inevitably occurred after repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Second Modification

An EEPROM of the second modification will be explained below. This EEPROM has substantially the same arrangement as that of the second embodiment. In this modification, a case will be exemplified wherein redundant bits for error correction are added to storage data. Note that the same reference numerals denote parts corresponding to those of the EEPROM of the second embodiment, and a detailed description thereof will be omitted.

The EEPROM mainly comprises a memory cell array 11, encoder circuit unit 36, and decoder circuit unit 37, as shown in FIG. 31, like in the second embodiment. However, unlike in the second embodiment, a function of adding redundant bits based on Hamming coding is added to the encoder circuit unit 36, and an error correction function is added to the decoder circuit unit 37.

More specifically, the encoder circuit unit 36 comprises EX-OR gates 46 and 47, segments input binary data in units of 4 bits, forms three redundant bits from such 4-bit data by Hamming coding, and adds the redundant bits to the information bits to form a 7-bit data sequence. In this case, after the data sequence is converted into first data via the EX-OR gates 46 and 47 as in the second embodiment, first data (m1, m2, m3, m4, q1, q2, q3), (m5, m6, m7, m8, q4, q5, q6), (m9, m10, m11, m12, q7, q8, q9) are respectively stored in seven bits, i.e., memory cells 31a and 31b and the upper bit of a memory cell 31c, the middle and lower bits of the memory cell 31c, a memory cell 31d, and the upper and middle bits of a memory cell 31e, and the lower bit of the memory cell 31e, and memory cells 31f and 31g, in units of seven memory cells, as shown in FIG. 32. Note that m1 to m12 are information bits, and q1 to q9 are redundant bits.

Using such first data, upon reading out second data from the memory cells 31 via the decoder circuit unit 37, error correction is done using the reconstructed 7-bit second data. Of course, if no errors occur, the decoder circuit unit 37 outputs correct storage data.

Normally, in Hamming coding using a data sequence obtained by adding three redundant bits to four storage bits, if data errors have occurred in two bits or more of 7-bit binary data, it becomes impossible to perform accurate determination. To the contrary, in the EEPROM of the second modification, even when errors have occurred in the first data stored in one memory cell, e.g., data “100” becomes “011” as a result of data errors, data “110” merely becomes “010” as a result of data errors in the readout second data, and errors have occurred in only one bit. As for continuous storage data (for 7 bits in this case), since data errors are unlikely to occur in the storage data in two or more memory cells 31, such case can be ignored. Hence, error correction of the storage data can be done with sufficiently high accuracy by this Hamming coding.

In the EEPROM of the second modification, since 3-bit binary data are used as storage data, and the respective bits that construct each storage data are assigned an output order to output especially the data of the upper bit first, the data of the upper bit is specified and output by a single determination process by the transistor Tr11. More specifically, when values that the storage data can assume are aligned in turn, two groups having identical upper bits, the number of which is equal to the number of bits of the storage data are formed. The second modification utilizes this fact, i.e., one of the two groups, i.e., the upper bit, is specified by only a single determination process of the transistor Tr11, and the upper bit is output first.

Furthermore, according to the EEPROM of the second modification, the first data, i.e., the data to be directly stored in the memory cells 31 are obtained by inserting only the EX-OR gates 46 and 47 in the input stage of the conventional device, and data errors can be confined to only single-bit errors by a simple arrangement, i.e., by inserting the EX-OR gates 44 and 45 in the output stage of the conventional device. Hence, even when multiple-valued storage data are lost due to data errors arising from deterioration of the memory cells 31, which have inevitably occurred after repetitive uses, error detection and error correction can be efficiently and accurately done.

Consequently, according to the EEPROM of the second modification, even when multiple-valued storage data are lost due to data errors arising from deterioration of the memory cells 31, which have inevitably occurred after the repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

Third Modification

An EEPROM of the third modification will be explained below. This EEPROM has substantially the same arrangement as that of the second embodiment, except that the arrangement of the decoder circuit is slightly different from that of the second embodiment. Note that the same reference numerals denote parts corresponding to those of the EEPROM of the second embodiment, and a detailed description thereof will be omitted.

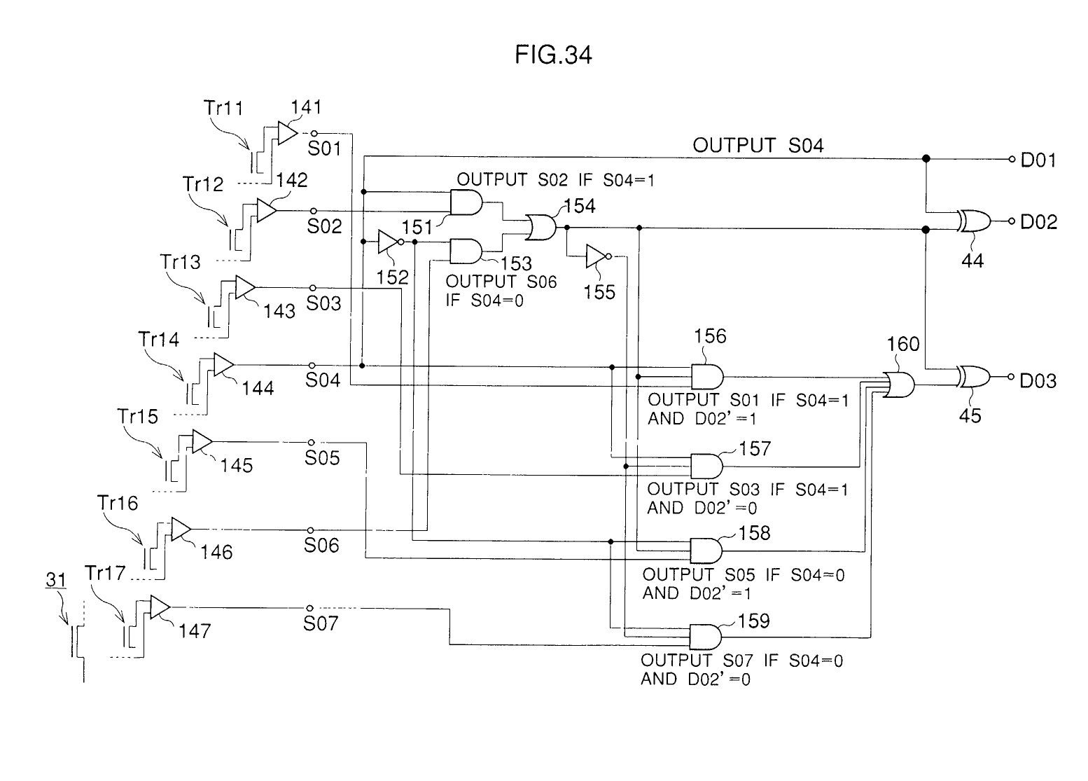

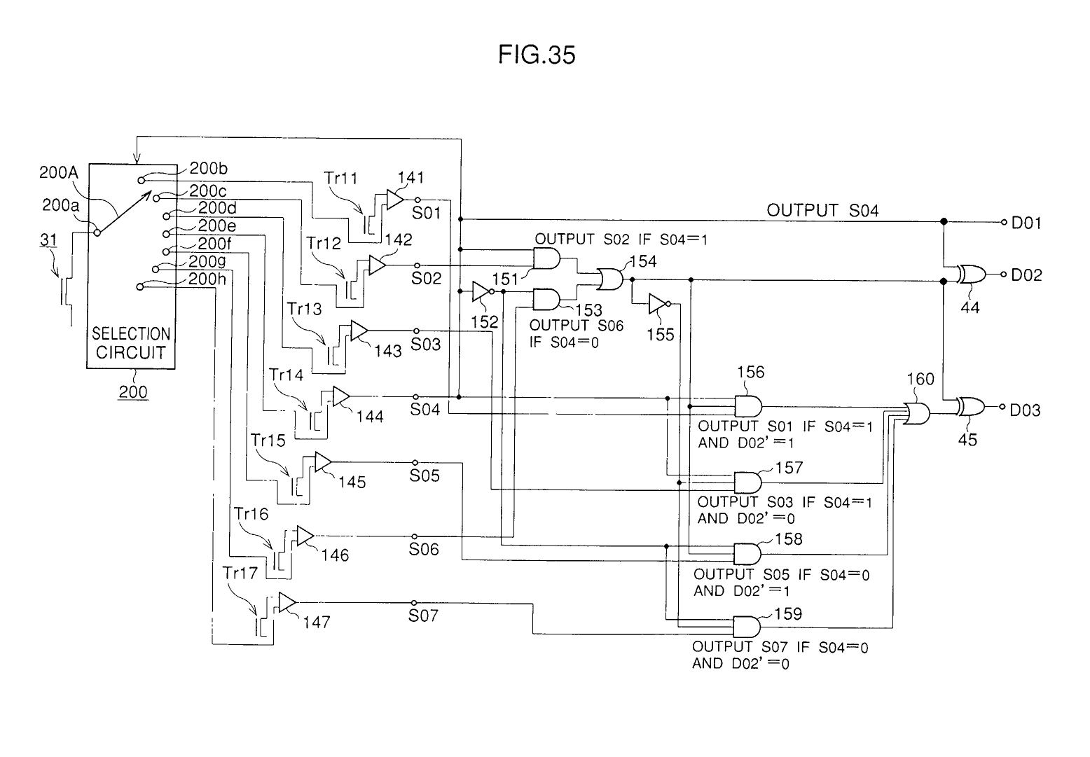

The EEPROM mainly comprises a memory cell array 11, encoder circuit unit 32, decoder circuit unit 38, and the like, as shown in FIG. 33, like in the second embodiment. The arrangement of the decoder circuit unit 38 is slightly different from the decoder circuit unit 33. That is, as shown in FIG. 34, the decoder circuit unit 38 comprises transistors Tr11, Tr12, Tr13, Tr14, Tr15, Tr16, and Tr17, which are respectively connected to each memory cell 10 and have threshold voltages set at 7.5 V, 6.5 V, 5.5 V, 4.5 V, 3.5 V, 2.5 V, and 1.5 V, sense amplifiers 141, 142, 143, 144, 145, 146, and 147 respectively connected to these transistors Tr11 to Tr17, terminals S01, S02, S03, S04, S05, S06, and S07 respectively connected to the sense amplifiers 141 to 147, an AND gate 151 connected to the terminals S02 and S04, an AND gate 153 connected to the terminal S04 via a NOT gate 152 and to the terminal S06, an OR gate 154 connected to the AND gates 151 and 153, an AND gate 156 connected to the terminal S01, OR gate 154, and terminal S04, an AND gate 157 connected to the terminal S03, to the OR gate 154 via a NOT gate 155, and to the terminal S04, an AND gate 158 connected to the terminal S04 via the NOT gate 152, and to the OR gate 154 and terminal S05, an AND gate 159 connected to the terminal S04 via the NOT gate 152, to the OR gate 154 via the NOT gate 155, and to the terminal S07, an OR gate 160 connected to the AND gates 156 to 159, an EX-OR gate 44 connected to receive signals from the terminal S04 and OR gate 154, and an EX-OR gate 45 connected to receive signals from the OR gates 154 and 160. The terminal S04 is directly connected to an output terminal D01, and the EX-OR gates 44 and 45 are respectively connected to output terminals D02 and D03. In this case, as shown in FIG. 35, a selection circuit 200 is preferably added. The EEPROM with the selection circuit 200 will be explained below with reference to FIG. 35. In this decoder circuit unit 38, the output terminal D01 outputs the upper bit of storage data, the output terminal D02 the middle bit of the storage data, and the output terminal D03 the lower bit of the storage data.

The selection circuit 200 is connected to each memory cell 31 and the reference transistors Tr11, Tr12, Tr13, Tr14, Tr15, Tr16, and Tr17 via connection terminals 200a, 200b, 200c, 200d, 200e, 200f, 200g, and 200h, respectively, and a selection switch 200A is disposed at the connection terminal 200a. The selection switch 200A can be selectively connected to the connection terminals 200b to 200h, and connects the connection terminal 200a to one of the connection terminals 200b to 200h in correspondence with storage data from the memory cell 31 and in accordance with the read flow of storage data (to be described later).

The methods of writing and reading storage data using the EEPROM are the same as those in the second embodiment. An example of the read method will be described below using FIGS. 25 and 26 again.

Whether the storage state is “R1, R2, R3, or R4”, or “R5, R6, R7, or R8”, i.e., whether the upper bit of the first data stored in the memory cell 31 is “0” or “1” is determined first using the transistor Tr11. In this case, by controlling the selection switch 200A of the selection circuit 200, the memory cell 31 is connected to the reference transistor Tr11. A voltage of about 9 V is applied to the source 3 and drain 4, and the gate electrode 6 (step S21). The drain current is then detected by the sense amplifier 141, and the threshold voltage V_{T} is compared with the threshold voltage of the transistor Tr11 (step S22). At this time, if the threshold voltage V_{T} is larger than the threshold voltage of the transistor Tr11, i.e., if the current of the memory cell is smaller than that of the transistor Tr11, it is determined that the upper bit is “1”; if the threshold voltage V_{T} is smaller than the threshold voltage of the transistor Tr11, i.e., if the current of the memory cell is larger than that of the transistor Tr11, it is determined that the upper bit is “0”. The determined upper bit is then output from the sense amplifier 141. The upper bit of the first data is equal to that of the second data, and this signal is output from the output terminal D01 as the upper bit of the storage data prior to the middle and lower bits (steps S23 and S24).

Subsequently, it is checked if the middle bit of the first data stored in the memory cell 31 is “0” or “1”. That is, if the threshold voltage V_{T} is larger than the threshold voltage of the transistor Tr11, a similar read is done using the transistor Tr12. More specifically, by controlling the selection switch 200A of the selection circuit 200, the memory cell 31 is connected to the reference transistor Tr12. Then, the current which flows in the memory cell is compared with that which flows in the transistor Tr12 (step S25). On the other hand, if the threshold voltage V_{T} is smaller than the threshold voltage of the transistor Tr11, a similar read is done using the transistor Tr13. More specifically, by controlling the selection switch 200A of the selection circuit 200, the memory cell 31 is connected to the reference transistor Tr13. After that, the current which flows in the memory cell is compared with that which flows in the transistor Tr13 (step S26).

If it is determined in step S25 that the threshold voltage V_{T} is larger than the threshold voltage of the transistor Tr12, i.e., the current which flows in the memory cell is smaller than that which flows in the transistor Tr12, it is determined that the middle bit of the first data is “1”, and the determined bit is output from the sense amplifier 142. The middle bit “1” is input to the EX-OR gate 44 together with the upper bit “1” of the first data. The EX-OR gate 44 converts data “11” into a middle bit “0” of the second data, and outputs the converted bit as the middle bit of the storage data from the output terminal D02 (step S27).

On the other hand, if it is determined in step S25 that the threshold voltage V_{T} is smaller than the threshold voltage of the transistor Tr12, i.e., the current which flows in the memory cell is larger than that which flows in the transistor Tr12, it is determined that the middle bit of the first data is “0”, and is output from the sense amplifier 142. The middle bit “0” is input to the EX-OR gate 44 together with the upper bit “1” of the first data. The EX-OR gate 44 converts data “10” into a middle bit “1” of the second data, and outputs the converted bit as the middle bit of the storage data from the output terminal D02 (step S28).

If it is determined in step S26 that the threshold voltage V_{T} is larger than the threshold voltage of the transistor Tr13, i.e., the current which flows in the memory cell is smaller than that which flows in the transistor Tr13, it is determined that the middle bit of the first data is “1”, and the determined bit is output from the sense amplifier 143. The middle bit “1” is input to the EX-OR gate 44 together with the upper bit “0” of the first data. The EX-OR gate 44 converts data “01” into a middle bit “1” of the second data, and outputs the converted bit as the middle bit of the storage data from the output terminal D02 (step S29).

On the other hand, if it is determined in step S26 that the threshold voltage V_{T} is smaller than the threshold voltage of the transistor Tr13, i.e., the current which flows in the memory cell is larger than that which flows in the transistor Tr13, it is determined that the middle bit of the first data is “0”, and the determined bit is output from the sense amplifier 143. The middle bit “0” is input to the EX-OR gate 44 together with the upper bit “0” of the first data. The EX-OR gate 44 converts data “00” into a middle bit “0” of the second data, and outputs the converted bit as the middle bit of the storage data from the output terminal D02 (step S30).

Subsequently, if the threshold voltage V_{T} is smaller than the threshold voltage of the transistor Tr13, a similar read is done using the transistor Tr14. That is, by controlling the selection switch 200A of the selection circuit 200, the memory cell 31 and reference transistor Tr14 are connected to each other. After that, the currents of the memory cell 31 and transistor Tr14 are compared with each other (step S31). On the other hand, if the threshold voltage V_{T} is larger than the threshold voltage of the transistor Tr13, a similar read is done using the transistor Tr15. More specifically, by controlling the selection switch 200A of the selection circuit 200, the memory cell 31 and reference transistor Tr15 are connected to each other. Then, the currents of the memory cell and transistor Tr15 are compared with each other (step S32).

If it is determined in step S31 that the threshold voltage V_{T} is larger than the threshold voltage of the transistor Tr14, i.e., the current which flows in the memory cell is smaller than that which flows in the transistor Tr14, it is determined that the lower bit is “1”, i.e., the first data stored in the memory cell 31 is “001” (step S33), and that bit is output from the sense amplifier 144. The lower bit “1” is input to the EX-OR gate 45 together with the middle bit “0” of the first data. The EX-OR gate 45 converts the data “01” into a lower bit “1” of the second data, and outputs the converted bit as the lower bit of the storage data from the output terminal D03 (step S34). Therefore, in this case, the storage data (second data) read out from the memory cell 31 is “₀₀₁” equal to the first data.

On the other hand, if it is determined in step S31 that the threshold voltage V_{T} is smaller than the threshold voltage of the transistor Tr14, i.e., the current which flows in the memory cell is larger than that which flows in the transistor Tr14, it is determined that the lower bit is “0”, i.e., the first data stored in the memory cell 31 is “000” (step S35), and that bit is output from the sense amplifier 144. The lower bit “0” is input to the EX-OR gate 45 together with the middle bit “0” of the first data. The EX-OR gate 45 converts the data “00” into a lower bit “0” of the second data, and outputs the converted bit as the lower bit of the storage data from the output terminal D03 (step S36). Therefore, in this case, the storage data (second data) read out from the memory cell 31 is “000” equal to the first data.

If it is determined in step S32 that the threshold voltage V_{T} is larger than the threshold voltage of the transistor Tr15, i.e., the current which flows in the memory cell is smaller than that which flows in the transistor Tr15, it is determined that the lower bit is “1”, i.e., the first data stored in the memory cell 31 is “011” (step S37), and that bit is output from the sense amplifier 145. The lower bit “1” is input to the EX-OR gate 45 together with the middle bit “1” of the first data. The EX-OR gate 45 converts the data “11” into a lower bit “0” of the second data, and outputs the converted bit as the lower bit of the storage data from the output terminal D03 (step S38). Therefore, in this case, the storage data (second data) read out from the memory cell 31 is “010”.

On the other hand, if it is determined in step S32 that the threshold voltage V_{T} is smaller than the threshold voltage of the transistor Tr15, i.e., the current which flows in the memory cell is larger than that which flows in the transistor Tr15, it is determined that the lower bit is “0” i.e., the first data stored in the memory cell 31 is “010” (step S39), and that bit is output from the sense amplifier 145. The lower bit “0” is input to the EX-OR gate 45 together with the middle bit “1” of the first data. The EX-OR gate 45 converts the data “10” into a lower bit “1” of the second data, and outputs the converted bit as the lower bit of the storage data from the output terminal D03 (step S40). Therefore, in this case, the storage data (second data) read out from the memory cell 31 is “011”.

If the threshold voltage V_{T} is smaller than the threshold voltage of the transistor Tr12, a similar read is done using the transistor Tr16 in step S41. That is, by controlling the selection switch 200A of the selection circuit 200, the memory cell 31 and reference transistor Tr16 are connected to each other. After that, the currents of the memory cell and transistor Tr16 are compared with each other (step S41). On the other hand, if the threshold voltage V_{T} is larger than the threshold voltage of the transistor Tr12, a similar read is done using the transistor Tr17. That is, by controlling the selection switch 200A of the selection circuit 200, the memory cell 31 and reference transistor Tr17 are connected to each other. After that, the currents of the memory cell and transistor Tr17 are compared with each other (step S42).

If it is determined in step S41 that the threshold voltage V_{T} is larger than the threshold voltage of the transistor Tr16, i.e., the current which flows in the memory cell is smaller than that which flows in the transistor Tr16, it is determined that the lower bit is “1”, i.e., the first data stored in the memory cell 31 is “101” (step S43), and that bit is output from the sense amplifier 146. The lower bit “1” is input to the EX-OR gate 45 together with the middle bit “0” of the first data. The EX-OR gate 45 converts the data “01” into a lower bit “1” of the second data, and outputs the converted bit as the lower bit of the storage data from the output terminal D03 (step S44). Therefore, in this case, as the middle bit of the converted storage data is “1”, the storage data (second data) read out from the memory cell 31 is “111”.

On the other hand, if it is determined in step S41 that the threshold voltage V_{T} is smaller than the threshold voltage of the transistor Tr16, i.e., the current which flows in the memory cell is larger than that which flows in the transistor Tr16, it is determined that the lower bit is “0”, i.e., the first data stored in the memory cell 31 is “100” (step S45), and that bit is output from the sense amplifier 146. The lower bit “0” is input to the EX-OR gate 45 together with the middle bit “0” of the first data. The EX-OR gate 45 converts the data “00” into a lower bit “0” of the second data, and outputs the converted bit as the lower bit of the storage data from the output terminal D03 (step S46). Therefore, in this case, as the middle bit of the converted storage data is “1”, the storage data (second data) read out from the memory cell 31 is “110”.

If it is determined in step S42 that the threshold voltage V_{T} is larger than the threshold voltage of the transistor Tr17, i.e., the current which flows in the memory cell is smaller than that which flows in the transistor Tr17, it is determined that the lower bit is “1”, i.e., the first data stored in the memory cell 31 is “111” (step S47), and that bit is output from the sense amplifier 147. The lower bit “1” is input to the EX-OR gate 45 together with the middle bit “1” of the first data. The EX-OR gate 45 converts the data “11” into a lower bit “0” of the second data, and outputs the converted bit as the lower bit of the storage data from the output terminal D03 (step S48). Therefore, in this case, as the middle bit of the converted storage data is “0”, the storage data (second data) read out from the memory cell 31 is “100”.

On the other hand, if the threshold voltage V_{T} is smaller than the threshold voltage of the transistor Tr17, i.e., the current which flows in the memory cell is larger than that which flows in the transistor Tr17, it is determined that the lower bit is “0”, i.e., the first data stored in the memory cell 31 is “110” (step S49), and that bit is output from the sense amplifier 147. The lower bit “0” is input to the EX-OR gate 45 together with the middle bit “1” of the first data. The EX-OR gate 45 converts the data “10” into a lower bit “1” of the second data, and outputs the converted bit as the lower bit of the storage data from the output terminal D03 (step S50). Therefore, in this case, as the middle bit of the converted storage data is “0”, the storage data (second data) read out from the memory cell 31 is “101”.

In this case, in the relationship between the outputs from the terminals S01 to S07, and those from the output terminals D01 to D03, since the terminal S04 is directly connected to the output terminal D01, the output from the terminal S04 perfectly matches that (upper bit) from the output terminal D01.

Also, owing to the arrangement of the logic gates (151 to 154), if the output from the terminal S04, i.e., the upper bit as the output from the output terminal D01, is “1”, the output from the terminal S02 is output from the OR gate 154. On the other hand, if the output from the terminal S04, i.e., the upper bit as the output from the output terminal D01, is “0”, the output from the terminal S06 is output from the OR gate 154. The signals from the terminals S04 and OR gate 154 are input to the EX-OR gate 44, and the signal from the EX-OR gate 44 is output from the output terminal D02 as the middle bit.

Furthermore, owing to the arrangement of the logic gates (155 to 166), if the output from the terminal S04, i.e., the upper bit as the output from the output terminal D01, is “1”, and the middle bit as the output from the output terminal D02 is “1”, the output from the terminal S01 is output from the OR gate 160. On the other hand, if the output from the terminal S04 is “1”, and the middle bit as the output from the output terminal D02 is “0”, the output from the terminal S03 is output from the OR gate 160. Furthermore, if the output from the terminal S04 is “0”,and the middle bit as the output from the output terminal D02 is “1”, the output from the terminal S05 is output from the OR gate 160. Moreover, if the output from the terminal S04 is “0”, and the middle bit as the output from the output terminal D02 is “0”, the output from the terminal S07 is output from the OR gate 160. In this fashion, the signals coming from the OR gates 154 and 160 are input to the EX-OR gate 45, and the signal from that EX-OR gate 45 is output from the output terminal D03 as the lower bit.

When first data (000, 001, 010, 011, 100, 101, 110, 111) directly stored in the memory cells 31 are used as storage data as in the conventional device, if the threshold voltage V_{T} becomes lower than the threshold voltage (=4.5 V) of, e.g., the transistor Tr11, the storage data “100” is read out as “011” as a result of data errors. At that time, data errors have occurred in all the upper, middle, and, lower bits. By contrast, in the EEPROM of the third modification, data errors occur in only one bit, as described above. Therefore, when the EEPROM of the third modification is used, even when data errors have occurred due to deterioration of the memory cells 31, they can be restricted to only single-bit errors, and error detection and error correction can be effectively performed using conventional error detection using parity error check codes and error correction using Hamming codes.

As described above, according to the EEPROM of the third modification, even when multiple-valued storage data are lost due to data errors arising from deterioration of the memory cells 31, which have inevitably occurred after repetitive uses, error detection and error correction can be efficiently and accurately done.

In the EEPROM of the third modification, since 3-bit binary data are used as storage data, and the respective bits that form each storage data are assigned an output order to output especially the data of the upper bit first, the data of the upper bit is specified and output by a single determination process by the transistor Tr11. More specifically, when values that the storage data can assume are aligned in turn, two groups having identical upper bits, the number of which is equal to the number of bits of the storage data are formed. Exploiting this fact, one of the two groups, i.e., the upper bit, is specified by only a single determination process of the transistor Tr11, and the upper bit is output first.

Furthermore, according to the EEPROM of the third modification, the first data, i.e., the data to be directly stored in the memory cells 31 are obtained by inserting only the EX-OR gates 46 and 47 in the input stage of the conventional device, and data errors can be limited to only single-bit errors by a simple arrangement, i.e., by inserting the EX-OR gates 44 and 45 in the output stage of the conventional device. Hence, even when multiple-valued storage data are lost due to data errors resulting from deterioration of the memory cells 31, which have inevitably occurred after repetitive uses, error detection and error correction can be efficiently and accurately done.

To recapitulate, according to the EEPROM of the third modification, even when multiple-valued storage data are lost due to data errors arising from deterioration of the memory cells 31, which have inevitably occurred after repetitive uses, error detection and error correction can be efficiently and accurately done by a very simple arrangement. In addition, signal delays can be suppressed and a high-speed read can be attained without making the circuit arrangement complex. Using such advantages, this embodiment is suitably applied to a so-called serial access type EEPROM which has storage locations that can be accessed in the input/output order.

In the second embodiment and its modifications, an octonary EEPROM as a nonvolatile memory has been exemplified as a semiconductor storage device. The present invention can also be applied to an octonary DRAM as a volatile memory, which has memory capacitors each for storing a signal charge, and access transistors for selecting the memory capacitors, sets each desired memory capacitor in a charge accumulation state by applying a predetermined reference voltage to the capacitor, and stores storage data corresponding to the reference voltage.

The first embodiment has exemplified the multiple-valued type EEPROM of four values (2 bits) and the second embodiment has exemplified the multiple-valued type EEPROM of eight values (3 bits). However, the present invention is not limited to these specific EEPROMs. For example, the present invention can also be applied to nonvolatile semiconductor storage devices other than EEPROMs, volatile semiconductor storage devices such as DRAMs, and various other multiple-valued type semiconductor storage devices. The present invention is not limited to four or eight values, and can be applied to multiple-valued semiconductor devices of 2ⁿ values (=n bits; n is a natural number equal to or larger than 2). Furthermore, the present invention is not limited to binary storage data (i.e., binary notation), but can also be applied to a case wherein each digit is expressed by “0”, “1”, and “2” (i.e., ternary notation), or data expressed by higher notations.

Furthermore, a program code itself for controlling various devices to implement the functions of the write and read methods described in the first and second embodiments and their modifications, and a means for supplying that program code to a computer, e.g., a storage medium that stores the program code, are included in the scope of the present invention. For example, as such storage medium, a storage medium 51 which implements steps S1 to S14 of the read method described in the first embodiment shown in FIG. 1, storage media 52, 53, 54, and 55 of the first, second, third, and fourth modifications shown in FIGS. 10, 12, 14, and 17, a storage medium 56 that implements steps S21 to S50 of the read method described in the second embodiment shown in FIG. 20, and storage media 57, 58, and 59 of the first, second, and third modifications shown in FIGS. 29, 31, and 33, may be used.

The program code is read out from each of the storage media 51 to 59 by a storage/reproduction device 60, and controls the computer. As the storage medium for storing the program code, for example, a floppy disk, hard disk, optical disk, magneto-optical disk, CD-ROM, magnetic tape, nonvolatile memory card, ROM, and the like may be used.

Not only when the functions of each of the above embodiments are implemented upon executing the supplied program code by the computer, but also when the functions of each of the above embodiments are implemented in collaboration of the program code and OS (operating system), or another application software program, which is running on the computer, such program code is included in the present invention.

Furthermore, the present invention includes a system in which the supplied program code is stored in a memory mounted on a function extension board of the computer or a function extension unit connected to the computer, and a CPU or the like mounted on that function extension board or unit executes some or all of the processing steps on the basis of the instruction of the program code so as to implement the functions of each of the above embodiments.

Third Embodiment

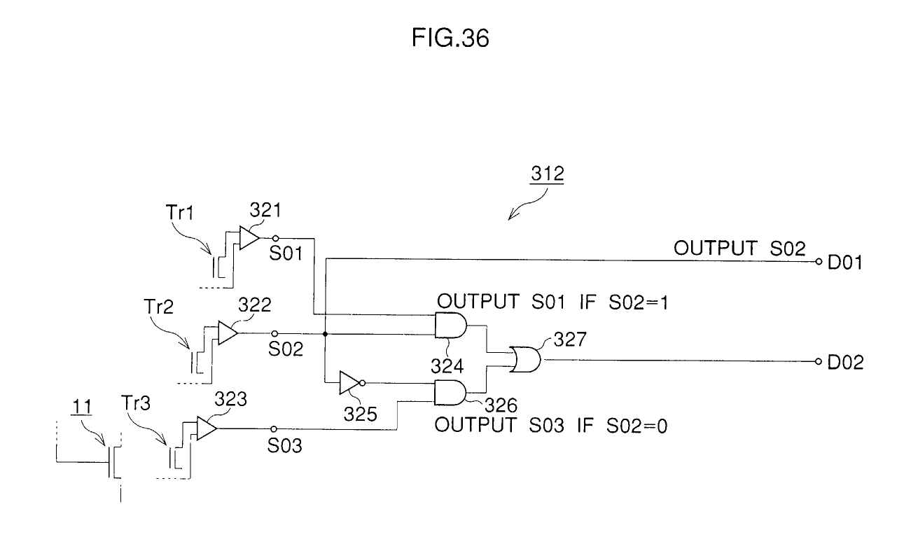

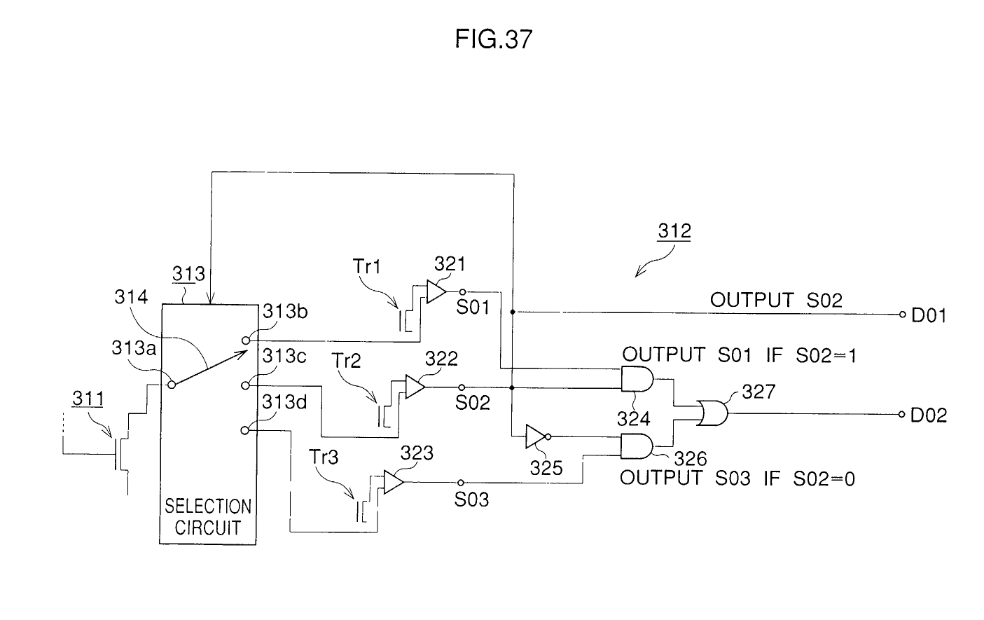

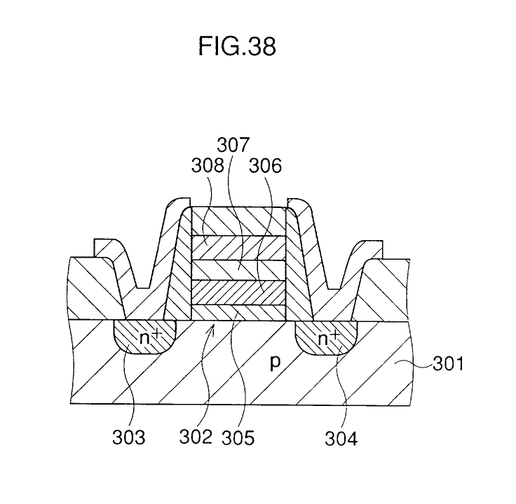

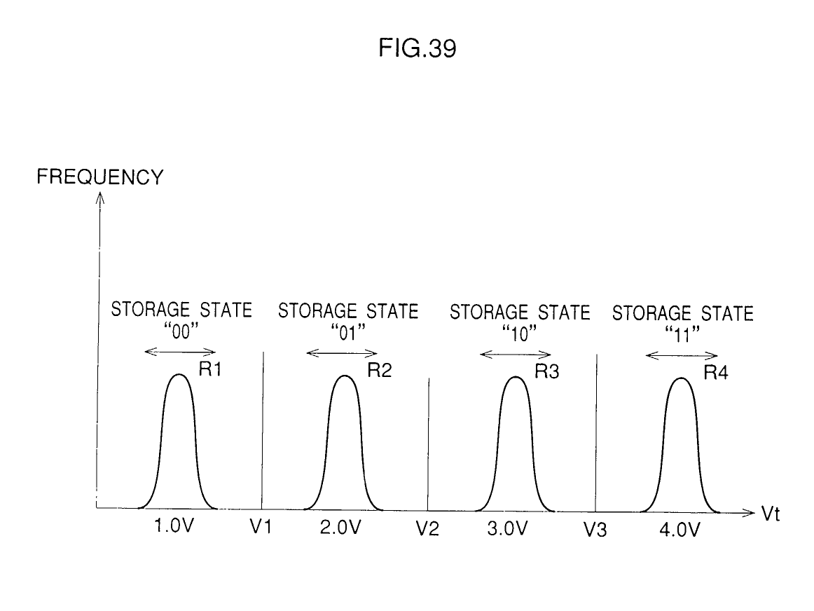

The third embodiment will be explained below. The third embodiment will exemplify an EEPROM as a nonvolatile semiconductor storage device which stores four-valued (2-bit) binary data as storage data. FIG. 36 is a circuit diagram showing the arrangement of principal part of an EEPROM of the third embodiment, FIG. 37 is a circuit diagram showing the arrangement with a control circuit in addition to that shown in FIG. 36, FIG. 38 is a schematic sectional view showing the arrangement of principal part of a memory cell of the EEPROM, and FIG. 39 is a graph showing the distribution of threshold voltages of the memory cells.

In the EEPROM of the third embodiment, its read means and peripheral circuits comprise a memory cell group (not shown) as a matrix of a plurality of memory cells 311, and a decoder circuit unit 312 which is connected to the respective memory cells 311, and detects and outputs storage data of the selected memory cell 311, as shown in FIG. 36. In this case, a selection circuit 313 is preferably added, as shown in FIG. 37. An EEPROM with the selection circuit 313 will be described below with reference to FIG. 37.

As shown in FIG. 38, each memory cell 311 has a source 303 and drain 304 as a pair of impurity diffusion layers, which are formed by doping an n-type impurity such as phosphorus (P), arsenic (As), or the like into the surface region of an element active region 302 defined by an element isolation structure such as a field oxide film or the like on a p-type silicon semiconductor substrate 301, an isolated, island-like floating gate 306 which is patterned via a tunnel oxide film 305 on a channel region C between the source 303 and drain 304, and a control gate 308 which is patterned on the floating gate 306 via a dielectric film 307 consisting of, e.g., an ONO film, and is capacitively coupled to the floating gate 306.

The decoder circuit unit 312 comprises reference transistors Tr1, Tr2, and Tr3, the threshold voltages of which are respectively set at 3.5 V, 2.5 V, and 1.5 V, sense amplifiers 321, 322, and 323 respectively connected to these reference transistors Tr1 to Tr3, terminals S01, S02, and S03 respectively connected to the sense amplifiers 321 to 323, an AND gate 324 connected to the terminals S01 and S02, an AND gate 326 connected to the terminal S02 via a NOT gate 325 and to the terminal S03, and an OR gate 327 connected to the AND gates 324 and 326. The terminal S02 is directly connected to an output terminal D01, and the OR gate 327 is connected to an output terminal D02. In this decoder circuit unit 312, the output terminal D01 outputs the upper bit of storage data, and the output terminal D02 outputs the lower bit of the storage data.

The selection circuit 313 is connected to each memory cell 311, and the reference transistors Tr1, Tr2, and Tr3 via connection terminals 313a, 313b, 313c, and 313d, and a selection switch 314 is arranged at the connection terminal 313a. The selection switch 314 can be selectively connected to the connection terminals 313b, 313c, and 313d, and connects the connection terminal 313a and one of the connection terminals 313b to 313d in correspondence with storage data from the memory cell 311 and in accordance with the read flow of storage data (to be described later).

In this EEPROM, as shown in FIG. 39, the memory cells 311 can store storage data corresponding to threshold voltages of four values (1 V, 2 V, 3 V, and 4 V), 31 upon operation of the encoder circuit unit 32, and can store four-valued first data (“00”, “01”, “10”, “11”) so that the value of the first data becomes larger as the threshold voltage becomes higher.

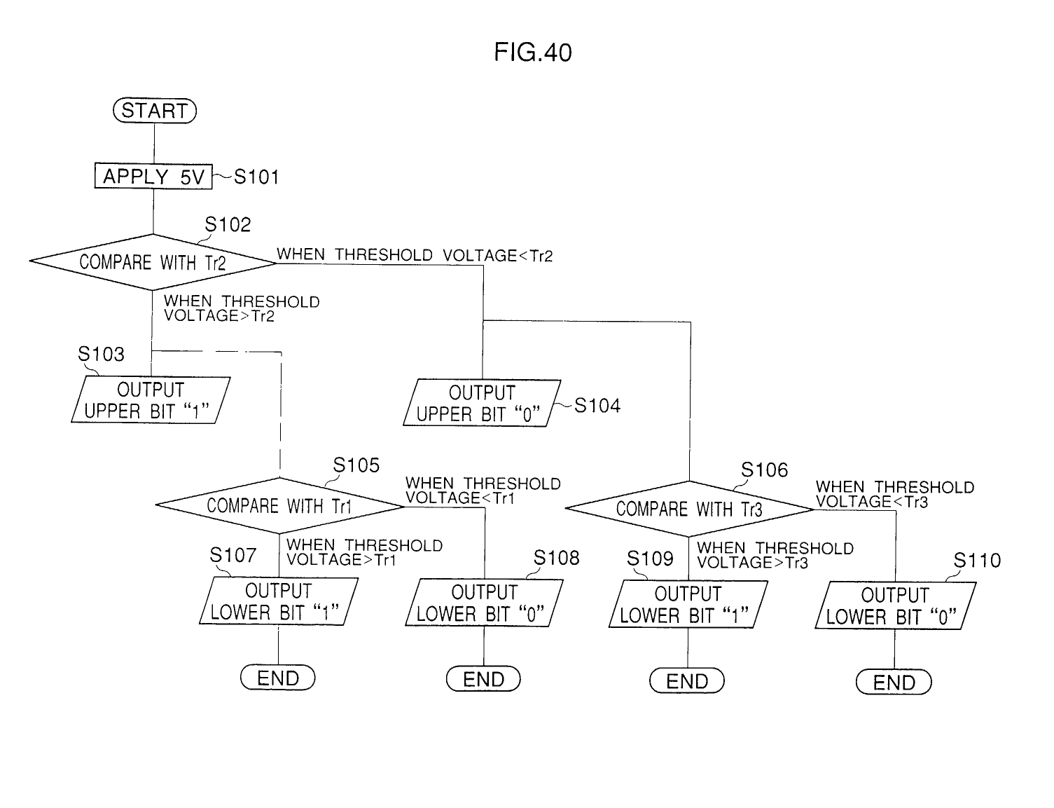

Data is read out from the respective memory cells 311 of this EEPROM as follows. FIG. 40 is a flow chart showing the respective steps upon reading.

As for storage data read out from the selected memory cell, as shown in FIG. 39, the threshold voltage (V_{T}) represents a distribution having four peaks (four values) of about 1 V, 2 V, 3 V, and 4 V. In FIG. 39, when the threshold voltage V_{T} is detected within the range R1, the storage state is “00”; and when the threshold voltage V_{T} is detected within the range R2, the storage state is “01”. On the other hand, when the threshold voltage V_{T} is detected within the range R3, the storage state is “10”; and when the threshold voltage V_{T} is detected within the range R4, the storage state is “11”.

Therefore, whether the storage state is “R1 or R2”, or “R3 or R4”, i.e., whether the upper bit of the storage data stored in the memory cell 311 is “0” or “1” is determined using the transistor Tr2. In this case, the memory cell 311 is connected to the reference transistor Tr2 by controlling the selection switch 314 in the selection circuit 313. Then, as shown in FIG. 40, a voltage near 5 V is applied to the source 303 and drain 304, and the gate electrode 306 (step S101). The drain current is detected by the sense amplifier 321, and the threshold voltage V_{T} and the threshold voltage of the transistor Tr1 are compared with each other (step S102). At this time, if the threshold voltage V_{T} is larger than the threshold voltage of the transistor Tr2, i.e., if the current of the transistor Tr2 is larger than that which flows in the channel region C of the memory cell, it is determined that the upper bit is “1”, and the determined bit is output first from the output terminal D01 as the upper bit of the storage data (step S103). On the other hand, if the threshold voltage V_{T} is smaller than the threshold voltage of the transistor Tr2, i.e., if the current which flows in the memory cell is larger than that which flows in the transistor Tr2, it is determined that the upper bit is “0”, and the determined bit is output first from the output terminal D01 as the upper bit of storage data (step S104).

Subsequently, if the threshold voltage V_{T} is larger than the threshold voltage of the transistor Tr2, a similar read is done using the transistor Tr1. More specifically, the memory cell 311 is connected to the reference transistor Tr1 by controlling the selection switch 314 in the selection circuit 313. Then, the current which flows in the memory cell is compared with that which flows in the transistor Tr1 (step S105). On the other hand, if the threshold voltage V_{T} is smaller than the threshold voltage of the transistor Tr2, a similar read is done using the transistor Tr3. That is, the memory cell 311 is connected to the reference transistor Tr3 by controlling the selection switch 314 of the selection circuit 313. Then, the current which flows in the memory cell 311 is compared with that which flows in the transistor Tr3 (step S106).

If it is determined in step S105 that the threshold voltage V_{T} is larger than the threshold voltage of the transistor Tr1, it is determined that the lower bit of the storage data is “1”, and that bit is output from the output terminal D02 after the upper bit (step S107). In this case, the storage data stored in the memory cell 311 is “11”.

On the other hand, if it is determined in step S105 that the threshold voltage V_{T} is smaller than the threshold voltage of the transistor Tr1, it is determined that the lower bit of the storage data is “0”, and that bit is output from the output terminal D02 after the upper bit (step S108). In this case, the storage data stored in the memory cell 311 is “10”.

If it is determined in step S106 that the threshold voltage V_{T} is larger than the threshold voltage of the transistor Tr3, it is determined that the lower bit of the storage data is “1”, and that bit is output from the output terminal D02 after the upper bit (step S109). In this case, the storage data stored in the memory cell 311 is “01”.

On the other hand, if it is determined in step S106 that the threshold voltage V_{T} is smaller than the threshold voltage of the transistor Tr3, it is determined that the lower bit of the storage data is “0”, and that bit is output from the output terminal D02 after the upper bit (step S110). In this case, the storage data stored in the memory cell 311 is noon.

Table 6 below summarizes the relationship between the outputs from the terminals S01 to S03, and those from the output terminals D01 and D02. As described above, in the flow of steps S101 to S104, since the terminal S02 is directly connected to the output terminal D01, the output from the terminal S02 perfectly matches that (upper bit) from the output terminal D01. In the flow of steps S105 to S110, owing to the arrangement of the logic gates (324 to 327), if the output from the terminal S02, i.e., the upper bit as the output from the output terminal D01, is “1”, the output from the terminal S01 is output from the output terminal D02 as the lower bit. On the other hand, if the output from the terminal S02, i.e., the upper bit as the output from the output terminal D01, is “0”, the output from the terminal S03 is output from the output terminal D02 as the lower bit.

TABLE 6

| | |
|---|---|
| S0 | D0 |

| 1 | 2 | 3 | 1 | 2 |
|---|---|---|---|---|
| 1 | 1 | 1 | 1 | 1 |
| 0 | 1 | 1 | 1 | 0 |
| 0 | 0 | 1 | 0 | 1 |
| 0 | 0 | 0 | 0 | 0 |

The method of writing storage data in the EEPROM will be explained below.

When storage data “11” is written, the drain 304 of the memory cell is set at the ground potential to open the source 303, and a voltage of approximately 22 V is applied to the control gate 308. At this time, electrons are injected from the drain 304 into the floating gate 306 via the tunnel oxide film 305, and the threshold voltage (V_{T}) shifts in the positive direction. As a result, the threshold voltage of the memory cell rises to about 4 V. This storage state is assumed to be “11”.

When data “10” is written, the drain 304 of the memory cell is set at the ground potential to open the source 303, and a voltage of about 20 V is applied to the control gate 308. At this time, electrons are injected from the drain 304 into the floating gate 306 via the tunnel oxide film 305, and the threshold voltage of the memory cell becomes about 3 V. This storage state is assumed to be “10”.

When data “01” is written, the drain 304 of the memory cell is set at the ground potential to open the source 303, and a voltage near 18 V is applied to the control gate 308. At this time, electrons are injected from the drain 304 into the floating gate 306 via the tunnel oxide film 305, and the threshold voltage of the memory cell becomes about 2 V. This storage state is assumed to be “01”.

Finally, when data “00” is written, a voltage of about 10 V is applied to the drain 304 of the memory cell to open the source 303 and set the control gate 108 at the ground potential. At this time, the electrons that have been injected into the floating gate 306 are cleared from the drain 304, and the threshold voltage of the memory cell becomes about 1 V. This storage state is assumed to be “00”.

As described above, in the EEPROM of the third embodiment, since 2-bit binary data are used as storage data, and the respective bits that form each storage data are assigned an output order to output especially the data of the upper bit first by controlling the selection circuit 313, the data of the upper bit is specified and output by a single determination process by the transistor Tr2. More specifically, when values that the storage data can assume are aligned in turn, two groups having identical upper bits, the number of which is equal to the number of bits of the storage data are formed (see Table 1). Utilizing this fact, one of the two groups, i.e., the upper bit, is specified by only a single determination process of the transistor Tr2, and the upper bit is output first.

Hence, according to the EEPROM of the third embodiment, signal delays can be suppressed and a high-speed read can be attained without making the circuit arrangement complex. Using such advantages, this embodiment is suitably applied to a so-called serial access type EEPROM which obtains storage locations to be accessed in the input/output order.

Note that the third embodiment has exemplified a quaternary EEPROM serving as a nonvolatile memory has been exemplified as a semiconductor storage device. The present invention can also be applied to a quaternary DRAM as a volatile memory, which has memory capacitors each for storing a signal charge, and access transistors for selecting the memory capacitors, sets each desired memory capacitor in a charge accumulation state by applying a predetermined reference voltage to the capacitor, and stores storage data corresponding to the reference voltage.

Fourth Embodiment

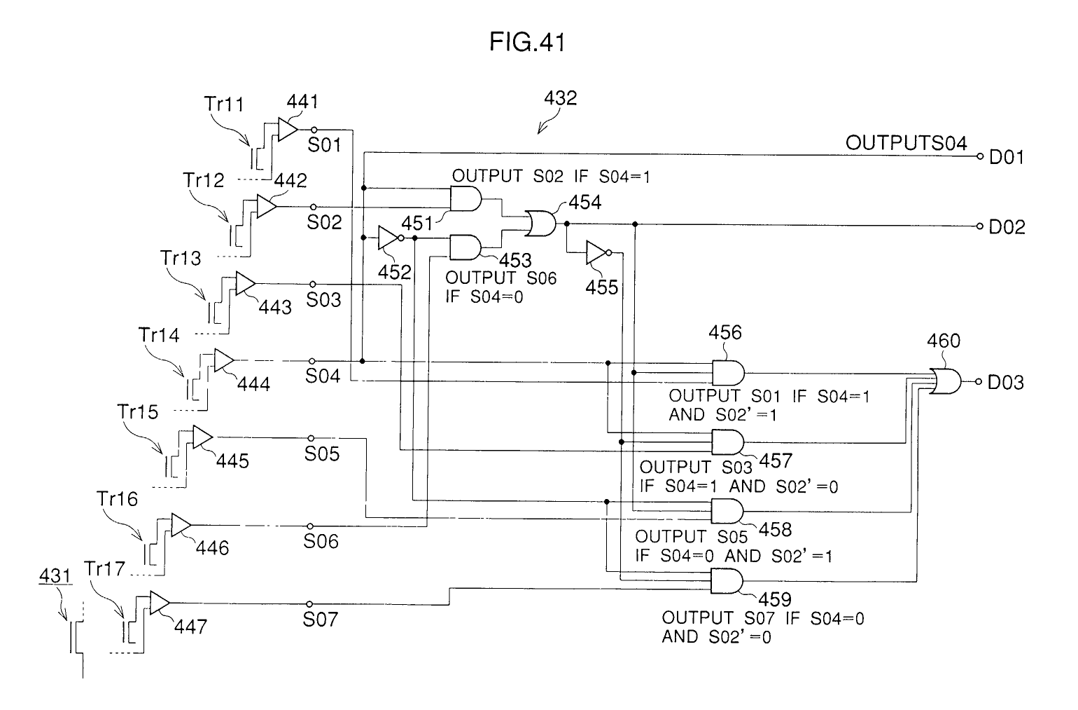

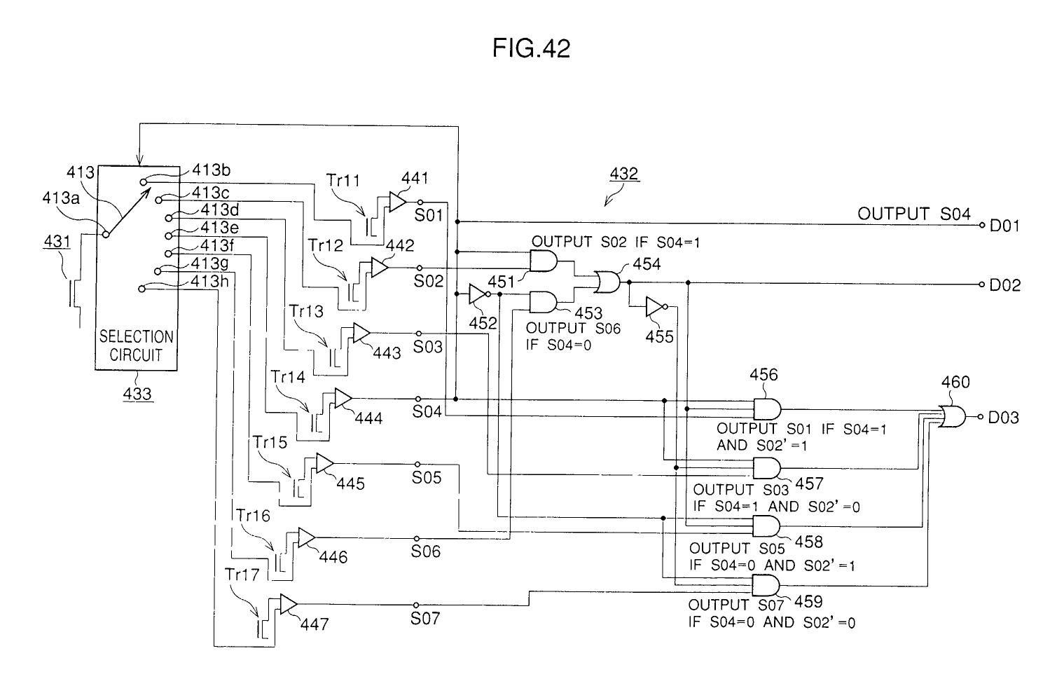

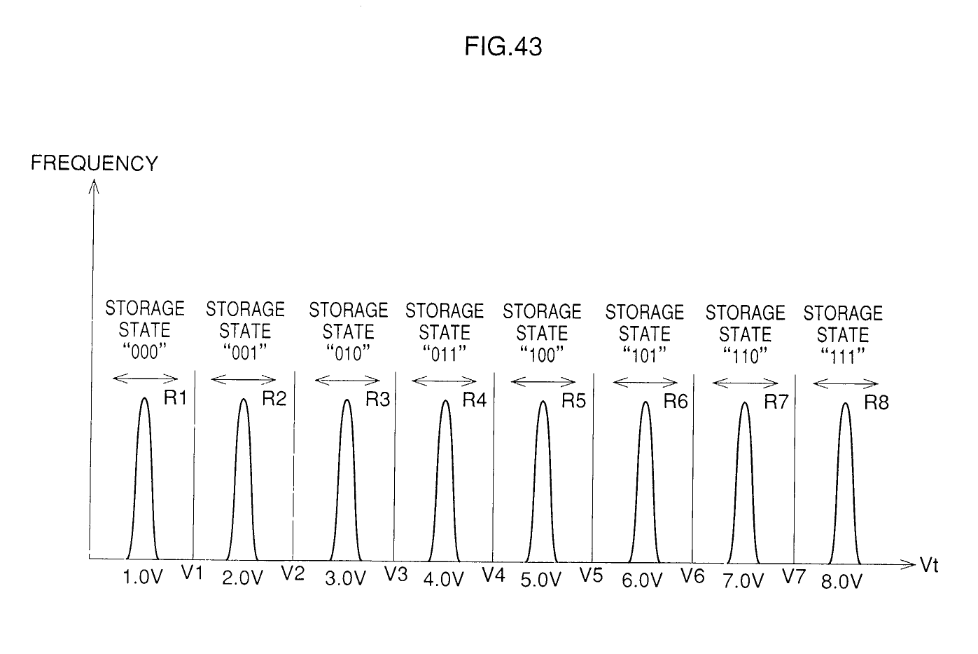

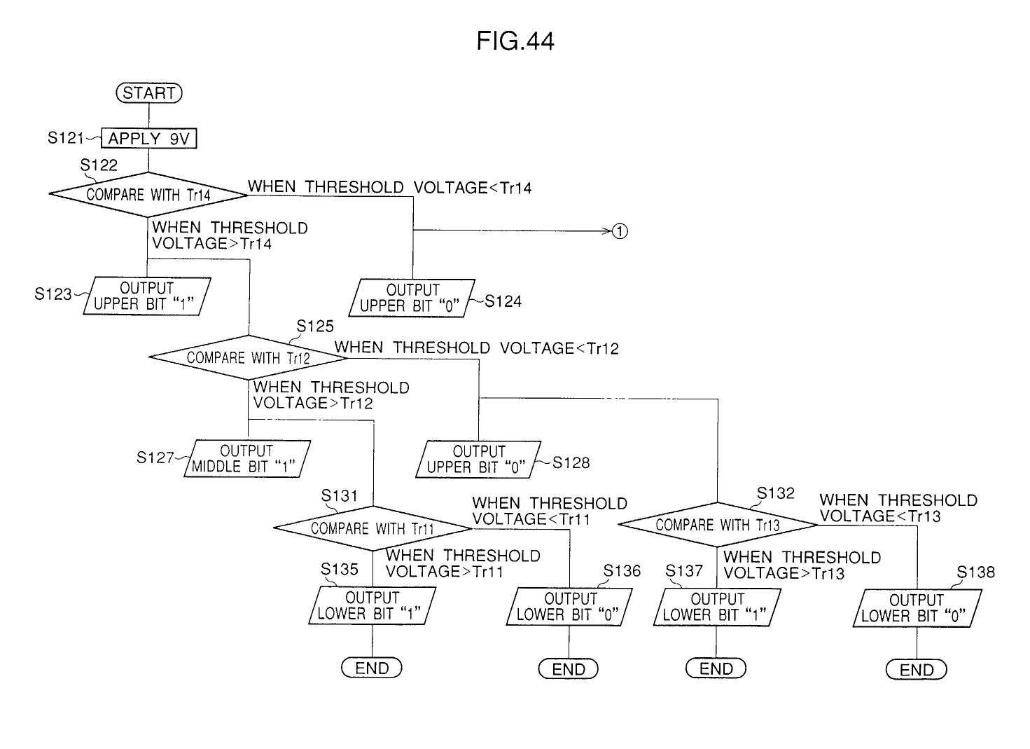

The fourth embodiment of the present invention will be explained below. The fourth embodiment will exemplify an EEPROM as a nonvolatile semiconductor storage device which can store eight-valued (=3 bits) storage data. FIG. 41 is circuit diagram showing the arrangement of principal part of an EEPROM of the third embodiment, FIG. 42 is a circuit diagram showing the arrangement with a control circuit in addition to that shown in FIG. 41, and FIG. 43 is a graph showing the distribution of threshold voltages of the memory cells.

As shown in FIG. 41, the EEPROM of the fourth embodiment comprises a memory cell group (not shown) as a matrix of a plurality of memory cells 431, and a decoder circuit unit 432 which is connected to the respective memory cells 431, and detects and outputs storage data of the selected memory cell 431. In this case, a selection circuit 433 is preferably added, as shown in FIG. 42. An EEPROM with the selection circuit 433 will be described below with reference to FIG. 42.

As in each memory cell 311 of the third embodiment, each memory cell 431 has a source 303 and drain 304 as a pair of impurity diffusion layers, which are formed by doping an n-type impurity such as phosphorus (P), arsenic (As), or the like into the surface region of an element active region 302 defined by an element isolation structure such as a field oxide film or the like on a p-type silicon semiconductor substrate 301, an isolated, island-like floating gate 306 which is patterned via a tunnel oxide film 305 on a channel region C between the source 303 and drain 304, and a control gate 308 which is patterned on the floating gate 306 via a dielectric film 307 consisting of, e.g., an ONO film, and is capacitively coupled to the floating gate 306.

The decoder circuit unit 432 comprises reference transistors Tr11, Tr12, Tr13, Tr14, Tr15, Tr16, and Tr17, the threshold voltages of which are respectively set at 7.5 V, 6.5 V, 5.5 V, 4.5 V, 3.5 V, 2.5 V, and 1.5 V, sense amplifiers 441, 442, 443, 444, 445, 446, and 447 respectively connected to these reference transistors Tr11 to Tr17, terminals S01, S02, S03, S04, S05, S06, and S07 respectively connected to the sense amplifiers 441 to 447, an AND gate 451 connected to the terminals S02 and S04, an AND gate 453 connected to the terminal S04 via a NOT gate 452 and to the terminal S06, an OR gate 454 connected to the AND gates 451 and 453, an AND gate 456 connected to the terminal S01, OR gate 454, and terminal S04, an AND gate 457 connected to the terminal S03, to the OR gate 454 via a NOT gate 455, and to the terminal S04, an AND gate 458 connected to the terminal S04 via the NOT gate 452, and to the OR gate 454 and terminal S05, an AND gate 459 connected to the terminal S04 via the NOT gate 452, to the OR gate 454 via the NOT gate 455, and to the terminal S07, and an OR gate 460 connected to the AND gates 456 to 459. In this decoder circuit unit 432, the terminal S04 is directly connected to an output terminal D01, and the OR gates 454 and 460 are respectively connected to output terminals D02 and D03. The output terminals D01, D02, and D03 respectively output the upper, middle, and lower bits of storage data.

The selection circuit 433 is connected to each memory cell 431 and the reference transistors Tr11, Tr12, Tr13, Tr14, Tr15, Tr16, and Tr17 via connection terminals 413a, 413b, 413c, 413d, 413e, 413f, 413g, and 413h, and a selection switch 413 is arranged at the connection terminal 413a. The selection switch 413 can be selectively connected to the connection terminals 413b to 413h, and connects the connection terminal 413a to one of the connection terminals 413b to 413h in correspondence with storage data from the memory cell 431 and in accordance with the read flow of storage data (to be described later).

The EEPROM can store storage data corresponding to threshold voltages of eight values (1 V, 2 V, 3 V, 4 V, 5 V, 6 V, 7 V, 8 V) in the respective memory cells, and can store eight-valued storage data (“000”, “001”, “010”, “011”, “100”, “101”, “110”, “111”) so that the value of the storage data becomes larger as the threshold voltage becomes higher.

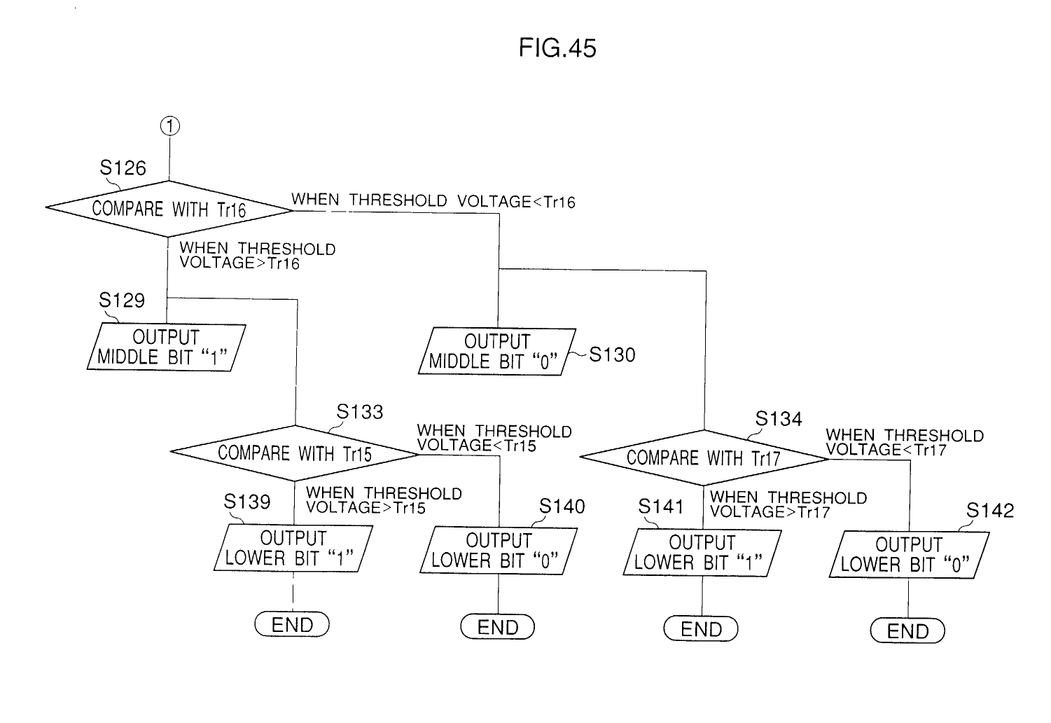

Data is read out from the respective memory cells 311 of this EEPROM as follows. FIGS. 40 and 45 are flow charts showing the respective steps upon reading.

As for storage data read out from the selected memory cell 431, as shown in FIG. 43, threshold voltages (V_{T}) have a distribution with eight peaks (eight values) at about 1 V, 2 V, 3 V, 4 V, 5 V, 6 V, 7 V, and 8 V. In FIG. 43, when the threshold voltage V_{T} is detected within the range R1, the storage state is “000”; when the threshold voltage V_{T} is detected within the range R2, the storage state is “001”; when the threshold voltage V_{T} is detected within the range R3, the storage state is “010”; and when the threshold voltage V_{T} is detected within the range R4, the storage state is “011”. On the other hand, when the threshold voltage V_{T} is detected within the range R5, the storage state is “100”; when the threshold voltage V_{T} is detected within the range R6, the storage state is “101”; when the threshold voltage V_{T} is detected within the range R7, the storage state is “110”; and when the threshold voltage V_{T} is detected within the range R8, the storage state is “111”.

Hence, whether the storage state is “R1, R2, R3, or R4”, or “R5, R6, R7, or R8”, i.e., whether the upper bit of the first data stored in the memory cell 431 is “0” or “1” is determined first using the transistor Tr14. In this case, by controlling the selection switch 413 of the selection circuit 433, the memory cell 431 is connected to the reference transistor Tr14. A voltage around 9 V is applied to the source 303 and drain 304, and the gate electrode 306 (step S121). The drain current is then detected by the sense amplifier 441, and the threshold voltage V_{T} is compared with the threshold voltage of the transistor Tr14 (step S122). At this time, if the threshold voltage V_{T} is larger than the threshold voltage of the transistor Tr14, i.e., if the current of the memory cell is smaller than that of the transistor Tr14, it is determined that the upper bit is “1”, and the determined bit is output from the output terminal D01 first as the upper bit of the storage data (step S123). On the other hand, if the threshold voltage V_{T} is smaller than the threshold voltage of the transistor Tr14, i.e., if the current of the memory cell is larger than that of the transistor Tr14, it is determined that the upper bit is “0”, and the determined bit is output from the output terminal D01 first as the upper bit of the storage data (step S124).

Subsequently, after step S123, i.e., if the threshold voltage V_{T} is larger than the threshold voltage of the transistor Tr14, a similar read is done using the transistor Tr12. More specifically, by controlling the selection switch 413 of the selection circuit 433, the memory cell 431 is connected to the reference transistor Tr12. Then, the current which flows in the memory cell is compared with that which flows in the transistor Tr12 (step S125). On the other hand, if the threshold voltage V_{T} is smaller than the threshold voltage of the transistor Tr14, a similar read is done using the transistor Tr16. More specifically, by controlling the selection switch 413 of the selection circuit 433, the memory cell 431 is connected to the reference transistor Tr16. After that, the current which flows in the memory cell is compared with that which flows in the transistor Tr16 (step S126).

If it is determined in step S125 as a result of the above read that the threshold voltage V_{T} is larger than the threshold voltage of the transistor Tr12, it is determined that the middle bit of the storage data is “1”, and the determined bit is output from the output terminal D02 after the upper bit (step S127). That is, in this process, the upper and middle bits of the 3-bit storage data have been output as “1” and “1”.

On the other hand, it is determined in step S125 as a result of the above read that the threshold voltage V_{T} is smaller than the threshold voltage of the transistor Tr12, it is determined that the middle bit of the storage data is “0”, and the determined bit is output from the output terminal D02 after the upper bit (step S128). That is, in this process, the upper and middle bits of the 3-bit storage data have been output as “1” and “0”.

If it is determined in step S126 as a result of the above read that the threshold voltage V_{T} is larger than the threshold voltage of the transistor Tr16, it is determined that the middle bit of the storage data is “1”, and the determined bit is output from the output terminal D02 after the upper bit (step S129). That is, in this process, the upper and middle bits of the 3-bit storage data have been output as “0” and “1”.

On the other hand, it is determined in step S126 as a result of the above read that the threshold voltage V_{T} is smaller than the threshold voltage of the transistor Tr16, it is determined that the middle bit of the storage data is “0”, and the determined bit is output from the output terminal D02 after the upper bit (step S130). That is, in this process, the upper and middle bits of the 3-bit storage data have been output as “0” and “0”.

Subsequently, after step S127, i.e., if the threshold voltage V_{T} is larger than the threshold voltage of the transistor Tr12 as a result of the above read, a similar read is done using the transistor Tr11. More specifically, by controlling the selection switch 413 of the selection circuit 433, the memory cell 431 is connected to the reference transistor Tr11. Then, the current which flows in the memory cell is compared with that which flows in the transistor Tr11 (step S131). On the other hand, if the threshold voltage V_{T} is smaller than the threshold voltage of the transistor Tr12, a similar read is one using the transistor Tr13. More specifically, by controlling the selection switch 413 of the selection circuit 433, the memory cell 431 is connected to the reference transistor Tr13. Then, the current which flows in the memory cell is compared with that which flows in the transistor Tr13 (step S132).

Also, after step S129, i.e., if the threshold voltage V_{T} is larger than the threshold voltage of the transistor Tr16 as a result of the above read, a similar read is done using the transistor Tr15. More specifically, by controlling the selection switch 413 of the selection circuit 433, the memory cell 431 is connected to the reference transistor Tr15. Then, the current which flows in the memory cell is compared with that which flows in the transistor Tr15 (step S133). On the other hand, if the threshold voltage V_{T} is smaller than the threshold voltage of the transistor Tr16, a similar read is one using the transistor Tr17. More specifically, by controlling the selection switch 413 of the selection circuit 433, the memory cell 431 is connected to the reference transistor Tr17. Then, the current which flows in the memory cell is compared with that which flows in the transistor Tr17 (step S134).

If it is determined in step S131 as a result of the above read that the threshold voltage V_{T} is larger than the threshold voltage of the transistor Tr11, it is determined that the lower bit of the storage data is “1”, and the determined bit is output from the output terminal D03 after the middle bit (step S135). That is, in this process, all the bits of the 3-bit storage data have been output, and the storage data in the memory cell 431 is “111”.

On the other hand, if it is determined in step S131 as a result of the above read that the threshold voltage V_{T} is smaller than the threshold voltage of the transistor Tr11, it is determined that the lower bit of the storage data is “0”, and the determined bit is output from the output terminal D03 after the middle bit (step S136). That is, in this process, all the bits of the 3-bit storage data have been output, and the storage data in the memory cell 431 is “110”.

If it is determined in step S132 as a result of the above read that the threshold voltage V_{T} is larger than the threshold voltage of the transistor Tr13, it is determined that the lower bit of the storage data is “1”, and the determined bit is output from the output terminal D03 after the middle bit (step S137). That is, in this process, all the bits of the 3-bit storage data have been output, and the storage data in the memory cell 431 is “101”.

On the other hand, if it is determined in step S132 as a result of the above read that the threshold voltage V_{T} is smaller than the threshold voltage of the transistor Tr13, it is determined that the lower bit of the storage data is “0”, and the determined bit is output from the output terminal D03 after the middle bit (step S138). That is, in this process, all the bits of the 3-bit storage data have been output, and the storage data in the memory cell 431 is “100”.

If it is determined in step S133 as a result of the above read that the threshold voltage V_{T} is larger than the threshold voltage of the transistor Tr15, it is determined that the lower bit of the storage data is “1”, and the determined bit is output from the output terminal D03 after the middle bit (step S139). That is, in this process, all the bits of the 3-bit storage data have been output, and the storage data in the memory cell 431 is “011”.

On the other hand, if it is determined in step S133 as a result of the above read that the threshold voltage V_{T} is smaller than the threshold voltage of the transistor Tr15, it is determined that the lower bit of the storage data is “0”, and the determined bit is output from the output terminal D03 after the middle bit (step S140). That is, in this process, all the bits of the 3-bit storage data have been output, and the storage data in the memory cell 431 is “010”.

If it is determined in step S134 as a result of the above read that the threshold voltage V_{T} is larger than the threshold voltage of the transistor Tr17, it is determined that the lower bit of the storage data is “1”, and the determined bit is output from the output terminal D03 after the middle bit (step S141). That is, in this process, all the bits of the 3-bit storage data have been output, and the storage data in the memory cell 431 is “001”.

On the other hand, if it is determined in step S134 as a result of the above read that the threshold voltage V_{T} is smaller than the threshold voltage of the transistor Tr17, it is determined that the lower bit of the storage data is “0”, and the determined bit is output from the output terminal D03 after the middle bit (step S142). That is, in this process, all the bits of the 3-bit storage data have been output, and the storage data in the memory cell 431 is “000”.

Table 7 below summarizes the relationship between the outputs from the terminals S01 to S07, and those form the output terminals D01 to D03. As described above, in the flow of steps S121 to S124, since the terminal S04 is directly connected to the output terminal D01, the output from the terminal S04 perfectly matches that (upper bit) from the output terminal D01. In the flow of steps S125 to S130, owing to the arrangement of the logic gates (451 to 454), if the output from the terminal S04, i.e., the upper bit as the output from the output terminal D01, is “1”, the output from the terminal S02 is output from the output terminal D02 as the middle bit. On the other hand, if the output from the terminal S04, i.e., the upper bit as the output from the output terminal D01, is “0”, the output from the terminal S06 is output from the output terminal D02 as the middle bit. Furthermore, in the flow of steps S131 to S142, owing to the arrangement of the logic gates (455 to 460), if the output from the terminal S04, i.e., the upper bit as the output from the output terminal D01, is “1”, and the middle bit as the output from the output terminal D02 is “1”, the output from the terminal S01 is output from the output terminal D03 as the lower bit. On the other hand, if the output from the terminal S04 is “1”, and the middle bit as the output from the output terminal D02 is “0”, the output from the terminal S03 is output from the output terminal D03 as the lower bit. Also, if the output from the terminal S04 is “0”, and the middle bit as the output from the output terminal D02 is “1”, the output from the terminal S05 is output from the output terminal D03 as the lower bit. Finally, if the output from the terminal S04 is “0”, and the middle bit as the output from the output terminal D02 is “0”, the output from the terminal S07 is output from the output terminal D03 as the lower bit.

TABLE 7

| SO | | | | | | | DO | | |
|---|---|---|---|---|---|---|---|---|---|
| 1 | 2 | 3 | 1 | 2 | 3 | 3 | 1 | 2 | 3 |
| 1 | 1 | 1 | 1 | 1 | 1 | 1 | 1 | 1 | 1 |
| 0 | 1 | 1 | 1 | 1 | 1 | 1 | 1 | 1 | 0 |
| 0 | 0 | 1 | 1 | 1 | 1 | 1 | 1 | 0 | 1 |
| 0 | 0 | 0 | 1 | 1 | 1 | 1 | 1 | 0 | 0 |
| 0 | 0 | 0 | 0 | 1 | 1 | 1 | 0 | 1 | 1 |
| 0 | 0 | 0 | 0 | 0 | 1 | 1 | 0 | 1 | 0 |
| 0 | 0 | 0 | 0 | 0 | 0 | 1 | 0 | 0 | 1 |
| 0 | 0 | 0 | 0 | 0 | 0 | 0 | 0 | 0 | 0 |

The method of writing storage data in this EEPROM will be explained below.

When data “111” is written, the drain 304 of the memory cell is set at the ground potential to open the source 303, and a voltage around 30 V is applied to the control gate 308. At this time, electrons are injected from the drain 304 into the floating gate 306 via the tunnel oxide film 305, and the threshold voltage (V_{T}) shifts in the positive direction. As a result, the threshold voltage of the memory cell rises to about 8 V. This storage state is assumed to be “111”.

When data “110” is written, the drain 304 of the memory cell is set at the ground potential to open the source 303, and a voltage of about 28 V is applied to the control gate 308. At this time, electrons are injected from the drain 304 into the floating gate 306 via the tunnel oxide film 305, and the threshold voltage of the memory cell becomes about 7 V. This storage state is assumed to be “110”.

When data “101” is written, the drain 304 of the memory cell is set at the ground potential to open the source 303, and a voltage near 26 V is applied to the control gate 308. At this time, electrons are injected from the drain 304 into the floating gate 306 via the tunnel oxide film 305, and the threshold voltage of the memory cell becomes about 6 V. This storage state is assumed to be “101”.

When data “100” is written, the drain 304 of the memory cell is set at the ground potential to open the source 303, and a voltage of approximately 24 V is applied to the control gate 308. At this time, electrons are injected from the drain 304 into the floating gate 306 via the tunnel oxide film 305, and the threshold voltage of the memory cell becomes about 5 V. This storage state is assumed to be “100”.

When data “011” is written, the drain 304 of the memory cell is set at the ground potential to open the source 303, and a voltage of about 22 V is applied to the control gate 308. At this time, electrons are injected from the drain 304 into the floating gate 306 via the tunnel oxide film 305, and the threshold voltage of the memory cell becomes about 4 V. This storage state is assumed to be “011”.

When data “010” is written, the drain 304 of the memory cell is set at the ground potential to open the source 303, and a voltage near 20 V is applied to the control gate 308. At this time, electrons are injected from the drain 304 into the floating gate 306 via the tunnel oxide film 305, and the threshold voltage of the memory cell becomes about 3 V. This storage state is assumed to be “010”.

When data “001” is written, the drain 304 of the memory cell is set at the ground potential to open the source 303, and a voltage of about 18 V is applied to the control gate 308. At this time, electrons are injected from the drain 304 into the floating gate 306 via the tunnel oxide film 305, and the threshold voltage of the memory cell becomes about 2 V. This storage state is assumed to be “001”.

Finally, when data “000” is written, a voltage of about 10 V is applied to the drain 304 of the memory cell to open the source 303 and set the control gate 108 at the ground potential. At this time, the electrons that have been injected into the floating gate 306 are cleared from the drain 304, and the threshold voltage of the memory cell becomes about 1 V. This storage state is assumed to be “000”.

As described above, in the EEPROM of the fourth embodiment, since 3-bit binary data are used as storage data, and the respective bits that form each storage data are assigned an output order to output especially the data of the upper bit first by controlling the selection circuit 433, the data of the upper bit is specified and output by a single determination process by the transistor Tr14. When values that the storage data can assume are aligned in turn, two groups having identical upper bits, the number of which is equal to the number of digits (the number of bits) of the storage data are formed. Utilizing this fact, one of the two groups, i.e., the upper bit, is specified by only a single determination process of the transistor Tr14, and the upper bit is output first. In general, in the arrangement of a decoder circuit of a read means, in case of 3-bit or more storage data as compared to 2-bit storage data, as the number of bits becomes larger, the number of logic gates that make up the decoder circuit and the number of input lines of each logic gate increase considerably, and the circuit becomes complex, thus posing various problems such as signal delays. However, in this EEPROM, even when the number of bits of the storage data is digitized to have three values, the upper bit can be output first, as described above, and the middle and lower bits are sequentially output in turn, thus suppressing signal delays and the like.

Consequently, according to the EEPROM of the fourth embodiment, signal delays can be suppressed and a high-speed read can be attained without making the circuit arrangement complex. Using such advantages, this embodiment is suitably applied to a so-called serial access type EEPROM which obtains storage locations to be accessed in the input/output order.

Note that the fourth embodiment has exemplified an octonary EEPROM serving as a nonvolatile memory has been exemplified as a semiconductor storage device. The present invention can also be applied to an octonary DRAM as a volatile memory, which has memory capacitors each for storing a signal charge, and access transistors for selecting the memory capacitors, sets each desired memory capacitor in a charge accumulation state by applying a predetermined reference voltage to the capacitor, and stores storage data corresponding to the reference voltage.

The third embodiment has exemplified the multiple-valued type EEPROM of four values (2 bits) and the fourth embodiment has exemplified the multiple-valued type EEPROM of eight values (3 bits). However, the present invention is not limited to these specific EEPROMs. The present invention is not limited to four or eight values, and can be applied to multiple-valued semiconductor devices of 2ⁿ values (=n bits; n is a natural number equal to or larger than 2), and the present invention is more effective as n is larger.

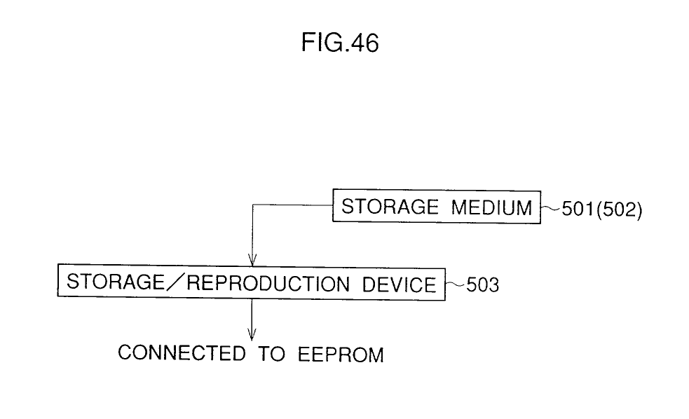

Furthermore, a program code itself for controlling various devices to implement the functions of the write and read methods described in the third and fourth embodiments, and a means for supplying that program code to a computer, e.g., a storage medium that stores the program code, are included in the scope of the present invention. For example, as such storage medium, a storage medium 501 which implements steps S101 to S110 of the read method described in the third embodiment shown in FIG. 46, and a storage medium 502 that implements steps S121 to S142 of the read method described in the fourth embodiment may be used.

The program code is read out from the storage medium 501 or 502 by a storage/reproduction device 503, and controls the EEPROM. As the storage medium for storing the program code, for example, a floppy disk, hard disk, optical disk, magneto-optical disk, CD-ROM, magnetic tape, nonvolatile memory card, ROM, and the like may be used.

Not only when the functions of each of the above embodiments are implemented upon executing the supplied program code by the computer, but also when the functions of each of the above embodiments are implemented in collaboration of the program code and OS (operating system), or another application software program, which is running on the computer, such program code is included in the present invention.

Furthermore, the present invention includes a system in which the supplied program code is stored in a memory mounted on a function extension board of the computer or a function extension unit connected to the computer, and a CPU or the like mounted on that function extension board or unit executes some or all of the processing steps on the basis of the instruction of the program code so as to implement the functions of each of the above embodiments.

What is claimed is:

1. A semiconductor storage device which has a matrix of a plurality of memory cells, and obeys a first rule according to which storage data of predetermined values of at least two digits are stored in the respective memory cells in correspondence with an order of reference voltages, comprising:
write means for generating codes by assigning the input storage data according to a second rule, and storing the codes in the memory cells; and
read means for assigning the code read out from the selected memory cell according to a third rule, and outputting the assigned code as output data,
wherein the third rule is a rule for generating the output data by assigning the codes complying with the first rule to have only one different digit between neighboring codes when the codes are arranged in turn in correspondence with the reference voltages, and the second rule is an inverse assignment rule to the third rule, and
the storage data and output data match each other unless an error has occurred in the output data.

2. A device according to claim 1, wherein said read means comprises a logic circuit for assigning digits that form the storage data in accordance with an assignment rule that obtains only one different digit between the storage data corresponding to neighboring reference voltages.

3. A device according to claim 2, wherein said write means comprises a logic circuit for implementing an inverse assignment to the assignment rule of said read means.

4. A device according to claim 1, wherein a data sequence is formed by adding redundant data for error detection or error correction to the storage data, the data sequence is converted into first data, and the first data are stored in a series of a predetermined number of memory cells, and
the redundant information is assigned to one digit of one of the series of memory cells.

5. A device according to claim 1, wherein said read means outputs data of an uppermost digit of the digits that form the storage data first, outputs the data of the uppermost digit by a single determination process, and sequentially outputs lower digits following the uppermost digit.

6. A device according to claim 4, wherein said read means outputs data of an uppermost digit of the digits that form the data sequence first, outputs the data of the uppermost digit by a single determination process, and sequentially outputs lower digits following the uppermost digit.

7. A device according to claim 5, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the storage data first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the storage data is output, and
repeats operation for specifying and outputting data of a lower digit following the lower digit until a lowermost digit is reached.

8. A device according to claim 7, wherein said read means comprises selection means for selecting and enabling the predetermined one of the reference transistors in accordance with the storage data from the memory cell, and
the comparison is made by the reference transistor selected by said selection means.

9. A device according to claim 6, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the data sequence first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the data sequence is output, and
repeats operation for specifying and outputting data of a lower digit following the lower digit until a lowermost digit is reached.

10. A device according to claim 9, wherein said read means comprises selection means for selecting and enabling the predetermined one of the reference transistors in accordance with the data sequence from the memory cell, and
the comparison is made by the reference transistor selected by said selection means.

11. A device according to claim 1, wherein the storage data is binary data.

12. A device according to claim 4, wherein the data sequence includes binary data.

13. A device according to claim 1, wherein each memory cell has a gate, source, and drain, and also has an island-shaped floating gate formed via a dielectric film on a portion between said gate and a tunnel insulating film formed on a channel region between said source and drain.

14. A device according to claim 1, wherein each memory cell is of serial access type.

15. A semiconductor storage device comprising:
storage means having a matrix of a plurality of memory cells, each of which stores first data of a predetermined value of at least two digits;
read means for selecting a desired memory cell from said storage means, detecting the first data stored in the selected memory cell, generating second data by converting the first data in accordance with an assignment rule for obtaining only one different digit in correspondence with neighboring reference voltages, and outputting the second data as storage data; and
write means for converting the storage data into the first data by performing assignment inverse to the assignment rule of said read means, and storing the first data in the memory cells.

16. A device according to claim 15, wherein said read means comprises logic circuits for assigning digits that form the storage data in accordance with an assignment rule that obtains only one different digit between the storage data corresponding to neighboring reference voltages.

17. A device according to claim 16, wherein said logic circuits are respectively connected to output terminals for the respective digits except for an output terminal for an uppermost digit.

18. A device according to claim 16, wherein said write means comprises a logic circuit for implementing an inverse assignment to the assignment rule of said read means.

19. A device according to claim 15, wherein a data sequence is formed by adding redundant data for error detection or error correction to the storage data, the data sequence is converted into first data, and the first data are stored in a series of a predetermined number of memory cells, and
the redundant information is assigned to one digit of one of the series of memory cells.

20. A device according to claim 15, wherein said read means outputs data of an uppermost digit of the digits that form the storage data first, outputs the data of the uppermost digit by a single determination process, and sequentially outputs lower digits following the uppermost digit.

21. A device according to claim 19, wherein said read means outputs data of an uppermost digit of the digits that form the data sequence first, outputs the data of the uppermost digit by a single determination process, and sequentially outputs lower digits following the uppermost digit.

22. A device according to claim 20, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the storage data first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the storage data is output, and
repeats operation for specifying and outputting data of a lower digit following the lower digit until a lowermost digit is reached.

23. A device according to claim 22, wherein said read means comprises selection means for selecting and enabling the predetermined one of the reference transistors in accordance with the storage data from the memory cell, and
the comparison is made by the reference transistor selected by said selection means.

24. A device according to claim 21, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the data sequence first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the data sequence is output, and
repeats operation for specifying and outputting data of a lower digit following the lower digit until a lowermost digit is reached.

25. A device according to claim 24, wherein said read means comprises selection means for selecting and enabling the predetermined one of the reference transistors in accordance with the data sequence from the memory cell, and
the comparison is made by the reference transistor selected by said selection means.

26. A device according to claim 15, wherein the storage data is binary data.

27. A device according to claim 19, wherein the data sequence includes binary data.

28. A device according to claim 15, wherein each memory cell has a gate, source, and drain, and also has an island-shaped floating gate formed via a dielectric film on a portion between said gate and a tunnel insulating film formed on a channel region between said source and drain.

29. A device according to claim 15, wherein each memory cell is of serial access type.

30. A multiple-valued type semiconductor storage device, which can store, in memory cells, storage data each defined by at least two digits, each of which assumes one of two values,
wherein input storage data are converted in accordance with a rule that makes the storage data correspond to reference voltages, and the converted data are stored in the memory cells upon writing,
the storage data stored in the memory cells are converted by an inverse conversion of the rule to have only one different digit between the storage data corresponding to neighboring reference voltages upon reading, and
the input storage data and output storage data match each other unless an error has occurred upon writing, upon storing in the memory cells, or upon reading.

31. A device according to claim 30, wherein said device comprises read means for selecting a desired memory cell and detecting the storage data stored in the selected memory cell, and
said read means comprises logic circuits for assigning digits that form the storage data in accordance with an assignment rule that obtains only one different digit between the storage data corresponding to neighboring reference voltages.

32. A device according to claim 31, wherein said logic circuits are respectively connected to output terminals for the respective digits except for an output terminal for an uppermost digit.

33. A device according to claim 32, wherein said device comprises write means for storing the storage data in the selected memory cell, and
said write means comprises a logic circuit for implementing an inverse assignment to the assignment rule of said read means.

34. A device according to claim 30, wherein a data sequence is formed by adding redundant data for error detection or error correction to the storage data, the data sequence is converted into first data, and the first data are stored in a series of a predetermined number of memory cells, and
the redundant information is assigned to one digit of one of the series of memory cells.

35. A device according to claim 30, wherein said read means outputs data of an uppermost digit of the digits that form the storage data first, outputs the data of the uppermost digit by a single determination process, and sequentially outputs lower digits after the uppermost digit.

36. A device according to claim 34, wherein said read means outputs data of an uppermost digit of the digits that form the data sequence first, outputs the data of the uppermost digit by a single determination process, and sequentially outputs lower digits after the uppermost digit.

37. A device according to claim 35, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the storage data first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the storage data is output, and
repeats operation for specifying and outputting data of a lower digit following the lower digit until a lowermost digit is reached.

38. A device according to claim 37, wherein said read means comprises selection means for selecting and enabling the predetermined one of the reference transistors in accordance with the storage data from the memory cell, and
the comparison is made by the reference transistor selected by said selection means.

39. A device according to claim 36, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the data sequence first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the data sequence is output, and
repeats operation for specifying and outputting data of a lower digit following the lower digit until a lowermost digit is reached.

40. A device according to claim 39, wherein said read means comprises selection means for selecting and enabling the predetermined one of the reference transistors in accordance with the data sequence from the memory cell, and
the comparison is made by the reference transistor selected by said selection means.

41. A device according to claim 30, wherein each memory cell is of serial access type.

42. A device according to claim 30, wherein the storage data is binary data.

43. A device according to claim 34, wherein the data sequence includes binary data.

44. A device according to claim 30, wherein each memory cell has a gate, source, and drain, and also has an island-shaped floating gate formed via a dielectric film on a portion between said gate and a tunnel insulating film formed on a channel region between said source and drain.

45. A semiconductor storage device which comprises a memory cell which can store predetermined storage data of 2ⁿ values (n is a natural number not less than 2), comprising:
read means for reading out first storage data stored in the memory cell;
first data conversion means for converting a first specific value of the first storage data obtained by said read means into binary data of at least one predetermined digit; and
second data conversion means for comparing the first specific value with (2ⁿ−1) reference values to obtain a second specific value and converting the second specific value into binary data,
wherein neighboring binary data corresponding to the first storage data have only one different digit therebetween.

46. A semiconductor storage device which comprises a memory cell which can store predetermined storage data of 2ⁿ values (n is a natural number not less than 2), comprising:
read means for reading out first storage data stored in the memory cell;
first data conversion means for converting a first specific value of the first storage data obtained by said read means into binary data of at least one predetermined digit; and
second data conversion means for comparing the first specific value with (2^{m}−1) reference values (m is a natural number smaller than n) to obtain a second specific value and converting the second specific value into binary data of m digits,
wherein neighboring binary data corresponding to the first storage data have only one different digit therebetween.

47. A semiconductor storage device which comprises a memory cell which can store predetermined storage data of N^{M} values (N and M are natural numbers not less than 2), comprising:
read means for reading out first storage data stored in the memory cell;
first data conversion means for converting a first specific value of the first storage data obtained by said read means into binary data of at least one predetermined digit; and
second data conversion means for comparing the first specific value with (N^{M}−1) reference values to obtain a second specific value and converting the second specific value into binary data,
wherein neighboring binary data corresponding to the first storage data have only one different digit therebetween.

48. A semiconductor storage device which comprises a memory cell which can store predetermined storage data of N^{M} values (N and M are natural numbers not less than 2), comprising:
read means for reading out first storage data stored in the memory cell;
first data conversion means for converting a first specific value of the first storage data obtained by said read means into binary data of at least one predetermined digit; and
second data conversion means for comparing the first specific value with (N^{L}−1) reference values (L is a natural number smaller than M) to obtain a second specific value and converting the second specific value into binary data of L digits,
wherein neighboring binary data corresponding to the first storage data have only one different digit therebetween.

49. A multiple-valued type semiconductor storage device which can store storage data of predetermined values of at least three digits in memory cells in correspondence with reference voltages, and read out the storage data by specifying the reference voltages by several determination processes,
wherein data of a predetermined one of digits that form the storage data is output first, and the data of the predetermined digit is output by a single determination process.

50. A semiconductor storage device comprising:
storage means having a matrix of a plurality of memory cells, which store 2-bit storage data in correspondence with reference voltages; and
read means having three reference transistors, each of which has a predetermined value between neighboring reference voltages as a threshold voltage thereof,
wherein said read means specifies and outputs first an upper bit of the storage data by a single first determination process using a predetermined one of the reference transistors, and
performs second and third determination processes using remaining two of the reference transistors, specifies a result of the second or third determination process as a lower bit of the storage data depending on a result of the first determination process, and then outputs the lower bit.

51. A semiconductor storage device comprising:
storage means having a matrix of a plurality of memory cells, which store storage data of predetermined values of at least three digits in correspondence with reference voltages; and
read means for selecting a desired memory cell from said storage means, and specifying and outputting the storage data by determining the reference voltage, said read means outputting data of a predetermined one of digits that form the storage data first, and outputting the data of the predetermined digit by a single determination process.

52. A device according to claim 49, wherein the predetermined digit is an uppermost digit of the storage data.

53. A device according to claim 51, wherein the predetermined digit is an uppermost digit of the storage data.

54. A device according to claim 49, wherein respective digits that form the storage data are output in turn from an uppermost digit.

55. A device according to claim 49, wherein each memory cell has a gate, source, and drain, and also has an island-shaped floating gate formed via a dielectric film on a portion between said gate and a tunnel insulating film formed on a channel region between said source and drain, and
the memory cell stores the storage data corresponding to the reference voltage by setting the reference voltage as a threshold voltage upon applying predetermined voltages to said gate, source, and drain, respectively.

56. A device according to claim 49, wherein each memory cell has a memory capacitor for accumulating a signal charge, and an access transistor for selecting the memory capacitor, and
the memory cell stores the storage data corresponding to the reference voltage by setting a charge accumulation state upon applying a predetermined reference voltage to the memory capacitor.

57. A device according to claim 55, wherein each memory cell is of serial access type.

58. A device according to claim 51, wherein said read means comprises reference transistors each of which has a predetermined value between neighboring reference voltages as a threshold voltage thereof, and specifies the reference voltage by comparing the threshold voltage of each reference transistor with the reference voltage of the memory cell, and
specifies and outputs the data of the uppermost digit of the storage data first by a single determination process using only a predetermined one of the reference transistors.

59. A device according to claim 58, wherein said read means specifies and outputs data of a lower digit following the uppermost digit by the determination process using a predetermined one of the remaining reference transistors on the basis of the data of the uppermost digit, and
repeats operation for specifying and outputting data of a lower digit following the lower digit until a lowermost digit is reached.

60. A device according to claim 59, wherein said read means comprises reference transistors each of which has a predetermined value between neighboring reference voltages as a threshold voltage thereof, and specifies the reference voltage by comparing the threshold voltage of each reference transistor with the reference voltage of the memory cell,
specifies and outputs the data of the uppermost digit of the storage data first by a single determination process using only a predetermined one of the reference transistors,
specifies and outputs data of a lower digit following the uppermost digit by the determination process using a predetermined one of the remaining reference transistors on the basis of the data of the uppermost digit, after the data of the uppermost digit of the storage data is output, and
repeats operation for specifying and outputting data of a lower digit following the lower digit until a lowermost digit is reached.

61. A device according to claim 58, wherein said read means comprises selection means for selecting and enabling the predetermined one of the reference transistors in accordance with the storage data from the memory cell, and
the comparison is made by the reference transistor selected by said selection means.

62. A device according to claim 51, wherein the storage data is binary data.

63. A semiconductor storage device which comprises a memory cell which can store predetermined storage data of 2ⁿ values (n is a natural number not less than 3), comprising:
read means for reading out first storage data stored in the memory cell;
first data conversion means for converting a first specific value of the first storage data obtained by said read means into binary data of at least one predetermined digit; and
second data conversion means for comparing the first specific value with (2ⁿ−1) reference values to obtain a second specific value and converting the second specific value into binary data.

64. A semiconductor storage device which comprises a memory cell which can store predetermined storage data of 2ⁿ values (n is a natural number not less than 3), comprising:
read means for reading out first storage data stored in the memory cell;
first data conversion means for converting a first specific value of the first storage data obtained by said read means into binary data of at least one predetermined digit; and
second data conversion means for comparing the first specific value with (2^{m}−1) reference values (m is a natural number smaller than n) to obtain a second specific value and converting the second specific value into binary data of m digits.

65. A semiconductor storage device which comprises a memory cell which can store predetermined storage data of N^{M} values (N is a natural number not less than 2, and M is a natural number not less than 3), comprising:
read means for reading out first storage data stored in the memory cell;
first data conversion means for converting a first specific value of the first storage data obtained by said read means into binary data of at least one predetermined digit; and
second data conversion means for comparing the first specific value with (N^{M}−1) reference values to obtain a second specific value and converting the second specific value into binary data.

66. A semiconductor storage device which comprises a memory cell which can store predetermined storage data of N^{M} values (N is a natural number not less than 2, and M is a natural number not less than 3), comprising:
read means for reading out first storage data stored in the memory cell;
first data conversion means for converting a first specific value of the first storage data obtained by said read means into binary data of at least one predetermined digit; and
second data conversion means for comparing the first specific value with (N^{L}−1) reference values (L is a natural number smaller than M) to obtain a second specific value and converting the second specific value into binary data of L digits.
